(19) United States
(12) Patent Application Publication
(10) Pub. No.: US 2026/0362747 A1
(43) Pub. Date: Nov. 12, 2026

(54) SEMICONDUCTOR DEVICE

(71) Applicant: SEMICONDUCTOR ENERGY LABORATORY CO., LTD., Atsugi-shi, Kanagawa-ken (JP)

(72) Inventors: Shunpei YAMAZAKI, Tokyo (JP); Masahiro WATANABE, Tochigi (JP); Seiji YASUMOTO, Tochigi (JP); Masami JINTYOU, Shimotsuga (JP); Miwa TANABE, Tochigi (JP)

(21) Appl. No.: 19/667,852

(22) Filed: May 5, 2026

(30) Foreign Application Priority Data
May 9, 2025 (JP) 2025-079007
May 9, 2025 (JP) 2025-079012
Jun. 6, 2025 (JP) 2025-095143
Feb. 10, 2026 (JP) 2026-020063

(51) Int. Cl. H10D 30/67

(52) U.S. Cl. CPC H10D 30/6755

(57) ABSTRACT

A semiconductor device including a transistor having high field-effect mobility is provided. The semiconductor device includes a semiconductor layer, a first insulating layer, a second insulating layer, and a conductive layer. The semiconductor layer is positioned over the first insulating layer. The second insulating layer is positioned over the semiconductor layer. The semiconductor layer includes a region overlapping with the conductive layer with the second insulating layer therebetween. The semiconductor layer includes a first metal oxide layer and a second metal oxide layer over the first metal oxide layer. The first metal oxide layer and the second metal oxide layer each include indium and oxygen. The film density of the first metal oxide layer is higher than that of the second metal oxide layer. The first insulating layer includes silicon, oxygen, and hydrogen. The second insulating layer includes silicon and oxygen.

### BACKGROUND OF THE INVENTION

### 1. Field of the Invention

One embodiment of the present invention relates to a semiconductor device and a method for manufacturing the semiconductor device. One embodiment of the present invention relates to a transistor and a method for manufacturing the transistor. One embodiment of the present invention relates to a semiconductor device including a transistor.

Note that one embodiment of the present invention is not limited to the above technical field. Examples of the technical field of one embodiment of the present invention include a semiconductor device, a display device, a light-emitting apparatus, a power storage device, a memory device, an electronic appliance, a lighting device, an input device (e.g., a touch sensor), an input/output device (e.g., a touch panel), driving methods thereof, and manufacturing methods thereof.

In this specification and the like, a semiconductor device means a device that utilizes semiconductor characteristics, and refers to a circuit including a semiconductor element (e.g., a transistor, a diode, or a photodiode), a device including the circuit, and the like. The semiconductor device also means any device that can function by utilizing semiconductor characteristics. For example, an integrated circuit, a chip including an integrated circuit, and an electronic component including a chip in a package are examples of the semiconductor device. In some cases, a memory device, a display device, a light-emitting apparatus, a lighting device, and an electronic appliance themselves are semiconductor devices and also include a semiconductor device.

### 2. Description of the Related Art

In recent years, a display device with high definition has been required. Devices for virtual reality (VR), augmented reality (AR), substitutional reality (SR), or mixed reality (MR) are given as examples of devices requiring high-resolution display devices and have been actively developed.

Examples of the display device include a display device including a liquid crystal element and a display device including a light-emitting element (also referred to as a light-emitting device). Examples of the light-emitting element include an organic electroluminescent (EL) element and a light-emitting diode (LED). Patent Document 1 discloses a high-resolution display device including an organic EL element.

A technique relating to a transistor using a semiconductor thin film has attracted attention. The transistor is used in a wide range of electronic devices such as an integrated circuit (IC) and a display device. As semiconductor materials usable for the transistor, silicon-based semiconductor materials have been widely used, but oxide semiconductors have been attracting attention as alternative materials.

Examples of an oxide semiconductor usable for a transistor include indium oxide and indium gallium zinc oxide. Non-Patent Document 1, Non-Patent Document 2, and Non-Patent Document 3 each disclose a thin film transistor including indium oxide.

### REFERENCES

[Patent Document 1] International Publication No. 2016/038508
[Non-Patent Document 1] Y. Magari et al., “High-mobility hydrogenated polycrystalline In₂O₃ (In₂O₃: H) thin-film transistors”, Nature Communications 13, 1078, (2022).
[Non-Patent Document 2] Dhananjay and C. W. Chu, “Realization of In₂O₃ thin film transistors through reactive evaporation process” Appl. Phys. Lett. 91, 132111 (2007).
[Non-Patent Document 3] J. Y. Lin et al., “First Demonstration of Top-Gate Enhancement-Mode ALD In₂O₃ FETs With High Thermal Budget of 600 °C for DRAM Applications”, IEEE Electron Device Letters, 45, 10, pp. 1851-1854 (2024).
[Non-Patent Document 4] Takashi Koida, “High-mobility transparent conductive film”, National Institute of Advanced Industrial Science and Technology, AIST Photovoltaic Technology Research Symposium 2019, Internet URL: https://unit.aist.go.jp/rpd-envene/PV/ja/results/2019/oral/T13.pdf

### SUMMARY OF THE INVENTION

An object of one embodiment of the present invention is to provide a semiconductor device including a transistor with high field-effect mobility. Another object is to provide a semiconductor device including a transistor with a high on-state current. Another object is to provide a semiconductor device including a transistor having a minute size. Another object is to provide a semiconductor device including a transistor having a short channel length. Another object is to provide a semiconductor device including a transistor with favorable electrical characteristics. Another object is to provide a semiconductor device that operates at high speed. Another object is to provide a semiconductor device that occupies a small area. Another object is to provide a semiconductor device having low wiring resistance. Another object is to provide a semiconductor device or a display device having low power consumption. Another object is to provide a highly reliable transistor, a highly reliable semiconductor device, or a highly reliable display device. Another object is to provide a high-resolution display device. Another object is to provide a method for manufacturing the transistor, the semiconductor device, or the display device described above. Another object is to provide a method for manufacturing a transistor, a semiconductor device, or a display device with high productivity. Another object is to provide a novel transistor, a novel semiconductor device, a novel display device, and manufacturing methods thereof.

Note that the description of these objects does not preclude the existence of other objects. One embodiment of the present invention does not necessarily achieve all of these objects. Other objects can be derived from the description of the specification, the drawings, and the claims.

One embodiment of the present invention is a semiconductor device including a semiconductor layer, a first insulating layer, a second insulating layer, and a conductive layer. The semiconductor layer is positioned over the first insulating layer. The second insulating layer is positioned over the semiconductor layer. The semiconductor layer includes a region overlapping with the conductive layer with the second insulating layer therebetween. The semiconductor layer includes a first metal oxide layer and a second metal oxide layer over the first metal oxide layer. The first metal oxide layer and the second metal oxide layer each include indium and oxygen. A film density of the first metal oxide layer is higher than a film density of the second metal oxide layer. The first insulating layer includes silicon, oxygen, and hydrogen. The second insulating layer includes silicon and oxygen.

One embodiment of the present invention is a semiconductor device including a semiconductor layer, a first insulating layer, a second insulating layer, and a conductive layer. The semiconductor layer is positioned over the first insulating layer. The second insulating layer is positioned over the semiconductor layer. The semiconductor layer includes a region overlapping with the conductive layer with the second insulating layer therebetween. The semiconductor layer includes a first metal oxide layer, a second metal oxide layer over the first metal oxide layer, and a third metal oxide layer over the second metal oxide layer. The first metal oxide layer, the second metal oxide layer, and the third metal oxide layer each include indium and oxygen. A film density of the first metal oxide layer is higher than a film density of the second metal oxide layer. A film density of the third metal oxide layer is higher than the film density of the second metal oxide layer. The first insulating layer includes silicon, oxygen, and hydrogen. The second insulating layer includes silicon and oxygen.

The semiconductor device described above preferably includes a third insulating layer. The third insulating layer preferably includes a region overlapping with the semiconductor layer with the first insulating layer therebetween. The third insulating layer preferably includes silicon and nitrogen.

In the semiconductor device described above, the third insulating layer preferably includes hydrogen. The third insulating layer preferably includes a region having a higher hydrogen concentration than the first insulating layer.

One embodiment of the present invention is a semiconductor device including a semiconductor layer, a first insulating layer, a second insulating layer, a third insulating layer, a fourth insulating layer, and a conductive layer. The second insulating layer is positioned over the first insulating layer. The semiconductor layer is positioned over the second insulating layer. The third insulating layer is positioned over the semiconductor layer. The semiconductor layer includes a region overlapping with the conductive layer with the third insulating layer therebetween. The fourth insulating layer is positioned over the semiconductor layer, the third insulating layer, and the conductive layer. The semiconductor layer includes a first metal oxide layer, a second metal oxide layer over the first metal oxide layer, and a third metal oxide layer over the second metal oxide layer. The first metal oxide layer, the second metal oxide layer, and the third metal oxide layer each include indium and oxygen. A film density of the first metal oxide layer is higher than a film density of the second metal oxide layer. A film density of the third metal oxide layer is higher than the film density of the second metal oxide layer. The second insulating layer includes silicon, oxygen, and hydrogen. The third insulating layer includes silicon and oxygen. The first insulating layer and the fourth insulating layer each include silicon and nitrogen.

In the semiconductor device described above, the semiconductor layer preferably includes a first region overlapping with the conductive layer with the second insulating layer therebetween and a pair of second regions sandwiching the first region. The fourth insulating layer preferably includes a region in contact with the second region.

In the semiconductor device described above, the first insulating layer preferably includes hydrogen. The first insulating layer preferably includes a region having a higher hydrogen concentration than the second insulating layer.

One embodiment of the present invention is a method for manufacturing a semiconductor device. In the method, a first insulating layer is formed, a semiconductor layer is formed over the first insulating layer, and first heat treatment is performed on the first insulating layer and the semiconductor layer. The first insulating layer is formed using a gas including a silicon element, an oxygen element, and a hydrogen element. A first metal oxide layer and a second metal oxide layer are formed in this order to form the semiconductor layer. The first metal oxide layer and the second metal oxide layer are each formed by a sputtering method. For the formation of each of the first metal oxide layer and the second metal oxide layer, an indium oxide target is used, and oxygen and argon are used as film formation gases. A power density at the time of the formation of the first metal oxide layer is higher than a power density at the time of the formation of the second metal oxide layer. A temperature of the first heat treatment is higher than or equal to 150 °C and lower than or equal to 670 °C.

In the above-described method for manufacturing a semiconductor device, a gas including a hydrogen element is preferably not used as a film formation gas for the formation of each of the first metal oxide layer and the second metal oxide layer.

In the above-described method for manufacturing a semiconductor device, the film formation gas for the formation of each of the first metal oxide layer and the second metal oxide layer preferably consists of oxygen and argon.

In the above-described method for manufacturing a semiconductor device, the first insulating layer is preferably not heated in the formation of each of the first metal oxide layer and the second metal oxide layer.

In the above-described method for manufacturing a semiconductor device, the semiconductor layer is preferably crystallized by the first heat treatment.

In the above-described method for manufacturing a semiconductor device, a pressure at the time of the formation of the first metal oxide layer is preferably lower than a pressure at the time of the formation of the second metal oxide layer.

In the above-described method for manufacturing a semiconductor device, a second insulating layer is preferably formed before the formation of the first insulating layer. The second insulating layer is preferably formed using a gas including a silicon element and a nitrogen element.

In the above-described method for manufacturing a semiconductor device, a third insulating layer is preferably formed over the semiconductor layer after the first heat treatment. The first insulating layer, the second insulating layer, the third insulating layer, and the semiconductor layer are preferably subjected to second heat treatment. The third insulating layer is preferably formed using a gas including a silicon element, an oxygen element, and a hydrogen element. A temperature of the second heat treatment is preferably higher than or equal to 300 °C and lower than or equal to 500 °C.

In the above-described method for manufacturing a semiconductor device, a conductive layer is preferably formed over the third insulating layer after the second heat treatment. A fourth insulating layer is preferably formed over the semiconductor layer, the third insulating layer, and the conductive layer. The fourth insulating layer is preferably formed using a gas including a silicon element and a nitrogen element.

In the above-described method for manufacturing a semiconductor device, the first metal oxide layer, the second metal oxide layer, and a third metal oxide layer are preferably formed in this order to form the semiconductor layer. The third metal oxide layer is preferably formed by a sputtering method. For the formation of the third metal oxide layer, an indium oxide target is preferably used, and oxygen and argon are preferably used as film formation gases. A power density at the time of the formation of the third metal oxide layer is preferably higher than the power density at the time of the formation of the second metal oxide layer.

In the above-described method for manufacturing a semiconductor device, a pressure at the time of the formation of the third metal oxide layer is preferably lower than the pressure at the time of the formation of the second metal oxide layer.

One embodiment of the present invention is a semiconductor device that includes a semiconductor layer, a first insulating layer, a second insulating layer, and a conductive layer. The semiconductor layer includes a region in contact with a top surface of the first insulating layer. The second insulating layer is positioned over the semiconductor layer. The semiconductor layer includes a region overlapping with the conductive layer with the second insulating layer therebetween. The semiconductor layer includes indium and oxygen. The first insulating layer includes silicon, oxygen, and hydrogen. In the first insulating layer, the amount of desorbed hydrogen molecules is greater than or equal to 1.2×10¹³ molecules/cm² and less than or equal to 8.0×10¹³ molecules/cm² in the thermal desorption spectroscopy in which the surface temperature of the first insulating layer is higher than or equal to 50 °C and lower than or equal to 350 °C.

In the above semiconductor device, the semiconductor layer preferably includes a first metal oxide layer and a second metal oxide layer over the first metal oxide layer. A film density of the first metal oxide layer is preferably higher than a film density of the second metal oxide layer.

In the above semiconductor device, the semiconductor layer preferably includes a first metal oxide layer, a second metal oxide layer over the first metal oxide layer, and a third metal oxide layer over the second metal oxide layer. The film density of the first metal oxide layer is preferably higher than the film density of the second metal oxide layer. A film density of the third metal oxide layer is preferably higher than the film density of the second metal oxide layer.

One embodiment of the present invention is a method for manufacturing a semiconductor device. In the method, a first insulating layer is formed, a semiconductor layer is formed over the first insulating layer, and first heat treatment is performed on the first insulating layer and the semiconductor layer. The first insulating layer is formed using a gas including a silicon element, an oxygen element, and a hydrogen element. In the first insulating layer, the amount of desorbed hydrogen molecules is greater than or equal to 1.2×10¹³ molecules/cm² and less than or equal to 8.0×10¹³ molecules/cm² in the thermal desorption spectroscopy in which the surface temperature of the first insulating layer is higher than or equal to 50 °C and lower than or equal to 350 °C. The semiconductor layer is formed by a sputtering method. For the formation of the semiconductor layer, an indium oxide target is used, and oxygen and argon are used as film formation gases. A temperature of the first heat treatment is higher than or equal to 150 °C and lower than or equal to 670 °C.

In the above-described method for manufacturing a semiconductor device, a gas including a hydrogen element is preferably not used as a film formation gas in the formation of the semiconductor layer.

In the above-described method for manufacturing a semiconductor device, the film formation gas for the formation of the semiconductor layer preferably consists of oxygen and argon.

In the above-described method for manufacturing a semiconductor device, the semiconductor layer is preferably crystallized by the first heat treatment.

In the above-described method for manufacturing a semiconductor device, the first insulating layer is preferably subjected to second heat treatment before the formation of the semiconductor layer. A temperature of the second heat treatment is preferably higher than or equal to 150 °C and lower than or equal to 670 °C.

In the above-described method for manufacturing a semiconductor device, the first metal oxide layer and the second metal oxide layer are preferably formed in this order to form the semiconductor layer. A power density at the time of the formation of the first metal oxide layer is preferably higher than a power density at the time of the formation of the second metal oxide layer.

In the above-described method for manufacturing a semiconductor device, a pressure at the time of the formation of the first metal oxide layer is preferably lower than a pressure at the time of the formation of the second metal oxide layer.

In the above-described method for manufacturing a semiconductor device, the first metal oxide layer, the second metal oxide layer, and a third metal oxide layer are preferably formed in this order to form the semiconductor layer. A power density at the time of the formation of the third metal oxide layer is preferably higher than the power density at the time of the formation of the second metal oxide layer.

In the above-described method for manufacturing a semiconductor device, a pressure at the time of the formation of the third metal oxide layer is preferably lower than the pressure at the time of the formation of the second metal oxide layer.

One embodiment of the present invention can provide a semiconductor device including a transistor with high field-effect mobility. A semiconductor device including a transistor with a high on-state current can be provided. A semiconductor device including a transistor having a minute size can be provided. A semiconductor device including a transistor having a short channel length can be provided. A semiconductor device including a transistor with favorable electrical characteristics can be provided. A semiconductor device which operates at high speed can be provided. A semiconductor device that occupies a small area can be provided. A semiconductor device having low wiring resistance can be provided. A semiconductor device or a display device having low power consumption can be provided. A highly reliable transistor, a highly reliable semiconductor device, or a highly reliable display device can be provided. A high-resolution display device can be provided. A method for manufacturing the transistor, the semiconductor device, or the display device described above can be provided. A method for manufacturing a transistor, a semiconductor device, or a display device with high productivity can be provided. A novel transistor, a novel semiconductor device, a novel display device, and manufacturing methods thereof can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

In the accompanying drawings:

FIG. 1A is a top view showing an example of a semiconductor device, and FIGS. 1B and 1C are cross-sectional views showing the example of the semiconductor device;

FIGS. 2A and 2B are cross-sectional views showing an example of a semiconductor device;

FIGS. 3A to 3C are cross-sectional views showing an example of a semiconductor device;

FIGS. 4A and 4B are cross-sectional views showing an example of a semiconductor device;

FIGS. 5A and 5B are cross-sectional views showing an example of a semiconductor device;

FIGS. 6A to 6D are cross-sectional views showing examples of a semiconductor device;

FIG. 7A is a top view showing an example of a semiconductor device, and FIG. 7B is a cross-sectional view showing the example of the semiconductor device;

FIG. 8A is a top view showing an example of a semiconductor device, and FIGS. 8B and 8C are cross-sectional views each showing the example of the semiconductor device;

FIGS. 9A to 9E are cross-sectional views showing an example of a method for manufacturing a semiconductor device;

FIGS. 10A to 10D are cross-sectional views showing an example of a method for manufacturing a semiconductor device;

FIG. 11 is a cross-sectional view showing an example of a method for manufacturing a semiconductor device;

FIGS. 12A and 12B each show dependence of Hall mobility on carrier concentration, and FIG. 12C is a cross-sectional view showing an indium oxide film;

FIG. 13A is a perspective view showing an example of a display device, and FIGS. 13B and 13C are circuit diagrams showing examples of a subpixel;

FIGS. 14A and 14B are circuit diagrams showing examples of a subpixel;

FIGS. 15A and 15B are cross-sectional views showing examples of a display device;

FIG. 16 is a cross-sectional view showing an example of a display device;

FIG. 17 is a cross-sectional view showing an example of a display device;

FIGS. 18A to 18C are cross-sectional views showing examples of a display device;

FIGS. 19A and 19B are cross-sectional views showing examples of a display device;

FIGS. 20A and 20B are cross-sectional views showing examples of a display device;

FIG. 21 is a cross-sectional view showing an example of a display device;

FIG. 22 is a cross-sectional view showing an example of a display device;

FIG. 23 is a cross-sectional view showing an example of a display device;

FIGS. 24A to 24D show examples of electronic appliances;

FIGS. 25A to 25F show examples of electronic appliances;

FIGS. 26A to 26G show examples of electronic appliances;

FIGS. 27A and 27B show I_{d}-V_{g} characteristics of transistors in Example;

FIGS. 28A and 28B show I_{d}-V_{g} characteristics of transistors in Example;

FIGS. 29A and 29B show I_{d}-V_{g} characteristics of transistors in Example;

FIG. 30 shows reliability of transistors in Example;

FIGS. 31A to 31C show TDS measurement results of samples in Example;

FIGS. 32A and 32B show TDS measurement results of samples in Example;

FIGS. 33A and 33B show I_{d}-V_{g} characteristics of transistors in Example;

FIGS. 34A to 34D show SIMS measurement results of samples in Example; and

FIG. 35 shows SIMS measurement results of samples in Example.

### DETAILED DESCRIPTION OF THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in the structures of the invention described below, the same portions or portions having similar functions are denoted by the same reference numerals in different drawings, and description of such portions is not repeated. The same hatching pattern is used for portions having similar functions, and the portions are not denoted by specific reference numerals in some cases.

The position, size, range, or the like of each component shown in drawings does not represent the actual position, size, range, or the like in some cases for easy understanding. Thus, the disclosed invention is not necessarily limited to the position, size, range, or the like disclosed in the drawings.

Ordinal numbers such as “first” and “second” in this specification and the like are used in order to avoid confusion among components and thus do not limit the number of components or the order of components (e.g., the order of steps or the stacking order of layers). A term without an ordinal number in this specification and the like may be described with an ordinal number in a claim in order to avoid confusion among components. A term with an ordinal number in this specification and the like may be described with a different ordinal number in a claim. A term with an ordinal number in this specification and the like may be described without an ordinal number in a claim.

In this specification, the drawings, and the like, when a plurality of components are denoted by the same reference numeral, and, particularly when they need to be distinguished from each other, identification signs such as “_1”, “[n]” or “[m,n]” are sometimes added to the reference numeral, for example. When matters common to a plurality of components with identification signs are described or when they do not need to be distinguished from each other, no identification sign is added in some cases.

Note that the terms a “film” and a “layer” can be interchanged with each other depending on the case or circumstances. For example, the term “conductive layer” can be replaced with the term “conductive film”. As another example, the term “insulating film” can be replaced with the term “insulating layer”.

A transistor is a kind of semiconductor element and enables amplification of a current or a voltage, a switching operation for controlling conduction or non-conduction, and the like. A transistor in this specification includes, in its category, an insulated-gate field-effect transistor (IGFET) and a thin film transistor (TFT).

The functions of a “source” and a “drain” are sometimes replaced with each other when a transistor of different polarity is used or when the direction of current flow is changed in a circuit operation, for example. Thus, the terms “source” and “drain” can be used interchangeably in this specification and the like. Note that the source and the drain of a transistor can also be referred to as a source terminal and a drain terminal or a source electrode and a drain electrode, for example, as appropriate depending on the situation.

A “gate” and a “back gate” can be interchanged with each other. Thus, the terms “gate” and “back gate” can be used interchangeably in this specification and the like. Note that the gate and the back gate of a transistor can also be referred to as a gate electrode and a back gate electrode, for example, as appropriate depending on the situation.

The expression “connection” in this specification includes “electrical connection”, for example. Note that the expression “electrical connection” is used in some cases to specify the connection relation of a circuit element as an object. The term “electrical connection” includes “direct connection” and “indirect connection”. The expression “A and B are directly connected” means that A and B are connected to each other without a circuit element (e.g., a transistor or a switch; a wiring is not a circuit element) therebetween. By contrast, the expression “A and B are indirectly connected” means that A and B are connected to each other with at least one circuit element therebetween. Note that A and B each denote an object such as an element, a circuit, a wiring, an electrode, a terminal, a semiconductor layer, or a conductive layer.

For example, assuming that a circuit including A and B is in operation, the circuit can be specified as “A and B are indirectly connected” as an object when electric signal transmission and reception or potential interaction between A and B occurs at some point during the operation period of the circuit. Note that even when neither electric signal transmission and reception nor potential interaction between A and B occurs at some point during the operation period of the circuit, the circuit can be specified as “A and B are indirectly connected” as long as electric signal transmission and reception or potential interaction between A and B occurs at another point during the operation period of the circuit.

Examples of the case where the expression “A and B are indirectly connected” can be used include the case where A and B are connected to each other through a source and a drain of at least one transistor. By contrast, examples of the case where the expression “A and B are indirectly connected” cannot be used include the case where an insulator is present on the path from A to B. Specific examples thereof include the case where a capacitor is connected between A and B and the case where a gate insulating film of a transistor or the like is present between A and B. In such cases, the expression “a gate (A) of a transistor and a source or a drain (B) of the transistor are indirectly connected” cannot be used.

Another example of the case where the expression “A and B are indirectly connected” cannot be used is the case where a plurality of transistors are connected through their sources and drains on the path from A to B and a constant potential V is supplied from a power source, GND, or the like to a node between one of the transistors and another one of the transistors.

Unless otherwise specified, an on-state current in this specification and the like refers to a drain current (also referred to as I_{d}) of a transistor in an on state (also referred to as a conduction state). Unless otherwise specified, the on state of an n-channel transistor means that a voltage between its gate and source (also referred to as a gate voltage, V_{g}, or V_{gs}) is higher than or equal to the threshold voltage (also referred to as Vₜₕ), and the on state of a p-channel transistor means that a voltage between its gate and source is lower than or equal to Vₜₕ.

Unless otherwise specified, an off-state current in this specification and the like refers to a leakage current between a source and a drain generated when a transistor is in an off state (also referred to as a non-conduction state or a cutoff state). Unless otherwise specified, the off state of an n-channel transistor means that a voltage between its gate and source is lower than the threshold voltage, and the off state of a p-channel transistor means that a voltage between its gate and source is higher than Vₜₕ.

In this specification and the like, the term “parallel” indicates that the angle formed between two straight lines is greater than or equal to −10° and less than or equal to 10°. Thus, the case where the angle is greater than or equal to −5° and less than or equal to 5° is also included. The term “substantially parallel” indicates that the angle formed between two straight lines is greater than or equal to −30° and less than or equal to 30°. The term “perpendicular” indicates that the angle formed between two straight lines is greater than or equal to 80° and less than or equal to 100°. Thus, the case where the angle is greater than or equal to 85° and less than or equal to 95° is also included. The term “substantially perpendicular” indicates that the angle formed between two straight lines is greater than or equal to 60° and less than or equal to 120°.

In this specification and the like, a top surface shape of a component means the outline of the component in a top view (a plan view). A top view means that the component is observed from a direction normal to a formation surface of the component or from a direction normal to a surface of a support (e.g., a substrate) where the component is formed.

In this specification and the like, the expression “having the same top surface shape” or “having substantially the same top surface shapes” means that the outlines of stacked layers at least partly overlap with each other. For example, the case of patterning an upper layer and a lower layer with the use of the same mask pattern or mask patterns that are partly the same is included. The expression “having the same top surface shape” or “having substantially the same top surface shapes” is also sometimes used in the case where the outlines do not completely overlap with each other; for instance, the outline of the upper layer may be positioned inward or outward from the outline of the lower layer. The state of “having the same top surface shape” or “having substantially the same top surface shapes” can be rephrased as the state where “end portions are aligned with each other” or “end portions are substantially aligned with each other”.

In this specification and the like, a tapered shape refers to a shape such that at least part of a side surface of a component is inclined with respect to a substrate surface or a formation surface of the component. Furthermore, the angle between the inclined side surface and the substrate surface or the formation surface is referred to as a taper angle in some cases.

In this specification and the like, step disconnection refers to a phenomenon in which a layer, a film, or an electrode is split because of the shape of its formation surface (e.g., a step).

In this specification and the like, the term “island shape” refers to a state where two or more layers formed using the same material in the same step are physically separated from each other. For example, the term “island-shaped metal oxide layer” refers to a state where the metal oxide layer and the adjacent metal oxide layer are physically separated from each other.

In this specification and the like, a device manufactured using a metal mask or a fine metal mask (FMM, a high-resolution metal mask) is sometimes referred to as a device having a metal mask (MM) structure. In this specification and the like, a device manufactured without using a metal mask or an FMM may be referred to as a device having a metal maskless (MML) structure.

In this specification and the like, a structure in which light-emitting layers of light-emitting elements (also referred to as light-emitting devices) having different emission wavelengths are separately formed may be referred to as a side-by-side (SBS) structure.

In this specification and the like, a hole or an electron is sometimes referred to as a carrier. For example, in a light-emitting element, a hole-injection layer or an electron-injection layer may be referred to as a carrier-injection layer, a hole-transport layer or an electron-transport layer may be referred to as a carrier-transport layer, and a hole-blocking layer or an electron-blocking layer may be referred to as a carrier-blocking layer. Note that in some cases, the above-described carrier-injection layer, carrier-transport layer, and carrier-blocking layer cannot be distinguished from each other. One layer may have two or three functions of the carrier-injection layer, the carrier-transport layer, and the carrier-blocking layer in some cases.

In this specification and the like, a light-emitting element includes an EL layer between a pair of electrodes (a first electrode and a second electrode). The light-emitting element includes the first electrode, the EL layer over the first electrode, and the second electrode over the EL layer. The EL layer includes at least a light-emitting layer. Examples of layers (also referred to as functional layers) in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, a light-receiving element (also referred to as a light-receiving device) includes at least an active layer functioning as a photoelectric conversion layer between a pair of electrodes. In this specification and the like, one of the first electrode and the second electrode may be referred to as a pixel electrode and the other may be referred to as a common electrode.

In this specification and the like, flexibility refers to a property of an object being flexible and bendable. In other words, it is a property of an object that can be deformed in response to an external force applied to the object, and elasticity or restorability to the former shape is not taken into consideration.

For example, an electronic appliance having flexibility, a display device having flexibility (also referred to as a flexible display or the like), a battery having flexibility (also referred to as a flexible battery or the like), and a substrate having flexibility (also referred to as a flexible substrate or the like) can be deformed in response to an external force. The electronic appliance having flexibility, the display device having flexibility, the battery having flexibility, and the substrate having flexibility can be used with their shape fixed in a state of being deformed, can be used while repeatedly deformed, and can be used in a state of not deformed. Note that the expression “deformed in response to an external force” above means being deformed without requiring an excessive force by the average adult's hand. Note that the flexibility can be evaluated with a tester (e.g., a tensile tester or a compressive tester) capable of stress-distortion measurement. In the stress-distortion measurement, an external force is applied to an object, and a distortion of the object caused by the stress due to the external force is measured, whereby the flexibility of the object can be quantified.

In this specification and the like, the expression “an object has flexibility” means that at least part of the object has flexibility. That is, the flexible object may include a portion that is not flexible.

### Embodiment 1

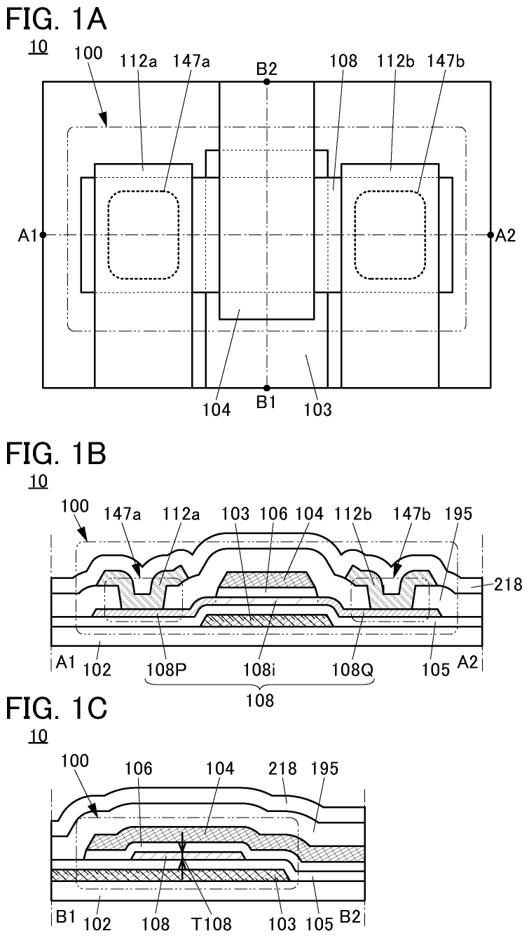

In this embodiment, a semiconductor device of one embodiment of the present invention will be described with reference to FIGS. 1A to 1C, FIGS. 2A and 2B, FIGS. 3A to 3C, FIGS. 4A and 4B, FIGS. 5A and 5B, FIGS. 6A to 6D, FIGS. 7A and 7B, FIGS. 8A to 8C, FIGS. 9A to 9E, FIGS. 10A to 10D, and FIG. 11. A semiconductor device of one embodiment of the present invention can be suitably used in one or both of a pixel circuit and a driver circuit of a display device, for example.

### Structure Example 1

FIG. 1A shows a top view (also referred to as a plan view) of a semiconductor device 10 of one embodiment of the present invention. FIG. 1B is a cross-sectional view taken along the dashed-dotted line A1-A2 in FIG. 1A, and FIG. 1C is a cross-sectional view taken along the dashed-dotted line B1-B2 in FIG. 1A. Note that in FIG. 1A, some components of the semiconductor device 10 (e.g., a gate insulating layer) are not shown. As in FIG. 1A, some components are not shown in top views of the semiconductor device described below.

The semiconductor device 10 includes a transistor 100. The transistor 100 includes a conductive layer 103 over a substrate 102, an insulating layer 105 over the conductive layer 103, a semiconductor layer 108 over the insulating layer 105, an insulating layer 106 over the semiconductor layer 108, and a conductive layer 104 over the insulating layer 106. The conductive layer 104 has a region overlapping with the semiconductor layer 108 with the insulating layer 106 therebetween. In the transistor 100, the conductive layer 104 functions as a first gate electrode, and the insulating layer 106 functions as a first gate insulating layer. The conductive layer 103 has a region overlapping with the semiconductor layer 108 with the insulating layer 105 therebetween. The conductive layer 103 includes a region overlapping with the conductive layer 104 with the insulating layer 105, the semiconductor layer 108, and the insulating layer 106 therebetween. In the transistor 100, the conductive layer 103 functions as a second gate electrode, and the insulating layer 105 functions as a second gate insulating layer. Note that a structure in which the conductive layer 103 is not provided can also be employed.

The semiconductor layer 108 includes a region 108i overlapping with the conductive layer 104 with the insulating layer 106 therebetween and includes a pair of regions (a region 108P and a region 108Q) between which the region 108i is sandwiched. The region 108P and the region 108Q do not overlap with the conductive layer 104. In the transistor 100, the region 108i functions as a channel formation region, the region 108P functions as one of a source region and a drain region, and the region 108Q functions as the other of the source region and the drain region.

In the semiconductor layer 108, the length of a region positioned between the source region and the drain region and overlapping with the conductive layer 104 with the insulating layer 106 therebetween is the channel length of the transistor 100. The width of a region where the semiconductor layer 108 overlaps with the conductive layer 104 in a direction orthogonal to the channel length direction is the channel width of the transistor 100.

Note that a region of the semiconductor layer 108 that overlaps with at least one of the conductive layer 104 and the conductive layer 103 functions as a channel formation region. Here, for easy explanation, a region of the semiconductor layer 108 that overlaps with the conductive layer 104 is sometimes referred to as the channel formation region; however, a region that does not overlap with the conductive layer 104 but overlaps with the conductive layer 103 can also function as the channel formation region.

The transistor 100 includes gate electrodes (the first gate electrode and the second gate electrode) on the opposite sides with a channel formation region therebetween, and can be referred to as a dual-gate transistor. Note that one of the first gate electrode and the second gate electrode may be referred to as a front gate electrode (also simply referred to as a gate electrode), and the other may be referred to as a back gate electrode. One of the first gate insulating layer and the second gate insulating layer is referred to as a front gate insulating layer (also simply referred to as a gate insulating layer), and the other is referred to as a back gate insulating layer in some cases.

The conductive layer 103 preferably includes a region protruding beyond the end portion of the conductive layer 104. In this case, it is possible to enhance the effect that an electric field generated outside the transistor is blocked by the conductive layer 103 and is less likely to act on the channel formation region (also referred to as an electric field blocking effect).

Providing the back gate electrode enables the potential on the back gate electrode side (also referred to as back channel side) of the semiconductor layer 108 to be fixed, so that the saturation of the I_{d}-V_{d} characteristics can be improved. Fixing the potential on the back channel side of the semiconductor layer 108 can inhibit a shift in the threshold voltage. This enables reduction in a drain current which flows at a gate voltage (V_{g}) of 0 V (hereinafter also referred to as a cut-off current), so that a normally-off transistor can be obtained. Accordingly, a semiconductor device with low power consumption can be provided. Note that in the following description, the conductive layer 104 is referred to as a gate electrode and the conductive layer 103 is referred to as a back gate electrode in some cases.

The semiconductor layer 108 preferably includes a metal oxide exhibiting semiconductor characteristics (also referred to as an oxide semiconductor). Examples of the metal oxide include indium oxide, gallium oxide, and zinc oxide. The band gap of the metal oxide is preferably larger than or equal to 2.0 eV, further preferably larger than or equal to 2.5 eV. A transistor including an oxide semiconductor (hereinafter referred to as an OS transistor) has much higher field-effect mobility than a transistor including amorphous silicon. In addition, the OS transistor has an extremely low off-state current, and charge accumulated in a capacitor that is connected in series to the transistor can be held for a long period. Furthermore, the power consumption of the semiconductor device can be reduced with the OS transistor. Note that in the case where an oxide semiconductor is used for a semiconductor layer, the semiconductor layer can be referred to as an oxide semiconductor layer or a metal oxide layer.

Note that the metal oxide preferably includes at least indium. In addition, the indium content percentage in the metal oxide is preferably high. When a metal oxide having a high indium content percentage is used in the semiconductor layer, the transistor can have a high on-state current. Thus, a semiconductor device that operates at high speed can be obtained. When the semiconductor device of one embodiment of the present invention is used for a display device, the display device can operate at high speed and have high display quality. In addition, a transistor using a metal oxide having a high indium content percentage has high field-effect mobility; thus, a high on-state current can be obtained even with a small channel width. Accordingly, the area occupied by the transistor can be reduced, leading to a reduction in the area occupied by the semiconductor device. When the semiconductor device of one embodiment of the present invention is used for a pixel circuit of a display device, the area occupied by the pixel circuit can be reduced and the display device can have high resolution. When the semiconductor device of one embodiment of the present invention is used for a driver circuit (e.g., one or both of a gate line driver circuit and a source line driver circuit) of a display device, the area occupied by the driver circuit can be reduced and the display device can have a narrow bezel.

In this specification and the like, the proportion of the number of indium atoms in the total number of atoms of all the metal elements contained is sometimes referred to as the indium content percentage. The same applies to other metal elements.

The semiconductor layer 108 preferably includes indium and oxygen. For example, indium oxide (also referred to as IO) can be suitably used for the semiconductor layer 108.

There is no particular limitation on the crystallinity of a semiconductor material used for the semiconductor layer 108, and any of an amorphous semiconductor, a single-crystalline semiconductor, and a semiconductor having other crystallinity than single crystal (a microcrystalline semiconductor, a polycrystalline semiconductor, or a semiconductor partly including crystal regions) can be used.

The semiconductor layer 108 preferably has crystallinity. An oxide semiconductor having crystallinity is preferably used for the semiconductor layer 108, in which case deterioration of the transistor characteristics can be suppressed. The semiconductor layer 108 preferably has high crystallinity; the semiconductor layer 108 is preferably polycrystalline or single-crystalline. For example, as the semiconductor layer 108, a polycrystalline indium oxide film is preferably used, and a single-crystalline indium oxide film is further preferably used. Note that indium oxide having a crystal grain may be referred to as crystal indium oxide (crystal IO) or crystalline indium oxide (crystalline IO) in some cases. The crystal of In₂O₃ typically has a cubic structure (bixbyite type).

A single-crystalline film, which does not have a crystal grain boundary, can inhibit carrier scattering at crystal grain boundary to enable a transistor having high field-effect mobility, and thus is particularly preferable. A polycrystalline film less causes carrier scattering than a microcrystalline film and an amorphous film and thus enables the transistor having high field-effect mobility. In the case where a polycrystalline film is used as the semiconductor layer 108, the grain size (hereinafter also referred to as crystal grain size) of the crystal grain included in the semiconductor layer 108 is preferably large. With the use of a polycrystalline film having a large crystal grain size, the number of crystal grain boundaries positioned in the channel formation region can be reduced and the length of each of the crystal grain boundaries positioned in the channel formation region can be shortened, so that the transistor can have high field-effect mobility. In addition, the number of crystal grain boundaries intersecting with the direction in which a drain current flows (also referred to as channel length direction) in the channel formation region is preferably small. Note that even a polycrystalline film can have an effect similar to that by a single-crystalline film as long as the crystal grain boundary is not positioned in a channel formation region.

In the case where a non-single-crystalline film (e.g., a polycrystalline film) is used as the semiconductor layer 108, the barrier height at the crystal grain boundary is preferably low. When the barrier height at the crystal grain boundary is low, the influence of grain boundary scattering is small; thus, a transistor with high field-effect mobility can be obtained. In general, the barrier height at the crystal grain boundary of low-temperature polysilicon (LTPS) is 60 meV to 80 meV. In the case where a polycrystalline metal oxide is used for the semiconductor layer 108, the barrier height at the crystal grain boundary of the polycrystalline metal oxide is preferably lower than that of LTPS. For example, the barrier height at the crystal grain boundary of the metal oxide is preferably greater than 0 meV and less than 60 meV, further preferably greater than 0 meV and less than or equal to 55 meV, still further preferably greater than 0 meV and less than or equal to 50 meV. Note that the barrier height at the crystal grain boundary of the metal oxide is not limited to the above range. In some cases, a transistor using silicon in its channel formation region is referred to as a Si transistor and a transistor using LTPS in its channel formation region is referred to as an LTPS transistor.

The barrier height at the crystal grain boundary can be measured by Kelvin probe force microscopy (KFM), for example. Note that KFM is a kind of measurement mode of scanning probe microscopy (SPM) and enables evaluation of a potential distribution on a sample surface by scanning the sample surface with a conductive probe and detecting electrostatic force between the probe and the sample surface.

Since the metal oxide has a low barrier height at the crystal grain boundary, an OS transistor has high field-effect mobility and can operate at high speed. The OS transistor also has favorable saturation (also referred to as high constancy of a current) and low hysteresis of electrical characteristics. Thus, the OS transistor can be suitably used as both the selection transistor and the driving transistor included in the pixel circuit. When an OS transistor with favorable saturation and high current controllability is used as the driving transistor, the display device can have high display quality. Furthermore, the use of an OS transistor with low hysteresis can improve the display quality.

Note that in this specification and the like, the state where the change in a current is small in the saturation region of the I_{d}-V_{d} characteristics of a transistor is sometimes described using the expression “favorable saturation.”

The crystallinity of the semiconductor layer 108 can be analyzed with an X-ray diffraction (XRD) pattern, a transmission electron microscope (TEM) image, or an electron diffraction (ED) pattern, for example. Alternatively, these methods can be combined as appropriate to be employed for analysis.

The insulating layer 106 and the insulating layer 105 each preferably include one or more inorganic insulating layers. Examples of materials that can be used for the inorganic insulating layer include an oxide, a nitride, an oxynitride, and a nitride oxide. Examples of the oxide include silicon oxide, aluminum oxide, magnesium oxide, gallium oxide, germanium oxide, yttrium oxide, zirconium oxide, lanthanum oxide, neodymium oxide, hafnium oxide, tantalum oxide, cerium oxide, gallium zinc oxide, and hafnium aluminate. Examples of the nitride include silicon nitride and aluminum nitride. Examples of the oxynitride include silicon oxynitride, aluminum oxynitride, gallium oxynitride, yttrium oxynitride, and hafnium oxynitride. Examples of the nitride oxide include silicon nitride oxide and aluminum nitride oxide.

In this specification and the like, an oxynitride refers to a material that includes more oxygen than nitrogen in its composition. A nitride oxide refers to a material that includes more nitrogen than oxygen in its composition.

The insulating layer 105 and the insulating layer 106 each include a region in contact with the semiconductor layer 108. In the case where the semiconductor layer 108 is formed using a metal oxide, at least part of the region of the insulating layer 106 that is in contact with the semiconductor layer 108 preferably includes oxygen to improve the characteristics of the interface between the semiconductor layer 108 and the insulating layer 106. Specifically, the region of the insulating layer 106 that is in contact with the channel formation region preferably includes oxygen. One or more of an oxide and an oxynitride can be suitably used for the region of the insulating layer 106 that is in contact with the channel formation region. The same applies to the insulating layer 105. The insulating layer 106 and the insulating layer 105 each preferably include, for example, silicon and oxygen. Silicon oxide or silicon oxynitride can be suitably used for each of the insulating layer 106 and the insulating layer 105.

The insulating layer 106 and the insulating layer 105 can each be formed by a sputtering method, an atomic layer deposition (ALD) method, or a chemical vapor deposition (CVD) method. Examples of the CVD method include a plasma-enhanced chemical vapor deposition (PECVD, also referred to as a plasma CVD) method and a thermal CVD method. An example of the thermal CVD method is a metal organic CVD (MOCVD) method. The plasma CVD method can be suitably used for the formation of each of the insulating layer 106 and the insulating layer 105.

The insulating layer 105, over which the semiconductor layer 108 is formed, preferably includes hydrogen. The insulating layer 105 preferably includes silicon, oxygen, and hydrogen, for example. Silicon oxynitride including hydrogen or silicon oxide including hydrogen can be suitably used for the insulating layer 105. It is preferable to form the insulator 105 by a method using a gas including a hydrogen element as a film formation gas. In this manner, the insulating layer 105 including hydrogen can be formed.

In the case of using a plasma CVD method, a deposition gas including a silicon element and an oxidizing gas can be used as film formation gases for a silicon oxynitride film and a silicon oxide film. As the deposition gas including a silicon element, one or more of silane (SiH₄), disilane (Si₂H₆), trisilane (Si₃H₈), and tetraethoxysilane (TEOS, Si(OC₂H₅)₄) can be used, for example. These deposition gases include a hydrogen element together with a silicon element and thus can be suitably used as a film formation gas for the insulating layer 105. As the oxidizing gas, a gas including an oxygen element can be used. For example, as the oxidizing gas, one or more of oxygen (O₂), ozone (O₃), nitrous oxide (N₂O), nitric oxide (NO), and nitrogen dioxide (NO₂) can be used. In the case where a silicon oxynitride film including hydrogen is formed, a film formation gas including a silicon element, an oxygen element, a nitrogen element, and a hydrogen element can be used. Typically, SiH₄ and N₂O can be suitably used as film formation gases for a silicon oxynitride film including hydrogen. In the case of using SiH₄, N₂O is preferably used as the oxidizing gas, in which case the number of particles can be smaller than that in the case of using O₂. In the case where a silicon oxide film including hydrogen is formed, a film formation gas including a silicon element, an oxygen element, and a hydrogen element can be used. Typically, TEOS and O₂ can be suitably used as film formation gases for a silicon oxide film including hydrogen. Note that there is no particular limitation on the kind of the film formation gas for the insulating layer 105.

The semiconductor layer 108 can be formed by forming a metal oxide film over the insulating layer 105 and processing the metal oxide film into an island shape. For the formation of the metal oxide film, a sputtering method, an ALD method, or a CVD method can be used. Note that in the case where the metal oxide film is formed by a sputtering method, the composition of the formed metal oxide film may be different from that of a sputtering target. In particular, the zinc content percentage in the formed metal oxide film may be reduced to approximately 50% of that in the sputtering target. Similarly, the content percentage of another element in the formed metal oxide film may be different from that in the sputtering target.

Before the metal oxide film is processed into an island shape or after the metal oxide film is processed into an island shape, heat treatment is preferably performed. The heat treatment can increase the crystallinity of the semiconductor layer 108 and reduce defects. The heat treatment can remove an impurity included in the semiconductor layer 108 or adsorbed on its surface.

The formed metal oxide film preferably has low crystallinity and is particularly preferably amorphous. The metal oxide film having low crystallinity is crystallized by the heat treatment, so that the crystallinity of the metal oxide film can be increased. In addition, crystal grains included in the semiconductor layer 108 can be increased in grain size. For example, when the metal oxide film includes hydrogen, generation of crystal nuclei and crystal growth are inhibited, so that a metal oxide film with low crystallinity can be formed.

Here, when the hydrogen concentration in the metal oxide film is too high at the time of the formation, the semiconductor layer 108 has a high hydrogen concentration, leading to an increase in the amount of oxygen vacancies (V_{O}) in the channel formation region in some cases. A defect that is an oxygen vacancy into which hydrogen enters (hereinafter, also referred to as V_{O}H) functions as a donor and generates an electron serving as a carrier in some cases. As a result, the threshold voltage of the transistor might shift. In addition, the reliability of the transistor might be reduced. In particular, the influence of oxygen vacancies and V_{O}H in a channel formation region on electrical characteristics is more significant in a transistor with a short channel length, and the transistor is likely to be normally on. Furthermore, when a metal oxide having a high indium content percentage is used for the semiconductor layer 108 as described above, the transistor can have high field-effect mobility. However, a metal oxide having a high indium content percentage is likely to generate an oxygen vacancy, which sometimes increases the amount of oxygen vacancies and V_{O}H in the semiconductor layer 108.

The metal oxide film including hydrogen can be formed with the use of a gas including a hydrogen element (e.g., H₂) as a film formation gas for the metal oxide film. In that case, the flow rate of the gas including a hydrogen element is preferably made low. However, even with the low flow rate of the gas including a hydrogen element, the hydrogen concentration in the metal oxide film is increased, which might lead to an increase in the amount of oxygen vacancies and V_{O}H in the semiconductor layer 108. In addition, when the flow rate is low, the flow rate is difficult to control in some cases.

The metal oxide film is preferably formed by a method that does not use a gas including a hydrogen element (e.g., H₂) as a film formation gas. This can inhibit an increase in the hydrogen concentration in the metal oxide film. The metal oxide film is preferably formed by a sputtering method. The metal oxide film is preferably formed by a sputtering method using a metal target or a metal oxide target. As the film formation gas in the formation of the metal oxide film, a noble gas (such as a helium gas, an argon gas, or a xenon gas) can be used. An H₂ gas is flammable and thus requires explosion-proof actions when used. An H₂ gas is preferably not used, in which case capital investment for explosion-proof actions is not required.

In the case of using a sputtering method for the formation of the metal oxide film, a film formation gas (e.g., argon) is ionized and made to collide with the sputtering target. Accordingly, the sputtered particles ejected from the sputtering target reach the layer over which the metal oxide film is formed (here, the insulating layer 105), whereby the metal oxide film is formed. The power density in the formation of the metal oxide film is preferably high. In addition, the pressure is preferably low. In that case, the sputtered particles with high kinetic energy reach the surface of the insulating layer 105, so that part of hydrogen included in the insulating layer 105 is desorbed. Then, the hydrogen desorbed from the insulating layer 105 diffuses into the metal oxide film. As described above, without using the gas including a hydrogen element as the film formation gas for the metal oxide film, hydrogen is desorbed from the insulating layer 105 during the film formation, and the hydrogen diffuses into the metal oxide film. In this manner, the metal oxide film can include hydrogen while being prevented from having an excessively high hydrogen concentration. Then, the metal oxide film is crystallized by heat treatment to have a large crystal grain size.

Hydrogen is preferably desorbed from the insulating layer 105 by application of heat. In the formation of the metal oxide film over the insulating layer 105, application of heat allows hydrogen (e.g., a hydrogen molecule) to be desorbed from the insulating layer 105 and diffuse into the metal oxide film. This allows the formed metal oxide film to have low crystallinity, so that the metal oxide film can have a large crystal grain size by heat treatment performed later. In the heat treatment performed after the formation of the metal oxide film, hydrogen is desorbed from the insulating layer 105 and diffuses into the metal oxide film. When the heat treatment is performed on the metal oxide film including hydrogen, less crystal nuclei are generated in the metal oxide film, so that the metal oxide film can have a large crystal grain size. As described above, supplying hydrogen from the insulating layer 105 to the metal oxide film can inhibit an excessive increase in the hydrogen concentration in the metal oxide film and allows the metal oxide film to have a large crystal grain size. Note that desorption of a substance from a layer is sometimes described with the expression “the substance is released.”

The amount of hydrogen molecules desorbed from the insulating layer 105 at a surface temperature of the insulating layer 105 of higher than or equal to 50 °C and lower than or equal to 350 °C is preferably greater than 1.0×10¹³ molecules/cm² and less than 1.0×10¹⁴ molecules/cm², further preferably greater than or equal to 1.2×10¹³ molecules/cm² and less than or equal to 8.0×10¹³ molecules/cm². The amount of the desorbed hydrogen molecules is the total amount of hydrogen molecules desorbed at a surface temperature of the insulating layer 105 of higher than or equal to 50 °C and lower than or equal to 350 °C.

When the amount of hydrogen molecules desorbed from the insulating layer 105 is large, the hydrogen concentration in the metal oxide film may be increased. In such a case, treatment for reducing the hydrogen concentration in the insulating layer 105 by releasing hydrogen from the insulating layer 105 is preferably performed after the formation of the insulating layer 105 but before the formation of the metal oxide film. This can reduce the amount of hydrogen diffusing into the metal oxide film and inhibit an increase in the hydrogen concentration in the metal oxide film. As the treatment, for example, heat treatment can be suitably used. Conditions of the treatment are preferably set such that the amount of hydrogen molecules desorbed from the insulating layer 105 after the treatment for reducing the hydrogen concentration in the insulating layer 105 is within the above range. Typically, the hydrogen concentration in the insulating layer 105 can be adjusted by adjusting the temperature of the heat treatment. For example, when the temperature of the heat treatment is increased, the hydrogen concentration in the insulating layer 105 can be reduced, so that the amount of hydrogen diffusing into the metal oxide film can be reduced.

When the amount of hydrogen molecules desorbed from the insulating layer 105 is small, the crystallinity of the formed metal oxide film is increased and the crystal grain size may be reduced. In such a case, treatment for increasing the hydrogen concentration in the insulating layer 105 by supplying hydrogen to the insulating layer 105 is preferably performed after the formation of the insulating layer 105 but before the formation of the metal oxide film. This can increase the amount of hydrogen diffusing into the metal oxide film and lower the crystallinity of the formed metal oxide film. As the treatment, for example, plasma treatment can be suitably used. Plasma treatment is preferably performed in an atmosphere including a gas including a hydrogen element (e.g., H₂). Conditions of the treatment are preferably set such that the amount of hydrogen molecules desorbed from the insulating layer 105 after the treatment for increasing the hydrogen concentration in the insulating layer 105 is within the above range. Typically, the hydrogen concentration in the insulating layer 105 can be adjusted by adjusting the time of the plasma treatment. For example, when the time of the plasma treatment is increased, the hydrogen concentration in the insulating layer 105 can be increased, so that the amount of hydrogen diffusing into the metal oxide film can be increased.

The insulating layer 105 can also be formed by a method that does not use a gas including a hydrogen element as a film formation gas. For example, in the case where a silicon oxide film is formed as the insulating layer 105, a reactive sputtering method using a silicon target or a sputtering method using a silicon oxide target can be used, and oxygen and argon can be used as film formation gases. In the case where the insulating layer 105 is formed by a method that does not use a gas including a hydrogen element as a film formation gas, the hydrogen concentration in the formed insulating layer 105 is low, and thus the treatment for increasing the hydrogen concentration in the insulating layer 105 is preferably performed.

The amount of desorbed hydrogen molecules can be evaluated by the amount of desorbed H₂ (m/z (also referred to as mass-to-charge ratio)=2) in thermal desorption spectroscopy (TDS), for example. In TDS, a desorbed amount can be quantified from the detection intensity (here, the current value) of a mass spectrometer. To convert the detection intensity into the desorbed amount, a standard sample in which the desorbed amount of H₂ (m/z=2) is known can be used, for example. Note that the lower quantification limit in TDS is approximately 1.0×10¹³ molecules/cm². The amount of hydrogen molecules desorbed from the insulating layer 105 is not limited to the above range.

In the case where TDS is performed on the semiconductor device 10, layers above the insulating layer 105 are preferably removed to expose the insulating layer 105. In this embodiment, the temperature rising rate of the sample surface temperature in TDS is approximately 16 °C/min. The temperature rising rate of a stage where the sample is placed can be approximately 32 °C/min, for example. Hydrogen may diffuse from the insulating layer 105 to the metal oxide film and the semiconductor layer 108 in the manufacturing process of the semiconductor device 10 to reduce the amount of hydrogen that can be desorbed from the insulating layer 105 in the semiconductor device 10 after the manufacturing process. Thus, in the case where TDS is performed on the semiconductor device 10, the amount of desorbed hydrogen molecules is sometimes small.

The hydrogen concentration in the semiconductor layer 108 and the insulating layer 105 can be analyzed by secondary ion mass spectrometry (SIMS), for example. Note that the hydrogen concentration in the semiconductor layer 108 is not uniform in some cases. The same applies to the insulating layer 105.

When an oxygen gas is used as a film formation gas for the metal oxide film, generation of oxygen vacancies in the metal oxide film can be inhibited. Furthermore, oxygen can be supplied into the insulating layer 105 during the formation of the metal oxide film. This enables the semiconductor layer 108 to be supplied with oxygen from the insulating layer 105 in a later step, so that the amounts of oxygen vacancies and V_{O}H in the semiconductor layer 108 can be reduced. However, when the proportion of the flow rate of an oxygen gas in the flow rate of the whole film formation gas (hereinafter also referred to as oxygen flow rate ratio) in the formation of the metal oxide film is too high, the number of crystal grains included in the metal oxide film after the film formation is increased and the crystal grains included in the semiconductor layer 108 are reduced in grain size in some cases. When the amount of oxygen included in the semiconductor layer 108 is too large, shallow level density of states (sDOS) are formed in the metal oxide in some cases. When the number of sDOS increases, the S value (also referred to as subthreshold swing or SS) of the transistor increases, which might decrease the field-effect mobility. The oxygen flow rate ratio is preferably higher than 0% and lower than or equal to 10%, further preferably higher than 0% and lower than or equal to 5%, still further preferably higher than 0% and lower than or equal to 3%. When the oxygen flow rate ratio is within the above range, oxygen vacancies and V_{O}H in the semiconductor layer 108 can be reduced and the crystallinity of the formed metal oxide film can be lowered. In addition, the transistor can have a small S value and high field-effect mobility. Note that the oxygen flow rate ratio is not limited to the above range.

A noble gas and an oxygen gas can be used for the formation of the metal oxide film. As described above, a gas including a hydrogen element is preferably not used for the formation of the metal oxide film. It is preferable that part of the film formation gas for the metal oxide film be a noble gas (typically, argon) and the other part of the film formation gas be an oxygen gas.

A thickness T108 of the channel formation region of the semiconductor layer 108 is preferably larger than or equal to 1 nm and smaller than or equal to 50 nm, further preferably larger than or equal to 1 nm and smaller than or equal to 40 nm, still further preferably larger than or equal to 1 nm and smaller than or equal to 30 nm, yet still further preferably larger than or equal to 1 nm and smaller than or equal to 20 nm, yet still further preferably larger than or equal to 1 nm and smaller than or equal to 10 nm. By increasing the thickness T108, the transistor can have a high on-state current. However, when the thickness T108 is too large, oxygen vacancies and V_{O}H in the semiconductor layer 108 are increased, so that the transistor becomes normally on in some cases. In addition, the reliability may be lowered. The crystal grain included in the semiconductor layer 108 is reduced in grain size in some cases. When the thickness T108 is within the above range, the transistor can have favorable electrical characteristics and high reliability. In a cross-sectional view, the thickness T108 can be the shortest distance between the top surface of the semiconductor layer 108 and the formation surface of the semiconductor layer 108 (here, the top surface of the insulating layer 105) in a region of the semiconductor layer 108 overlapping with the conductive layer 104. In FIG. 1C, the thickness T108 is indicated by a solid arrow. Note that the thickness T108 is not limited to being within the above range.

The grain size of the crystal grain included in the semiconductor layer 108 can be analyzed with a transmission electron microscope (TEM), a scanning transmission electron microscope (STEM), or an electron backscatter diffraction pattern (EBSD or EBSP), for example. Alternatively, these methods can be combined as appropriate to be employed for analysis. As the grain size, for example, the average of the grain sizes of a plurality of crystal grains can be used. The grain size of the crystal grain can be, for example, the diameter of a circle that has the same as the crystal grain. The diameter here is sometimes referred to as an equivalent circular area diameter or the like. The cubic crystal structure of In₂O₃ belongs to a space group Ia-3 (space group number 206), for example.

Note that in this specification and the like, a crystal grain boundary refers to a boundary between adjacent crystal grains with different crystal orientations, for example. Thus, in this specification and the like, a crystal grain boundary does not include a boundary between adjacent crystal grains with the same crystal orientation. For example, in the case where a boundary is observed between two crystal grains in a TEM image but the crystal orientations of the two crystal grains are aligned or substantially aligned with each other, the boundary is not referred to as a crystal grain boundary in some cases. In addition, in the case where a difference in crystal orientation between adjacent measurement points is small (e.g., in the case where the difference in crystal orientation is less than) 5° in EBSD, these measurement points can be regarded as belonging to the same crystal grain.

In this specification and the like, a space group is represented using the short symbol of the international notation (or the Hermann-Mauguin notation). In addition to this, a space group number in International Tables for Crystallography Volume A (hereinafter also referred to as ITA) is sometimes described. The Miller index is used for the expression of crystal planes and crystal orientations. In the crystallography, a bar is placed over a number in the expression of space groups, crystal planes, and crystal orientations; in this specification and the like, because of format limitations, space groups, crystal planes, and crystal orientations are sometimes expressed by placing a minus sign (−) in front of a number instead of placing a bar over the number. Furthermore, an individual direction that shows an orientation in crystal is denoted by “[ ]”, a set direction that shows all of the equivalent orientations is denoted by “< >”, an individual plane that shows a crystal plane is denoted by “( )”, and a set plane having equivalent symmetry is denoted by “{ }”. Even when the same space group number is used, the expression of a space group differs depending on the way of determining a crystal axis in some cases.

The grain size of the crystal grain can also be observed with an optical microscope or a scanning electron microscope (SEM), for example. When etchants with different etching rates depending on crystal planes or crystallinity are used, unevenness in the surface of the semiconductor layer 108 is caused, in which case the crystal grains can be easily observed also with an optical microscope or a SEM. In the case where an indium oxide film is used as the semiconductor layer 108, an etchant including acid can be used to make an observation of a crystal grain of indium oxide easy. As the acid, one or more kinds of phosphoric acid, oxalic acid, hydrofluoric acid, nitric acid, and hydrochloric acid can be used, for example. When the etching amount is too large, part of the semiconductor layer 108 is eliminated and the crystal grain is not easily observed in some cases. Thus, the etching amount is preferably adjusted depending on the kind, concentration, temperature, and treatment time of the etchant so that the semiconductor layer 108 does not disappear and has a small thickness (also referred to as half etching). By performing the half etching, crystal grains can be easily observed.

Note that in the case where the thickness T108 is small, the crystallinity and the grain size of the crystal grain of the semiconductor layer 108 are difficult to evaluate in some cases.

FIG. 1B and the like show a structure in which an end portion of the insulating layer 106 is aligned with an end portion of the conductive layer 104. The end portion of the insulating layer 106 is positioned over the semiconductor layer 108. The insulating layer 106 overlaps with neither the region 108P nor the region 108Q. It can be said that the top surface shape of the insulating layer 106 is aligned or substantially aligned with that of the conductive layer 104. The insulating layer 106 can be formed with the use of a resist mask for processing the conductive layer 104, for example. Note that a structure where the end portion of the insulating layer 106 is not aligned with the end portion of the conductive layer 104 can also be employed.

An insulating layer 195 is provided over the semiconductor layer 108, the insulating layer 106, and the conductive layer 104. The insulating layer 195 includes regions in contact with the top surface and the side surface of the semiconductor layer 108, the side surface of the insulating layer 106, and the top surface and the side surface of the conductive layer 104. The insulating layer 195 includes regions in contact with the region 108P and the region 108Q and has an opening portion 147a reaching the region 108P and an opening portion 147b reaching the region 108Q. A conductive layer 112a and a conductive layer 112b are formed to cover the opening portion 147a and the opening portion 147b, respectively. The conductive layer 112a is in contact with the region 108P in the opening portion 147a and is connected to the region 108P. The conductive layer 112b is in contact with the region 108Q in the opening portion 147b and is connected to the region 108Q.

The conductive layer 112a functions as one of a source electrode and a drain electrode of the transistor 100, and the conductive layer 112b functions as the other of the source electrode and the drain electrode.

The conductive layer 104 is positioned above the semiconductor layer 108 and can be referred to as a top gate. When an impurity is supplied to the semiconductor layer 108 with the conductive layer 104 used as a mask, the region 108P and the region 108Q serving as the source region and the drain region can be formed in a self-aligned manner. The transistor 100 can be referred to as a top-gate self-aligned (TGSA) transistor.

In the TGSA transistor, the physical distance between the conductive layer 104 functioning as the gate electrode and the conductive layers 112a and 112b functioning as the source electrode and the drain electrode can be increased, so that the parasitic capacitance therebetween can be reduced.

Note that the conductive layer 103 can be connected to the conductive layer 112a or the conductive layer 112b. For example, an opening portion reaching the conductive layer 103 is provided in the insulating layer 195, the insulating layer 106, and the insulating layer 105 and the conductive layer 112a is provided to cover the opening portion, whereby the conductive layer 103 and the conductive layer 112a can be in contact with each other. When the conductive layer 112a and the conductive layer 103 are connected to each other, one of a source electrode and a drain electrode can have the same potential as the back gate electrode. In the case where the conductive layer 112a functions as the source electrode, for example, a shift in threshold voltage of the transistor 100 can be inhibited. In addition, the reliability of the transistor 100 can be improved.

Alternatively, the conductive layer 103 can be connected to the conductive layer 104. The conductive layer 103 and the conductive layer 104 can be in contact with each other when for example, an opening portion reaching the conductive layer 103 is provided in the insulating layer 106 and the insulating layer 105 and the conductive layer 104 is provided to cover the opening portion. When a gate electrode and a back gate electrode are electrically connected to each other, the back gate electrode and the gate electrode can have the same potential, so that the on-state current of the transistor 100 can be increased.

The region 108P and the region 108Q each include an impurity. When the impurity is supplied to the semiconductor layer 108, the electric resistance of each of the region 108P and the region 108Q can be reduced. As an element included in the impurity (hereinafter also referred to as a first element or an impurity element), one or more kinds of hydrogen, boron, carbon, nitrogen, fluorine, phosphorus, sulfur, arsenic, aluminum, magnesium, silicon, and a noble gas can be used. Note that typical examples of the noble gas include helium, neon, argon, krypton, and xenon. As the first element, it is particularly preferable to use one or more kinds of hydrogen, boron, phosphorus, and fluorine. The concentration of the first element in each of the region 108P and the region 108Q is higher than the concentration of the first element in the region 108i.

The concentration of the first element in the semiconductor layer 108 can be analyzed by SIMS or X-ray photoelectron spectrometry (XPS), for example. Note that XPS is also referred to as an electron spectrometry for chemical analysis (ESCA), in some cases. Alternatively, a plurality of analysis methods can be used. For example, a combined analysis of both SIMS and XPS can be performed. The same applies to other analyses.

By supplying the first element, oxygen vacancies are generated in the semiconductor layer 108. Furthermore, V_{O}H is generated, whereby the region 108P and the region 108Q each having low electric resistance can be formed. In the case where an element that is easily bonded to oxygen is used as the first element, the first element deprives the semiconductor layer 108 of oxygen and exists in a state of being bonded to oxygen. When an element that is stabilized by being bonded to oxygen is used as the first element, the first element in the semiconductor layer 108 exists stably in an oxidized state and thus is not easily desorbed by heat or the like applied during the manufacturing process of the semiconductor device; hence, the electric resistance of each of the region 108P and the region 108Q can be kept low. Thus, as the first element, it is preferable to use an element an oxide of which can exist as a solid at least at a temperature during the manufacturing process. One or both of boron and phosphorus can be suitably used as the first element.

In the case where boron is used as the first element, boron included in each of the region 108P and the region 108Q can exist in a state of being bonded to oxygen. This can be confirmed by a peak derived from a B₂O₃ bond, which is observed in XPS analysis. Furthermore, in XPS analysis, the intensity of a peak attributed to a state where a boron element exists alone is not observed or is extremely low to be at the background level.

When hydrogen is supplied, oxygen vacancies are generated and V_{O}H is generated by the entry of hydrogen into the oxygen vacancies; thus, the electric resistance of each of the region 108P and the region 108Q can be efficiently reduced. Accordingly, hydrogen can be suitably used as the first element.

The conditions for supplying the first element are preferably adjusted such that the concentration of the first element is the highest at a surface of the semiconductor layer 108 or a region near the surface.

As a source material used for supplying the first element, a gas including the first element can be used, for example. In the case where boron is supplied, one or both of a B₂H₆ gas and a BF₃ gas can be typically used. In the case where phosphorus is supplied, a PH₃ gas can be typically used. A mixed gas in which any of these source gases is diluted with a noble gas can also be used. Note that the source material is not limited to a gas, and a solid or a liquid can also be employed by being vaporized.

As a method for supplying the first element, an ion implantation method or plasma treatment can be used, for example.

In the ion implantation method, the concentration profile in the depth direction can be highly accurately controlled by the acceleration energy and the dosage of ions. The acceleration energy can be adjusted by the acceleration voltage at the time of the ion implantation. With the use of an ion implantation method in which a source gas is ionized and the ion is subjected to mass separation and then supplied, ions having a certain mass can be supplied and the purity of the ions to be supplied can be increased. Alternatively, an ion implantation method in which ions are supplied without mass separation may be used, in which case the productivity can be improved. In this specification and the like, there is no limitation on whether mass separation is performed unless otherwise specified. Note that a method in which ions are subjected to mass separation and then supplied is referred to as an ion implantation method, and a method in which ions are supplied without mass separation is referred to as an ion doping method in some cases. When a gas including the first element is used as the source gas, the first element can be supplied. The supply amount of the first element can be adjusted by the acceleration energy and the dosage of ions, for example.

In the case of using an ion implantation method to supply the first element, conditions such as an acceleration voltage and a dosage are preferably set in consideration of the composition, density, thickness, and the like of each of the insulating layer 106 and the semiconductor layer 108. Note that when the first element is also supplied to a region of the insulating layer 105 that does not overlap with the conductive layer 104, the region sometimes includes the first element.

Note that the method for supplying the first element is not particularly limited to the above methods; plasma treatment, treatment employing thermal diffusion by heating, or the like can be used, for example. For the plasma treatment, an apparatus in which a gas is made to be plasma by high-frequency power can be suitably used. Examples of the apparatus include a plasma CVD apparatus, a plasma etching apparatus, and a plasma ashing apparatus. In the case of plasma treatment, the first element can be supplied in such a manner that plasma is generated in a gas atmosphere including the first element to be supplied and plasma treatment is performed.

A plasma CVD apparatus can be used for the supply of the first element to each of the region 108P and the region 108Q and formation of the insulating layer 195. Accordingly, the supply of the first element and the formation of the insulating layer 195 can be successively performed in the plasma CVD apparatus, whereby the productivity can be improved. These treatments are preferably performed successively in the same treatment chamber of the same plasma CVD apparatus. For example, when plasma treatment in an atmosphere including a gas including a hydrogen element (e.g., NH₃) is performed with a plasma CVD apparatus, hydrogen can be supplied as the first element to the region of the semiconductor layer 108 that does not overlap with the conductive layer 104. Subsequently, the insulating layer 195 can be formed in the treatment chamber where the supply of the first element is performed.

An insulating layer 218 is provided over the conductive layer 112a, the conductive layer 112b, and the insulating layer 195. The insulating layer 195 and the insulating layer 218 each function as a protective layer for the transistor 100.

### [Semiconductor Layer 108]

A metal oxide applicable to the semiconductor layer 108 is specifically described. As described above, the metal oxide preferably includes at least indium. Indium oxide can be suitably used as the metal oxide. Alternatively, the metal oxide preferably includes one or both of indium and an element M. Further alternatively, the metal oxide preferably includes one or both of indium and zinc. Further alternatively, the metal oxide preferably includes one or two or more kinds selected from indium, the element M, and zinc. The element Mis a metal element or a metalloid element that has a high binding energy with oxygen and is, for example, a metal element or a metalloid element whose binding energy with oxygen is higher than that of indium. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M included in the metal oxide is preferably one or more kinds of the above elements, further preferably one or more kinds selected from gallium, aluminum, tin, and yttrium, still further preferably one or more kinds selected from gallium, aluminum, and tin. These elements are further preferable because they have high bonding energy with oxygen and have substantially the same ion radius as indium or zinc. In addition, tin is tetravalent and is preferable because the carrier mobility can be increased. In this specification and the like, a metal element and a metalloid element may be collectively referred to as a “metal element”, and a “metal element” in this specification and the like may refer to a metalloid element.

For example, the semiconductor layer 108 can be formed using indium oxide (IO), gallium oxide, zinc oxide, indium zinc oxide (also referred to as In—Zn oxide or IZO (registered trademark)), indium tin oxide (also referred to as In—Sn oxide or ITO), indium titanium oxide (In—Ti oxide), indium gallium oxide (also referred to as In—Ga oxide or IGO), indium tungsten oxide (also referred to as In—W oxide or IWO), indium gallium aluminum oxide (In—Ga—Al oxide), indium gallium tin oxide (also referred to as In—Ga—Sn oxide or IGTO), gallium zinc oxide (also referred to as Ga—Zn oxide or GZO), aluminum zinc oxide (also referred to as Al—Zn oxide or AZO), indium aluminum zinc oxide (also referred to as In-Al—Zn oxide or IAZO), indium tin zinc oxide (also referred to as In—Sn—Zn oxide or ITZO (registered trademark)), indium titanium zinc oxide (In—Ti—Zn oxide), indium gallium zinc oxide (also referred to as In—Ga—Zn oxide or IGZO), indium gallium tin zinc oxide (also referred to as In—Ga—Sn—Zn oxide or IGZTO), or indium gallium aluminum zinc oxide (also referred to as In—Ga—Al—Zn oxide, IGAZO, IGZAO, or IAGZO). Alternatively, indium tin oxide including silicon (also referred to as In—Sn—Si oxide or ITSO), gallium tin oxide (Ga—Sn oxide), aluminum tin oxide (Al—Sn oxide), or the like can be used.

Instead of indium or in addition to indium, the metal oxide can include one or more kinds of metal elements with large period numbers in the periodic table. The larger the overlap between orbits of metal elements is, the more likely it is that the metal oxide will have high carrier conductivity. Thus, a transistor including a metal element with a large period number can have high field-effect mobility in some cases. Examples of the metal element with a large period number include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may include one or more kinds selected from nonmetallic elements. By including a non-metallic element, the metal oxide sometimes has an increased carrier concentration, a reduced band gap, or the like, in which case the transistor can have increased field-effect mobility. Examples of the nonmetallic element include carbon, nitrogen, phosphorus, sulfur, selenium, fluorine, chlorine, bromine, and hydrogen.

A metal oxide including indium and the element M can be used for the semiconductor layer 108. When the element M is included, formation of oxygen vacancies (V_{O}) in the metal oxide is inhibited, and generation of carriers due to oxygen vacancies is inhibited. This inhibits a shift in the threshold voltage of the transistor and thus reduces a cutoff current, so that the transistor can be normally off. A transistor with a low off-state current can be provided. A change in the electrical characteristics of the transistor can be reduced to improve the reliability of the transistor. For example, a change in electrical characteristics due to negative bias stress (hereinafter also referred to as negative-bias stress temperature photodegradation) can be inhibited.

However, when the content percentage of the element M in the metal oxide is too high, the indium content percentage becomes low and thus the field-effect mobility is lowered in some cases. Accordingly, in the metal oxide, the atomic proportion of the element Mis preferably lower than or equal to the atomic proportion of indium.

In the metal oxide, the atomic proportion of indium is preferably higher than or equal to the atomic proportion of the element M. The indium content percentage in the metal oxide is preferably higher than or equal to 50% and lower than or equal to 100%, further preferably higher than or equal to 60% and lower than or equal to 100%, still further preferably higher than or equal to 60% and lower than or equal to 99%, yet still further preferably higher than or equal to 70% and lower than or equal to 99%, yet still further preferably higher than or equal to 80% and lower than or equal to 99%, yet still further preferably higher than or equal to 80% and lower than or equal to 98%, yet still further preferably higher than or equal to 80% and lower than or equal to 96%, yet still further preferably higher than or equal to 86% and lower than or equal to 94%, yet still further preferably higher than or equal to 80% and lower than or equal to 92%. Note that the indium content percentage is not limited to the above range.

The electrical characteristics and reliability of the transistor can be different depending on the composition of the metal oxide used for the semiconductor layer 108. Thus, the content percentage of indium and the element M is preferably selected in accordance with the electrical characteristics and reliability required for the transistor. Typically, indium gallium oxide with an indium content percentage of higher than or equal to 60% and lower than or equal to 99% is preferably used for the semiconductor layer 108. With such a structure, a transistor with both high field-effect mobility and reliability can be formed.

In the case where the metal oxide is In—M oxide, In—M oxide with metal elements in any of the following atomic proportions is preferably used: In:M=99:1, In:M=98:2 (49:1), In:M=97:3, In:M=95:5 (19:1), In:M=10:1, In:M=5:1, In:M=4:1, In:M=3:1, In:M=2:1, or the vicinity thereof. Typically, a metal oxide that has any of the above atomic proportions and includes Ga as the element M can be suitably used.

In the case where a plurality of kinds of elements are included as the element M, the sum of the proportion of the number of the element M atoms in the total number of atoms of all the metal elements contained can be referred to as the element M content percentage.

A metal oxide having a high zinc content percentage has high crystallinity, whereby diffusion of impurities in the metal oxide can be inhibited. Consequently, a change in the electrical characteristics of the transistor can be reduced to improve the reliability of the transistor.

When the metal oxide is In—M—Zn oxide, the atomic proportion of In is preferably higher than or equal to that of the element M in the In—M—Zn oxide. For example, In—M—Zn oxide with metal elements in any of the following atomic proportions can be used: In:M:Zn=1:1:1, In:M:Zn=1:1:1.2, In:M:Zn=2:1:3, In:M:Zn=3:1:1, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=5:1:9, In:M:Zn=6:1:6, In:M:Zn=10:1:1, In:M:Zn=10:1:3, In:M:Zn=10:1:4, In:M:Zn=10:1:6, In:M:Zn=10:1:7, In:M:Zn=10:1:8, In:M:Zn=5:2:5, In:M:Zn=10:1:10, In:M:Zn=20:1:10, In:M:Zn=40:1:10, or the vicinity thereof. Note that in this specification and the like, a composition in the neighborhood includes ±30% of an intended atomic ratio. By increasing the atomic proportion of In in the metal oxide, the on-state current, field-effect mobility, or the like of the transistor can be improved.

The atomic proportion of In can also be lower than that of the element M in the In—M—Zn oxide. Examples of the atomic proportion of the metal elements of such In—M—Zn oxide include In:M:Zn=1:3:2, In:M:Zn=1:3:3, In:M:Zn=1:3:4, In:M:Zn=1:3:6 and a composition in the vicinity of any of the above atomic proportions. By increasing the proportion of the number of M atoms in the metal oxide, generation of oxygen vacancies can be suppressed.

A metal oxide that does not include the element M can be used for the semiconductor layer 108. In the case where the metal oxide is In—Zn oxide, examples of the atomic proportion of metal elements include In:Zn=1:1, In:Zn=2:1, In:Zn=1:2, In:Zn=3:1, In:Zn=3:2, In:Zn=2:3, In:Zn=4:1, In:Zn=4:3, In:Zn=5:1, In:Zn=5:2, In:Zn=5:3, In:Zn=5:4, In:Zn=5:6, In:Zn=5:7, In:Zn=5:8, In:Zn=5:9, In:Zn=7:1, In:Zn=10:1, In:Zn=10:3, In:Zn=10:7, or the vicinity thereof. Furthermore, the atomic proportion of In is preferably higher than or equal to that of Zn. By increasing the atomic proportion of In in the metal oxide, the on-state current, field-effect mobility, or the like of the transistor can be improved.

In the case where the metal oxide is In—M—Zn oxide, In—M—Zn oxide with a metal element in the atomic proportion of In:M:Zn=40:1:10 or the vicinity thereof is preferably used. Typically, a metal oxide that has any of the above atomic proportions and includes Ga as the element M can be suitably used.

Analysis of the composition of the semiconductor layer 108 can be performed by energy dispersive X-ray spectrometry (EDX), XPS, inductively coupled plasma-mass spectrometry (ICP-MS), or inductively coupled plasma-atomic emission spectrometry (ICP-AES). Alternatively, these methods can be combined as appropriate to be employed for analysis. It is preferable that peak separation of a spectrum obtained by the analysis be performed to identify and quantify an element. As for an element whose content percentage is low, the actual content percentage may be different from the content percentage obtained by analysis because of the influence of the analysis accuracy. In the case where the element M content percentage is low, for example, the element M content percentage obtained by analysis is lower than the actual content percentage, the element M content percentage may be difficult to quantify, or the element M is below the lower detection limit in some cases.

The semiconductor layer 108 can have a single-layer structure or a stacked-layer structure of two or more layers. In the case where the semiconductor layer 108 has a stacked-layer structure, the above-described metal oxide can be suitably used for each layer included in the semiconductor layer 108. The layers included in the semiconductor layer 108 can be formed using the same material. Alternatively, one or more layers included in the semiconductor layer 108 can be formed using different materials.

In this specification and the like, different materials mean materials, the constituent elements of which are partially or entirely different from each other, or materials having the same constituent element and different compositions.

It is preferable to use a metal oxide having crystallinity for the semiconductor layer 108. Examples of the structure of a metal oxide having crystallinity include a c-axis aligned crystalline (CAAC) structure, a polycrystalline structure, a microcrystalline structure, and a nano-crystalline (nc) structure. With use of a metal oxide having crystallinity, the density of defect states in the semiconductor layer 108 can be reduced, which enables the transistor to have high reliability. Thus, the semiconductor device can have high reliability.

The semiconductor layer 108 is preferably formed using a CAAC-OS or an nc-OS.

The CAAC-OS includes a plurality of layered crystals. The c-axis of the crystal is aligned in the normal direction of the formation surface. The semiconductor layer 108 preferably includes a layered crystal parallel or substantially parallel to the formation surface. The semiconductor layer 108 preferably includes a layered crystal parallel or substantially parallel to the top surface of the insulating layer 105 that is the formation surface. With such a structure, the layered crystal of the semiconductor layer 108 is formed parallel or substantially parallel to the channel length direction of the transistor 100, whereby the transistor can have a high on-state current.

A change in electrical characteristics of an OS transistor due to irradiation with radiation is small, that is, an OS transistor has high resistance to radiation; thus, an OS transistor can be suitably used even in an environment where radiation can enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a proton beam, and a neutron beam).

The semiconductor layer 108 may include a layered material functioning as a semiconductor. The layered material generally refers to a group of materials having a layered crystal structure. The layered material has high electrical conductivity in a unit layer, that is, high two-dimensional electrical conductivity. When a material that functions as a semiconductor and has high two-dimensional electrical conductivity is used for a channel formation region, the transistor can have a high on-state current.

Examples of the layered material include graphene, silicene, and chalcogenide. Chalcogenide is a compound including chalcogen (an element belonging to Group 16). Examples of chalcogenide include transition metal chalcogenide and chalcogenide of Group 13 elements. Specific examples of the transition metal chalcogenide which can be used for a channel formation region include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

### [Insulating Layers 106 and 105]

The above description can be referred to for materials that can be used for the insulating layer 106 and the insulating layer 105. A miniaturized transistor including a thin gate insulating layer might have a high leakage current. When a high dielectric constant material (also referred to as a high-k material) is used for the gate insulating layer, the voltage at the time of operation of the transistor can be reduced while the physical thickness is maintained. Examples of the high-k material usable for the insulating layer 106 include gallium oxide, hafnium oxide, zirconium oxide, an oxide including aluminum and hafnium, an oxynitride including aluminum and hafnium, an oxide including silicon and hafnium, an oxynitride including silicon and hafnium, and a nitride including silicon and hafnium.

Although the insulating layer 106 and the insulating layer 105 each have a single-layer structure in FIG. 1B and the like, one embodiment of the present invention is not limited thereto. One or both of the insulating layer 106 and the insulating layer 105 can have a stacked-layer structure of two or more layers. In the case where the insulating layer 106 has a stacked-layer structure, an insulating layer on the semiconductor layer 108 side preferably includes an oxide or an oxynitride. Similarly, in the case where the insulating layer 105 has a stacked-layer structure, an insulating layer on the semiconductor layer 108 side preferably includes an oxide or an oxynitride. For example, one or more of silicon oxide, silicon oxynitride, and aluminum oxide can be suitably used for the insulating layer on the semiconductor layer 108 side. Note that Non-Patent Document 3 discloses a structure in which hafnium oxide is used for an insulating layer in contact with the bottom surface of an indium oxide layer, which is a semiconductor layer, and aluminum oxide is used for an insulating layer in contact with the top surface of the indium oxide layer.

A material that does not easily transmit a substance is preferably used for one or more layers included in the insulating layer 106. It can also be said that the layer functions as a barrier film. Providing the layer functioning as a barrier film can inhibit diffusion of a metal component included in the conductive layer 104 and impurities (e.g., water and hydrogen) included in a layer formed over the transistor 100 into the semiconductor layer 108 through the insulating layer 106. Furthermore, oxygen included in the semiconductor layer 108 can be inhibited from diffusing into the conductive layer 104 side through the insulating layer 106. In that case, formation of oxygen vacancies in the semiconductor layer 108 can be suppressed. Furthermore, the conductive layer 104 can be inhibited from being oxidized by oxygen included in the semiconductor layer 108 and from having higher electric resistance. Consequently, a transistor with favorable electrical characteristics and high reliability can be obtained. Similarly, a layer functioning as a barrier film is preferably provided as one or more layers included in the insulating layer 105.

Note that in this specification and the like, a barrier film refers to a film having a barrier property. A barrier property means one or both of a function of hindering diffusion of a target substance and then inhibiting the substance from passing through a film (also referred to as low permeability) and a function of capturing or fixing (also referred to as gettering) the substance.

For the barrier film, one or more of an oxide including one or both of aluminum and hafnium, an oxide including magnesium, an oxide including gallium, a nitride including silicon, an oxynitride including silicon, and a nitride oxide including silicon can be used, for example. Typically, for the barrier film, one or more of aluminum oxide, hafnium oxide, hafnium aluminate, magnesium oxide, gallium oxide, gallium zinc oxide, silicon nitride, silicon oxynitride, and silicon nitride oxide can be suitably used, for example. For the barrier film included in the insulating layer 106, one or more of an oxide and an oxynitride can be used, and aluminum oxide can be suitably used, for example. For the barrier film included in the insulating layer 105, one or more of a nitride and a nitride oxide can be used, and silicon nitride can be suitably used, for example.

The insulating layer 106 can have a stacked-layer structure of a silicon oxynitride film and a silicon nitride film over the silicon oxynitride film, for example. Alternatively, the insulating layer 106 can have a stacked-layer structure of a silicon oxynitride film and an aluminum oxide film over the silicon oxynitride film. Further alternatively, the insulating layer 106 can have a stacked-layer structure of an aluminum oxide film and a silicon oxynitride film over the aluminum oxide film. Further alternatively, the insulating layer 106 can have a stacked-layer structure of an aluminum oxide film and a silicon nitride film over the aluminum oxide film. Although the example where the insulating layer 106 has a stacked-layer structure of two layers is described here, one embodiment of the present invention is not limited thereto. The insulating layer 106 can have a stacked-layer structure of three or more layers.

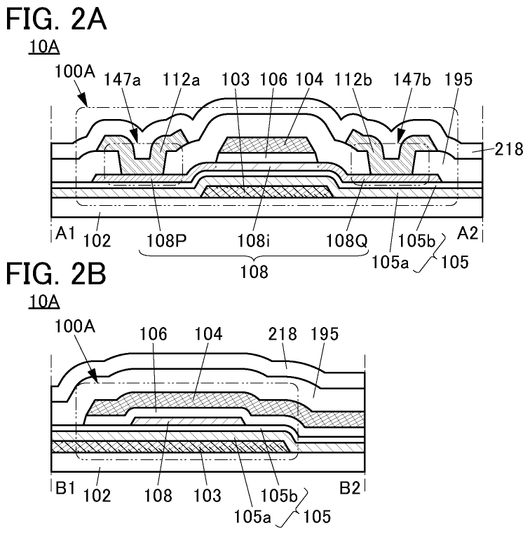

FIGS. 2A and 2B show an example in which the insulating layer 105 has a stacked-layer structure. FIG. 1A can be referred to for a top view of a semiconductor device 10A shown in FIGS. 2A and 2B. FIG. 2A is a cross-sectional view taken along the dashed-dotted line A1-A2 in FIG. 1A, and FIG. 2B is a cross-sectional view taken along the dashed-dotted line B1-B2 in FIG. 1A.

The semiconductor device 10A includes a transistor 100A. FIGS. 2A and 2B show an example in which the insulating layer 105 has an insulating layer 105a and an insulating layer 105b over the insulating layer 105a.

As described above, the insulating layer 105b in contact with the semiconductor layer 108 preferably includes oxygen. The insulating layer 105a positioned on the substrate 102 and the conductive layer 103 side preferably functions as a barrier film. Providing the barrier film can inhibit diffusion of components (e.g., metal) included in the substrate 102 and the conductive layer 103 into the semiconductor layer 108, whereby a semiconductor device can be highly reliable. For the barrier film, the above description can be referred to. The insulating layer 105a preferably includes nitrogen.

The insulating layer 105a preferably includes silicon and nitrogen. The insulating layer 105b preferably includes silicon and oxygen. For example, silicon nitride and silicon oxynitride can be suitably used for the insulating layer 105a and the insulating layer 105b, respectively.

In the case where the insulating layer 105 has a stacked-layer structure, one or more layers included in the insulating layer 105 preferably include hydrogen. In particular, the insulating layer 105b, which is the layer over which the semiconductor layer 108 is formed, preferably includes hydrogen. The insulating layer 105b preferably includes silicon, oxygen, and hydrogen, for example. For the insulating layer 105b, silicon oxynitride including hydrogen or silicon oxide including hydrogen can be suitably used, for example. It is preferable to form the insulator 105b by a method using a gas including hydrogen element as a film formation gas. The above description can be referred to for the silicon oxynitride film including hydrogen and the silicon oxide film including hydrogen.

The insulating layer 105a can include hydrogen. When hydrogen included in the insulating layer 105a diffuses into the insulating layer 105b, the metal oxide film can include hydrogen at the time of formation of the metal oxide film over the insulating layer 105. The insulating layer 105a preferably includes silicon, nitrogen, and hydrogen, for example. For the insulating layer 105a, silicon nitride including hydrogen can be used, for example. As a film formation gas for the silicon nitride film, a deposition gas including a silicon element and a nitriding gas can be used. As the nitriding gas, a gas including a nitrogen element can be used. As the nitriding gas, one or more of nitrogen (N₂) and ammonia (NH₃) can be used, for example. Because of including a hydrogen element together with a nitrogen element, NH₃ can be suitably used as a film formation gas for the insulating layer 105a. Typically, SiH₄, N₂, and NH₃ can be suitably used as film formation gases for a silicon nitride film including hydrogen. The hydrogen concentration in the silicon nitride film can be controlled with the proportion of the flow rate of the ammonia gas in the whole film formation gas (hereinafter also referred to as ammonia flow rate ratio). Specifically, when the ammonia flow rate ratio is made high, the hydrogen concentration in the silicon nitride film can be increased; when the ammonia flow rate ratio is made low, the hydrogen concentration can be reduced. In addition, the stress of the silicon nitride film can be controlled with the ammonia flow rate ratio in some cases. Reducing the stress can suppress a defect due to the stress (e.g., film separation).

Although the example where the insulating layer 105 has a stacked-layer structure of two layers is described here, one embodiment of the present invention is not limited thereto. Alternatively, the insulating layer 105 can have a stacked-layer structure of three or more layers.

### [Conductive Layers 112a, 112b, 104, and 103]

The conductive layer 112a, the conductive layer 112b, the conductive layer 104, and the conductive layer 103 can each have a single-layer structure or a stacked-layer structure of two or more layers. The conductive layers 112a, 112b, 104, and 103 can each be formed using, for example, one or more of chromium, copper, aluminum, gold, silver, zinc, tantalum, titanium, tungsten, manganese, nickel, iron, cobalt, molybdenum, and niobium, or an alloy including one or more of these metals as its components. For each of the conductive layers 112a, 112b, 104, and 103, a conductive material with low electric resistivity that includes one or more of copper, silver, gold, and aluminum can be suitably used. Copper or aluminum is particularly preferable because of its high mass-productivity.

As each of the conductive layers 112a, 112b, 104, and 103, a metal oxide having conductivity (also referred to as an oxide conductor (OC)) can be used. Examples of the oxide conductor include indium oxide, zinc oxide, ITO, In—Zn oxide, In—W oxide, In—W—Zn oxide, In—Ti oxide, In—Ti—Sn oxide, ITSO, In—Sn—Zn oxide, Ga—Zn oxide, and In—Ga—Zn oxide. An oxide conductor including indium is particularly preferable because of its high conduction property. When an oxygen vacancy is formed in a metal oxide having semiconductor characteristics and hydrogen is added to the oxygen vacancy, a donor level is formed in the vicinity of the conduction band. As a result, the conductivity of the metal oxide is increased, and thus, the metal oxide becomes a conductor. The metal oxide having become a conductor can also be referred to as an oxide conductor.

The conductive layers 112a, 112b, 104, and 103 can each have a stacked-layer structure of a conductive film including the above-described oxide conductor (metal oxide) and a conductive film including a metal or an alloy. The use of the conductive film including a metal or an alloy can reduce the wiring resistance.

For each of the conductive layers 112a, 112b, 104, and 103, a nitride conductor can alternatively be used. Examples of the nitride conductor include tantalum nitride and titanium nitride.

A Cu—X alloy film (X is Mn, Ni, Cr, Fe, Co, Mo, Ta, or Ti) can alternatively be used for each of the conductive layers 112a, 112b, 104, and 103. The use of a Cu—X alloy film results in lower manufacturing cost because the film can be processed by wet etching.

For the conductive layer 104, a material having a large work function (ØM) is preferably used. The work function of the conductive layer 104 is preferably larger than the electron affinity of the semiconductor layer 108. An OS transistor formed using a metal oxide including indium is an accumulation-type transistor in which electrons are majority carriers. When the material having a large work function is used for the conductive layer 104 functioning as a gate electrode of the transistor, a shift in the threshold voltage of the transistor can be caused. In addition, the transistor can be normally off. Accordingly, a transistor with favorable electrical characteristics can be provided.

For the conductive layer 104, it is possible to use a conductive material having a work function larger than or equal to 4.5 eV, preferably larger than or equal to 5.0 eV, for example. Examples of the conductive material include metals such as platinum, nickel, copper, cobalt, molybdenum, chromium, and tungsten. Examples of the conductive material include an oxide conductor, an oxide conductor including nitrogen, and a nitride conductor. Examples of the oxide conductor include ITO, ITSO, In—Zn oxide, indium tin oxide including tungsten (In—Sn—W oxide), In—Ti oxide, and indium zirconium oxide (In—Zr oxide). Examples of the oxide conductor including nitrogen include In—Ga—Zn oxide including nitrogen, indium tin oxide including nitrogen, indium gallium oxide including nitrogen, indium zinc oxide including nitrogen, tin oxide including nitrogen, and indium oxide including nitrogen. Examples of the nitride conductor include titanium nitride, indium nitride, and tin nitride.

Note that the same material can be used for the conductive layers 112a, 112b, 104, and 103. Alternatively, for at least one of the conductive layers, a different material can be used.

### [Insulating Layer 195]

The insulating layer 195 preferably includes one or more inorganic insulating layers. The above description can be referred to for the inorganic insulating layer.

The insulating layer 195 preferably functions as a barrier film. In that case, diffusion of impurities (e.g., water and hydrogen) into the transistors from the outside can be effectively inhibited, leading to an increase in the reliability of the semiconductor device. For example, one or two or more of silicon nitride, silicon nitride oxide, and silicon oxynitride can be suitably used for the insulating layer 195. For the barrier film, the above description can be referred to.

A barrier film is preferably provided above and below the semiconductor layer 108. Each of these barrier films preferably includes a region overlapping with the semiconductor layer 108. In that case, diffusion of impurities from above and below the semiconductor layer 108 into the semiconductor layer 108 can be inhibited. Accordingly, a change in the electrical characteristics of the transistor can be reduced to improve the reliability of the transistor. For example, a barrier film is preferably provided for both the insulating layer 195 and the insulating layer 105. The above description can be referred to for the insulating layer 105. Typically, silicon nitride can be used for the insulating layer 105a, and silicon nitride oxide can be used for the insulating layer 195. Alternatively, silicon nitride can be used for the insulating layer 105a, and silicon oxynitride can be used for the insulating layer 195. For the stacked-layer structure of the insulating layer 105, the description of FIGS. 2A and 2B can be referred to.

### [Insulating Layer 218]

For the insulating layer 218, one or both of an inorganic insulating layer and an organic insulating layer can be used. For the inorganic insulating layer, any of the materials that can be used for the insulating layer 106 and the insulating layer 105 given above can be used. Examples of materials that can be used for the organic insulating layer include an acrylic resin and a polyimide resin. The organic insulating layer functions as a planarization layer that reduces unevenness caused by the transistor.

### [Substrate 102]

There is no particular limitation on the properties of a material of the substrate 102 as long as the material has heat resistance enough to withstand at least heat application treatment to be performed later. For example, a single-crystalline semiconductor substrate or a polycrystalline semiconductor substrate of silicon or silicon carbide, a compound semiconductor substrate of silicon germanium or the like, an SOI substrate, a glass substrate, a quartz substrate, a sapphire substrate, a ceramic substrate, or an organic resin substrate can be used as the substrate 102. As the substrate 102, a substrate provided with a semiconductor element can be used. As the substrate 102, a substrate provided with an insulating film on its surface can be used. Note that the shape of the substrate 102 is not particularly limited and can be a circle or a square shape, for example.

A flexible substrate may be used as the substrate 102, and the transistor 100 and the like can be formed directly on the flexible substrate. Alternatively, a separation layer can be provided between the substrate 102 and the transistor 100 and the like. With the separation layer, part or the whole of a semiconductor device formed thereover can be separated from the substrate 102 and transferred onto another substrate. In that case, the transistor 100 and the like can be transferred onto a substrate having low heat resistance or a flexible substrate as well.

A structure example partly different from <Structure example 1> described above will be described below. Note that the description of the same portions as those in <Structure Example 1> is omitted in some cases. In the drawings that are referred to later, the same hatching pattern is applied to portions having functions similar to those in <Structure Example 1> described above, and the portions are not denoted by reference numerals in some cases.

Note that there is no particular limitation on the structure of the transistor that can be used in the semiconductor device of one embodiment of the present invention.

### Structure Example 2

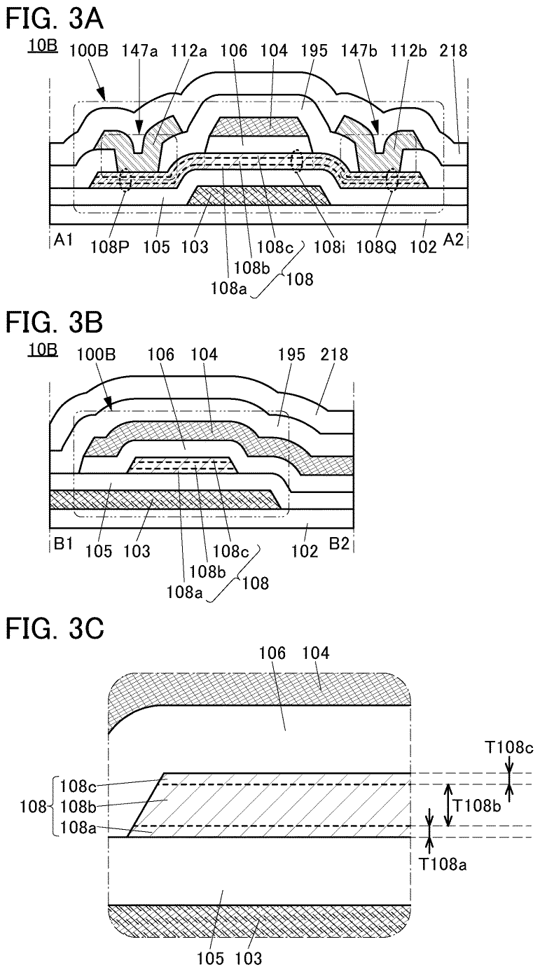

Cross-sectional views of a semiconductor device 10B that is one embodiment of the present invention are shown in FIGS. 3A and 3B. FIG. 1A can be referred to for a top view of the semiconductor device 10B. FIG. 3A is a cross-sectional view taken along the dashed-dotted line A1-A2 in FIG. 1A, and FIG. 3B is a cross-sectional view taken along the dashed-dotted line B1-B2 in FIG. 3A.

The semiconductor device 10B includes a transistor 100B. The transistor 100B is different from the transistor 100 shown in FIG. 1B and the like mainly in that the semiconductor layer 108 has a stacked-layer structure.

FIG. 3B and the like show a structure in which the semiconductor layer 108 has a three-layer structure of a semiconductor layer 108a, a semiconductor layer 108b over the semiconductor layer 108a, and a semiconductor layer 108c over the semiconductor layer 108b. The semiconductor layer 108b is in contact with the semiconductor layer 108a and the semiconductor layer 108c and is sandwiched therebetween.

For each of the semiconductor layers 108a, 108b, and 108c, the material given for the semiconductor layer 108 can be used. The semiconductor layers 108a, 108b, and 108c can be formed using the same material. Indium oxide can be suitably used for each of the semiconductor layers 108a, 108b, and 108c. Alternatively, one or more of the semiconductor layers 108a, 108b, and 108c can be formed using different materials.

Note that a boundary between the semiconductor layer 108a and the semiconductor layer 108b cannot be clearly identified in some cases, as well as a boundary between the semiconductor layer 108b and the semiconductor layer 108c. Thus, the boundaries are denoted by dashed lines in FIG. 3B and the like. Note that one or both of these boundaries can be observed in some cases.

The conductivity of the semiconductor layer 108b is preferably higher than the conductivity of each of the semiconductor layer 108a and the semiconductor layer 108c. In that case, the semiconductor layer 108b serves as a main current path in the transistor 100B. Meanwhile, in the semiconductor layer 108, each of the semiconductor layer 108a in contact with the insulating layer 105 and the semiconductor layer 108c in contact with the insulating layer 106 is preferably denser and has fewer defects than the semiconductor layer 108b.

Impurities or defects might cause formation of trap states at an interface between the insulating layer 106 functioning as a gate insulating layer and the semiconductor layer 108 and the vicinity thereof, and an interface between the insulating layer 105 functioning as a back gate insulating layer and the semiconductor layer 108 and the vicinity thereof. In addition, when the insulating layer 106 is formed, damage to the interface between the insulating layer 106 and the semiconductor layer 108 and the vicinity thereof might cause formation of trap states at the interface between the insulating layer 106 and the semiconductor layer 108 and the vicinity thereof. When the semiconductor layer 108b, which is a main current path, is sandwiched between the semiconductor layer 108a and the semiconductor layer 108c, the semiconductor layer 108b can be distanced from the interface between the semiconductor layer 108 and the insulating layers, so that the density of trap states at the interface of the semiconductor layer 108b and the vicinity thereof can be reduced. With such a structure, a transistor with high field-effect mobility can be formed.

Here, application of a high potential to the conductive layer 104 functioning as a gate electrode might cause formation of trap states at the interface between the insulating layer 106 and the semiconductor layer 108 and the vicinity thereof. Similarly, application of a high potential to the conductive layer 103 functioning as a back gate electrode might cause formation of trap states at the interface between the insulating layer 105 and the semiconductor layer 108 and the vicinity thereof. When electrons are trapped by these trap states, the threshold voltage of the transistor might shift in the positive direction and the reliability might be lowered. Providing the semiconductor layer 108c that has few defects and is in contact with the insulating layer 106 can inhibit formation of trap states at the interface between the insulating layer 106 and the semiconductor layer 108 and the vicinity thereof. Similarly, providing the semiconductor layer 108a that has few defects and is in contact with the insulating layer 105 can inhibit formation of trap states at the interface between the insulating layer 105 and the semiconductor layer 108 and the vicinity thereof. As a result, the transistor can have high reliability.

When the semiconductor layer 108b with high conductivity is sandwiched between the semiconductor layer 108a and the semiconductor layer 108c with few defects as described above, the transistor can have both high field-effect mobility and high reliability. Consequently, the semiconductor device can have both high-speed operation and high reliability.

In the channel formation region, the semiconductor layer 108b preferably has higher carrier mobility than the semiconductor layer 108a and the semiconductor layer 108c. Here, in the case where non-single-crystalline metal oxide (e.g., polycrystalline metal oxide) is used for the semiconductor layer, an increase in carrier concentration can increase carrier mobility in some cases. The carrier concentration of the semiconductor layer 108b is preferably higher than those of the semiconductor layer 108a and the semiconductor layer 108c. In that case, the conductivity of the semiconductor layer 108b, which is a main current path, is increased, so that the transistor can have high field-effect mobility.

Each of the semiconductor layers 108a, 108b, and 108c preferably includes an element that increases the carrier concentration (hereinafter also referred to as a second element). As the second element, for example, one or more of hydrogen, carbon, and nitrogen can be used.

Hydrogen can be suitably used as the second element. When hydrogen reacts with oxygen bonded to a metal atom in the metal oxide to be water, an oxygen vacancy is formed in the metal oxide. In addition, when a defect that is an oxygen vacancy into which hydrogen enters (V_{O}H) functions as a donor and an electron serving as a carrier is generated, the carrier concentration in the metal oxide is increased. Note that hydrogen is sometimes described as an example of the second element below.

In the channel formation region, the semiconductor layer 108b preferably includes a region having a higher concentration of the second element than the semiconductor layer 108a and the semiconductor layer 108c. Typically, the semiconductor layer 108b preferably includes a region having a higher hydrogen concentration than the semiconductor layer 108a and the semiconductor layer 108c. In that case, the carrier concentration and carrier mobility of the semiconductor layer 108b can be increased. Meanwhile, when the hydrogen concentrations in the semiconductor layer 108a and the semiconductor layer 108c are too high, the number of defects might be increased. Thus, in the channel formation region, each of the semiconductor layer 108a and the semiconductor layer 108c preferably includes a region having a lower concentration of the second element than the semiconductor layer 108b.

For analysis of the concentration of the second element in the semiconductor layer 108, SIMS or XPS can be used, for example. For analysis of hydrogen concentration, for example, SIMS can be suitably used. Note that the reliability of measurement values might be lowered due to a matrix effect at an interface between the semiconductor layer 108 and a layer in contact with the semiconductor layer 108 and the vicinity thereof. For example, in the case where measurement is performed in a direction from the insulating layer 106 side toward the semiconductor layer 108, the reliability of the measurement value might be lowered at the interface between the insulating layer 106 and the semiconductor layer 108 and the vicinity thereof. A measurement value with low reliability of a region is not regarded as the concentration of the second element in the semiconductor layer 108. When the measurement in the direction from the insulating layer 106 side toward the semiconductor layer 108 and measurement in a direction from the insulating layer 105 side toward the semiconductor layer 108 are combined, the analysis of the concentration of the second element in the semiconductor layer 108 can have increased accuracy in some cases.

In the analysis of the concentration, the intensity of a constituent element of a metal oxide sometimes enables estimation of the position of the interface between the insulating layer 106 and the semiconductor layer 108 and the position of the interface between the insulating layer 105 and the semiconductor layer 108. For example, a range where the intensity of a constituent element of the metal oxide included in the semiconductor layer 108 is greater than or equal to ½ of its maximum value can be referred to as the semiconductor layer 108. In the case where a metal oxide including indium is used for the semiconductor layer 108 and SIMS is used for the analysis of the concentration of the second element, a range where the secondary ion intensity of indium is greater than or equal to ½ of its maximum value can be referred to as the semiconductor layer 108, and a range where the secondary ion intensity is less than ½ of its maximum value can be referred to as a layer other than the semiconductor layer 108 (e.g., the insulating layer 105 and the insulating layer 106). Alternatively, a range where the secondary ion intensity of a cluster including indium (e.g., a cluster including indium and oxygen) is greater than or equal to ½ of its maximum value can be referred to as the semiconductor layer 108, and a range where the secondary ion intensity is less than ½ of its maximum value can be referred to as a layer other than the semiconductor layer 108 (e.g., the insulating layer 105 and the insulating layer 106).

The film density of each of the semiconductor layer 108a and the semiconductor layer 108c is preferably higher than the film density of the semiconductor layer 108b. In that case, defects in the semiconductor layer 108a and the semiconductor layer 108c can be reduced. Providing the semiconductor layer 108c having a high film density over the semiconductor layer 108b can inhibit the semiconductor layer 108b from being damaged in the formation of the insulating layer 106. The film density can be evaluated by Rutherford backscattering spectrometry (RBS) or X-ray reflectivity (XRR), for example.

A difference in film density can be evaluated using a cross-sectional TEM image in some cases. In TEM observation, a transmission electron (TE) image is dark-colored (dark) when the film density is high, and a TE image is pale (bright) when the film density is low. Thus, even in the case where the semiconductor layers 108a, 108b, and 108c are formed using the same material such as indium oxide, a difference in film density between these layers can be observed as a difference in contrast in cross-sectional TEM observation in some cases. Specifically, in the TE image, the semiconductor layer 108a and the semiconductor layer 108c each sometimes include a dark-colored (dark) region compared with the semiconductor layer 108b. The semiconductor layer 108b sometimes has a pale (bright) region compared with the semiconductor layer 108a and the semiconductor layer 108c.

Note that each of the semiconductor layer 108a and the semiconductor layer 108c can have the same film density as the semiconductor layer 108b or lower film density than the semiconductor layer 108b.

Even in the case of using the same material, when the film is denser and has a higher film density, the etching rate may be lower. The etching rate of each of the semiconductor layer 108a and the semiconductor layer 108c with respect to an etchant is preferably lower than the etching rate of the semiconductor layer 108b. The semiconductor layer 108c with a low etching rate is preferably provided over the semiconductor layer 108b. In that case, the semiconductor layer 108c can be inhibited from disappearing in an etching step after the formation of the semiconductor layer 108, so that a reduction in the thickness of the semiconductor layer 108 can be inhibited.

In the case where the semiconductor layer 108 has a three-layer structure of the semiconductor layer 108a, the semiconductor layer 108b, and the semiconductor layer 108c, a metal oxide film is formed in the following manner: a first metal oxide film to be the semiconductor layer 108a, a second metal oxide film to be the semiconductor layer 108b, and a third metal oxide film to be the semiconductor layer 108c are formed in this order.

The first metal oxide film, the second metal oxide film, and the third metal oxide film are each preferably formed by a sputtering method using a metal target or a metal oxide target. Alternatively, the first metal oxide film, the second metal oxide film, and the third metal oxide film are each preferably formed by an ALD method. In an ALD method, the film formation speed can be easily controlled, so that a thin film can be formed with high yield. Thus, an ALD method can be suitably used particularly when the thickness of the metal oxide film is small. Alternatively, a CVD method can be used.

Examples of a power source used in a sputtering apparatus include a direct current (DC) power source, a radio frequency (RF) power source, and an alternating current (AC) power source. Note that it is also possible to use a pulsed DC power source that applies voltage to a target in a pulsed manner. A magnetron sputtering method, which utilizes a magnetic field of a magnet, has a high film formation speed and thus can improve the productivity. For the formation of each of the first metal oxide film, the second metal oxide film, and the third metal oxide film, a sputtering method, in particular, a magnetron sputtering method can be suitably used. Note that a magnetron sputtering method is sometimes described below as an example of a film formation method for the first metal oxide film, the second metal oxide film, and the third metal oxide film.

After the formation of the first metal oxide film, the second metal oxide film is preferably formed successively in a vacuum without exposure of the surface of the first metal oxide film to the air. Similarly, after the formation of the second metal oxide film, the third metal oxide film is preferably formed successively in a vacuum without exposure of the surface of the second metal oxide film to the air. Successive formation of the first metal oxide film, the second metal oxide film, and the third metal oxide film can inhibit impurities derived from the air from attaching to the surfaces of the first metal oxide film and the second metal oxide film. Examples of the impurities include water and organic substances.

In the case where two or more of the first metal oxide film, the second metal oxide film, and the third metal oxide film are formed using the same material, film formation can be performed in the same treatment chamber using the same sputtering target.

The semiconductor layers 108a, 108b, and 108c are preferably formed using the same material. The first metal oxide film, the second metal oxide film, and the third metal oxide film can be successively formed in the same treatment chamber using the same sputtering target. This can improve the productivity in manufacturing the semiconductor device and reduce the manufacturing cost. Furthermore, it is possible to inhibit impurities derived from the air from attaching to the surfaces of the first metal oxide film and the second metal oxide film.

Alternatively, one or more of the semiconductor layers 108a, 108b, and 108c are preferably formed using different materials. The first metal oxide film, the second metal oxide film, and the third metal oxide film can be formed using two or more sputtering targets. Also in this case, the metal oxide films are preferably formed successively in a vacuum without exposure of the surfaces of the metal oxide films to the air in the same apparatus. For example, the metal oxide films are preferably formed successively in a vacuum in different treatment chambers in the same apparatus.

As described above, the boundary between the semiconductor layer 108a and the semiconductor layer 108b and the boundary between the semiconductor layer 108b and the semiconductor layer 108c cannot be clearly observed in some cases. In particular, in the case where the semiconductor layers 108a, 108b, and 108c are formed using the same material, these boundaries cannot be clearly observed in some cases. When the first metal oxide film, the second metal oxide film, and the third metal oxide film are formed successively in a vacuum, interfaces between the metal oxide films are not formed, and boundaries therebetween cannot be observed in some cases. In such a case, the semiconductor layer 108a, the semiconductor layer 108b, and the semiconductor layer 108c can be rephrased as a first region, a second region, and a third region, respectively. The semiconductor layer 108 includes the first region (corresponding to the semiconductor layer 108a) on the insulating layer 105 side, the third region (corresponding to the semiconductor layer 108c) on the insulating layer 106 side, and the second region (corresponding to the semiconductor layer 108b) between the first region and the third region.

The concentration of the second element in the second region is preferably higher than the concentration of the second element in each of the first region and the third region. For the concentration of the second element in the second region, the above description of the concentration of the second element in the semiconductor layer 108b can be referred to. The above description of the concentrations of the second element in the semiconductor layer 108a and the semiconductor layer 108c can be respectively referred to for the concentrations of the second element in the first region and the third region. Note that the concentration of the second element in each of the first region, the second region, and the third region are not limited to the above range.

The film density of each of the first region and the third region is preferably higher than the film density of the second region. In the TEM observation of the cross section of the semiconductor layer 108, the first region and the third region each sometimes have a dark-colored (dark) region as compared with the second region in the TE image. The second region may include a pale (bright) region as compared with the first region and the third region.

Here, by changing the film formation conditions of the metal oxide film, the film quality of the metal oxide film (to be a semiconductor layer later) can be made different. Examples of the film quality include conductivity, a band gap, the number of defects, an impurity concentration, and crystallinity. Examples of film formation conditions include power density, pressure, kinds of gases, a flow rate of a gas, substrate temperature, and a distance between a sputtering target and a substrate (also referred to as a T-S distance or a TS distance). In the case of changing the film formation conditions, one or more of the power density, the pressure, the kinds of gases, the flow rate of the gas, the substrate temperature, and the T-S distance can be changed. Note that it takes time to change the substrate temperature and the T-S distance in some cases. Thus, in the case where two or more metal oxide films are formed in the same treatment chamber, the substrate temperature and the T-S distance are preferably the same. Note that even in the case of using the same material, the band gap might be different depending on the film formation conditions.

The film formation condition of the first metal oxide film (hereinafter also referred to as a first film formation condition) is preferably different from the film formation condition of the second metal oxide film (hereinafter also referred to as a second film formation condition). The film formation condition of the third metal oxide film (hereinafter also referred to as a third film formation condition) is preferably different from the second film formation condition. For example, one or both of the power density and the pressure in the first film formation condition are preferably different from the power density and the pressure in the second film formation condition. Similarly, one or both of the power density and the pressure in the third film formation condition are preferably different from the power density and the pressure in the second film formation condition. It is particularly preferable that the power density and the pressure in the first film formation condition be different from the power density and the pressure in the second film formation condition, and the power density and the pressure in the third film formation condition be different from the power density and the pressure in the second film formation condition.

The power density in each of the first film formation condition and the third film formation condition is preferably higher than the power density in the second film formation condition. Higher power density enables the semiconductor layer 108a and the semiconductor layer 108c to be dense and have few defects. The power density in each of the first film formation condition and the third film formation condition is preferably greater than or equal to 0.3 W/cm² and less than or equal to 2 W/cm², further preferably greater than or equal to 0.4 W/cm² and less than or equal to 2 W/cm², still further preferably greater than or equal to 0.5 W/cm² and less than or equal to 2 W/cm², yet still further preferably greater than or equal to 0.6 W/cm² and less than or equal to 2 W/cm², yet still further preferably greater than or equal to 0.6 W/cm² and less than or equal to 1 W/cm². Low power density might increase the number of defects in the semiconductor layer 108a and the semiconductor layer 108c, whereas excessively high power density might increase the load on an apparatus. When the power density in each of the first film formation condition and the third film formation condition is within the above range, the semiconductor layer 108a and the semiconductor layer 108c can be dense and have few defects, and the load on the apparatus can be reduced. Note that the power density in each of the first film formation condition and the third film formation condition is not limited to the above range.

Note that the power density is a value obtained by dividing an amount of power applied to the substrate by a magnet area. The magnet area is an area of a surface of a magnet which faces a sputtering target.

The power density in the second film formation condition is preferably higher than or equal to 0.1 W/cm² and lower than or equal to 1 W/cm², further preferably higher than or equal to 0.2 W/cm² and lower than or equal to 1 W/cm², still further preferably higher than or equal to 0.2 W/cm² and lower than or equal to 0.8 W/cm², yet still further preferably higher than or equal to 0.2 W/cm² and lower than or equal to 0.6 W/cm², yet still further preferably higher than or equal to 0.3 W/cm² and lower than or equal to 0.6 W/cm². The power density in the second film formation condition is preferably lower than the power density in each of the first film formation condition and the third film formation condition. High power density might lower the conductivity of the semiconductor layer 108b, whereas excessively low power density might cause a lower film formation speed and might accordingly lower the productivity. Excessively low power density might also make discharging unstable. When the power density in the second film formation condition is within the above range, the semiconductor layer 108b can have high conductivity, and the productivity can be improved. Note that the power density in the second film formation condition is not limited to the above range.

The pressure in each of the first film formation condition and the third film formation condition is preferably lower than the pressure in the second film formation condition. Lower pressure enables the semiconductor layer 108a and the semiconductor layer 108c to be dense and have few defects. The pressure in each of the first film formation condition and the third film formation condition is preferably higher than or equal to 0.1 Pa and lower than or equal to 0.8 Pa, further preferably higher than or equal to 0.1 Pa and lower than or equal to 0.6 Pa, still further preferably higher than or equal to 0.1 Pa and lower than or equal to 0.4 Pa, yet still further preferably higher than or equal to 0.1 Pa and lower than or equal to 0.3 Pa. Hight pressure might increase the number of defects in the semiconductor layer 108a and the semiconductor layer 108c, whereas excessively low pressure might make the pressure adjustment in the treatment chamber time-consuming and might accordingly lower the productivity. Excessively low pressure sometimes causes arcing to impede discharging. When the pressure in the first film formation condition and the third film formation condition is within the above range, the semiconductor layer 108a and the semiconductor layer 108c can be dense and have few defects, and the productivity can be improved. Note that the pressure in each of the first film formation condition and the third film formation condition is not limited to the above range.

The pressure in the second film formation condition is preferably higher than or equal to 0.2 Pa and lower than or equal to 1 Pa, further preferably higher than or equal to 0.3 Pa and lower than or equal to 1 Pa, still further preferably higher than or equal to 0.4 Pa and lower than or equal to 1 Pa, yet still further preferably higher than or equal to 0.4 Pa and lower than or equal to 0.8 Pa. The pressure in the second film formation condition is preferably higher than the pressure in each of the first film formation condition and the third film formation condition. Low pressure might lower the conductivity of the semiconductor layer 108b. Meanwhile, excessively high pressure might cause a lower film formation speed and might accordingly lower the productivity. Excessively high pressure might impede discharging in some cases. When the pressure in the second film formation condition is within the above range, the semiconductor layer 108b can have high conductivity and the productivity can be improved. Note that the pressure in the second film formation condition is not limited to the above range.

It is particularly preferable that the power density in each of the first film formation condition and the third film formation condition be higher than the power density in the second film formation condition, and the pressure in each of the first film formation condition and the third film formation condition be lower than the pressure in the second film formation condition. Accordingly, the conductivity of the semiconductor layer 108b can be further increased, and the semiconductor layer 108a and the semiconductor layer 108c can be denser and have fewer defects.

Here, the structure is described in which the power density and the pressure in each of the first film formation condition and the third film formation condition are different from the power density and the pressure in the second film formation condition; however, one embodiment of the present invention is not limited thereto. Other than the power density and pressure (e.g., a gas flow rate) can be made different between the first and third film formation conditions and the second film formation condition.

Note that the first film formation condition and the third film formation condition can be the same or different from each other. When the first film formation condition and the third film formation condition are the same, i.e., the semiconductor layer 108a and the semiconductor layer 108c have the same film quality, the number of kinds of films managed in manufacturing the semiconductor device can be reduced. In that case, productivity can be improved. Alternatively, the first film formation condition and the third film formation condition can be made different; that is, the semiconductor layer 108a and the semiconductor layer 108c can have different film qualities. In the formation of the insulating layer 106, the semiconductor layer 108c is sometimes damaged; thus, the third film formation condition preferably produces a denser film with fewer defects than the first film formation condition. For example, one or both of the power density and the pressure can be made different between the third film formation condition and the first film formation condition. Specifically, the power density in the third film formation condition can be higher than the power density in the first film formation condition. Furthermore, the pressure in the third film formation condition can be lower than the pressure in the first film formation condition.

FIG. 3C is an enlarged view of the semiconductor layer 108 and the vicinity thereof shown in FIG. 3B. In FIG. 3C, a thickness T108a of the semiconductor layer 108a, a thickness T108b of the semiconductor layer 108b, and a thickness T108c of the semiconductor layer 108c are indicated by solid arrows. The thickness T108a, the thickness T108b, and the thickness T108c are respectively the thicknesses of the semiconductor layer 108a, the semiconductor layer 108b, and the semiconductor layer 108c of the semiconductor layer 108 in a region overlapping with the conductive layer 104 in a cross-sectional view. Note that the thickness T108a, the thickness T108b, and the thickness T108c can be controlled by the treatment time (also referred to as film formation time) for the formation of the semiconductor layer 108a, the semiconductor layer 108b, and the semiconductor layer 108c, respectively.

The thickness T108b is preferably large. The thickness T108b is preferably larger than each of the thickness T108a and the thickness T108c. When the thickness T108b of the semiconductor layer 108b, which is the main current path, is made large, the transistor can have a high on-state current. However, in the case where the thickness T108b is too large, the amount of oxygen vacancies and V_{O}H in the semiconductor layer 108b is increased, which might cause a shift in the threshold voltage of the transistor and increase a cutoff current. The thickness T108b is preferably larger than or equal to 1 nm and smaller than or equal to 30 nm, further preferably larger than or equal to 2 nm and smaller than or equal to 30 nm, still further preferably larger than or equal to 2 nm and smaller than or equal to 20 nm, yet still further preferably larger than or equal to 4 nm and smaller than or equal to 20 nm, yet still further preferably larger than or equal to 4 nm and smaller than or equal to 10 nm. When the thickness T108b is within the above range, the transistor can have a high on-state current. Moreover, the threshold voltage shift can be inhibited, and thus, the cut-off current can be reduced; accordingly, the transistor can be normally off. Note that the thickness T108b is not limited to the above range.

The thickness T108a and the thickness T108c are each preferably smaller than the thickness T108b. The thickness T108a and the thickness T108c are each preferably larger than or equal to 0.5 nm and smaller than or equal to 10 nm, further preferably larger than or equal to 0.5 nm and smaller than or equal to 6 nm, still further preferably larger than or equal to 0.5 nm and smaller than or equal to 4 nm, yet still further preferably larger than or equal to 0.5 nm and smaller than or equal to 3 nm, yet still further preferably larger than or equal to 1 nm and smaller than or equal to 3 nm. When the thickness T108c is too large, the physical distance between the conductive layer 104 functioning as the first gate electrode and the semiconductor layer 108b is increased; thus, a field-effect mobility is decreased in some cases. Meanwhile, when the thickness T108c is too small, the physical distance between the semiconductor layer 108b, which is a main current path, and both of the interface between the insulating layer 106 and the semiconductor layer 108 and the vicinity of the interface, in which trap states can be formed, is shortened, so that the field-effect mobility is decreased in some cases. In addition, the reliability may be lowered. The same applies to the thickness T108a. When the thickness T108a and the thickness T108c are each within the above range, the transistor can have high field-effect mobility and high reliability. Note that each of the thickness T108a and the thickness T108c is not limited to the above ranges.

Here, the semiconductor layer 108 has a stacked-layer structure of three layers; however, one embodiment of the present invention is not limited thereto. The semiconductor layer 108 can have a single-layer structure or a stacked-layer structure of two layers or four or more layers. In the case where the semiconductor layer 108 has a stacked-layer structure, the semiconductor layer 108 preferably includes at least the semiconductor layer 108b.

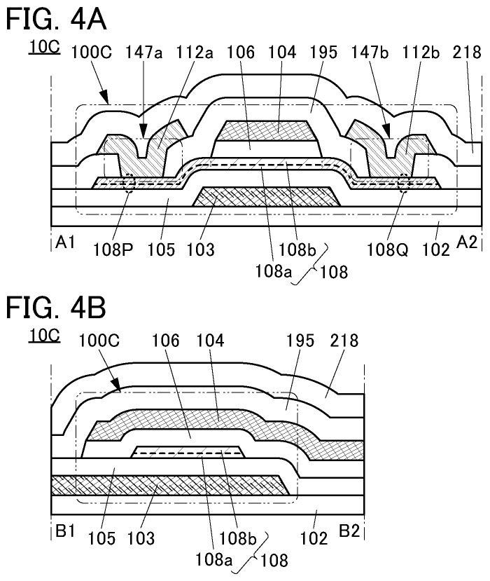

FIGS. 4A and 4B show cross-sectional views of a semiconductor device 10C of one embodiment of the present invention. FIG. 1A can be referred to for a top view of the semiconductor device 10C. FIG. 4A is a cross-sectional view taken along the dashed-dotted line A1-A2 in FIG. 1A, and FIG. 4B is a cross-sectional view taken along the dashed-dotted line B1-B2 in FIG. 1A.

The semiconductor device 10C includes a transistor 100C. The transistor 100C is different from the transistor 100B shown in FIG. 3A and the like mainly in that the semiconductor layer 108 has a two-layer structure of the semiconductor layer 108a and the semiconductor layer 108b. When the semiconductor layer 108c is not provided, the process can be simplified and the productivity can be improved.

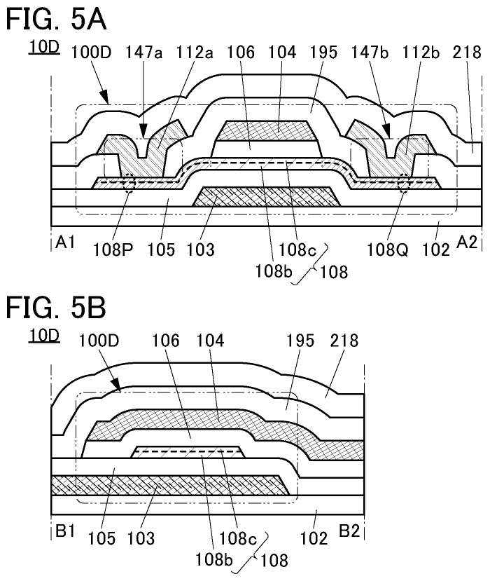

FIGS. 5A and 5B are cross-sectional views of a semiconductor device 10D of one embodiment of the present invention. FIG. 1A can be referred to for a top view of the semiconductor device 10D. FIG. 5A is a cross-sectional view taken along the dashed-dotted line A1-A2 in FIG. 1A, and FIG. 5B is a cross-sectional view taken along the dashed-dotted line B1-B2 in FIG. 1A.

The semiconductor device 10D includes a transistor 100D. The transistor 100D is different from the transistor 100B shown in FIG. 3A and the like mainly in that the semiconductor layer 108 includes a two-layer structure of the semiconductor layer 108b and the semiconductor layer 108c. When the semiconductor layer 108a is not provided, the process can be simplified and the productivity can be improved.

As described above, the layers included in the semiconductor layer 108 can be formed using the same material. Alternatively, one or more layers included in the semiconductor layer 108 can be formed using different materials.

Structure examples in which one or more layers included in the semiconductor layer 108 are formed using different materials are described.

In the semiconductor layer 108 shown in FIGS. 3A to 3C, FIGS. 4A and 4B, and FIGS. 5A and 5B, each of the semiconductor layer 108a and the semiconductor layer 108c preferably includes indium, the element M, and oxygen. The semiconductor layer 108b preferably includes indium and oxygen. The element M content percentage in each of the semiconductor layer 108a and the semiconductor layer 108c is preferably higher than that in the semiconductor layer 108b. For example, In—M oxide can be suitably used for each of the semiconductor layer 108a and the semiconductor layer 108c, and indium oxide can be suitably used for the semiconductor layer 108b. For the element M, the above description can be referred to. For example, gallium can be suitably used as the element M. Hereinafter, gallium is sometimes described as an example of the element M.

The semiconductor layer 108a and the semiconductor layer 108c each preferably include indium, gallium, and oxygen. The semiconductor layer 108b preferably includes indium and oxygen. The gallium content percentage in each of the semiconductor layer 108a and the semiconductor layer 108c is preferably higher than those in the semiconductor layer 108b. For example, In—Ga oxide can be suitably used for each of the semiconductor layer 108a and the semiconductor layer 108c, and indium oxide can be suitably used for the semiconductor layer 108b.

When the semiconductor layer 108c includes the element M having high bonding energy with oxygen, an increase in oxygen vacancies and V_{O}H in the semiconductor layer 108 can be inhibited. When the semiconductor layer 108c with a small amount of oxygen vacancies and V_{O}H is provided on the side of the conductive layer 104 functioning as a gate electrode, the transistor can have high reliability. Similarly, when the semiconductor layer 108a with a small amount of oxygen vacancies and V_{O}H is provided on the side of the conductive layer 103 functioning as a back gate electrode, the transistor can have high reliability.

In the formation of the insulating layer 106 over the semiconductor layer 108, damage to the semiconductor layer 108 might cause formation of oxygen vacancies and V_{O}H in the semiconductor layer 108. As a result, the threshold voltage of the transistor might shift. In addition, the reliability of the transistor might be lowered. When a metal oxide including the element M is used for the semiconductor layer 108c including a region in contact with the insulating layer 106, an increase in oxygen vacancies and V_{O}H in the semiconductor layer 108 can be inhibited. Accordingly, the transistor can be normally off even with a short channel length. In addition, variation in threshold voltage due to drain-induced barrier lowering (DIBL) can be inhibited, which enables the transistor to have high reliability.

The indium content percentage in the semiconductor layer 108b is preferably higher than the indium content percentage in each of the semiconductor layer 108a and the semiconductor layer 108c. A high indium content percentage in the semiconductor layer 108b, which is a main current path, enables the transistor to have high field-effect mobility.

In the case where the first metal oxide film to be the semiconductor layer 108a, the second metal oxide film to be the semiconductor layer 108b, and the third metal oxide film to be the semiconductor layer 108c are formed by a sputtering method, the metal oxide films are preferably formed successively by different sputtering targets in a vacuum in the same apparatus without exposure of a surfaces of the metal oxide films to the air. For example, the metal oxide films are preferably formed successively in a vacuum in different treatment chambers in the same apparatus. For example, a sputtering target including indium, the element M, and oxygen can be used for the formation of each of the first metal oxide film and the third metal oxide film. As the sputtering target, a sputtering target of In-M oxide can be used, for example. For the formation of the second metal oxide film, a sputtering target including indium and oxygen can be used. As the sputtering target, a sputtering target of indium oxide can be used, for example.

Alternatively, it is possible that the first metal oxide film, the second metal oxide film, and the third metal oxide film are formed using the same sputtering target, and then the element M (e.g., gallium) is supplied to the first metal oxide film and the third metal oxide film. For the supply of the element M, an ion implantation method can be used, for example. For the ion implantation method, the above description can be referred to. For the formation of the first metal oxide film, the second metal oxide film, and the third metal oxide film, for example, a sputtering target of indium oxide can be used. In that case, the first metal oxide film, the second metal oxide film, and the third metal oxide film can be successively formed in the same treatment chamber using the same sputtering target, whereby the productivity in manufacturing the semiconductor device can be improved.

In the supply of the element M to the semiconductor layer 108a, the acceleration energy in the supply is preferably set such that the concentration of the element M is the highest in the semiconductor layer 108a or at the interface between the insulating layer 105 and the semiconductor layer 108a or the vicinity of the interface. Similarly, in the supply of the element M to the semiconductor layer 108c, the acceleration energy in the supply is preferably set such that the concentration of the element Mis the highest in the semiconductor layer 108c or at the interface between the insulating layer 106 and the semiconductor layer 108c or the vicinity of the interface.

In the supply of the element M to the first metal oxide film and the third metal oxide film, the element M is also supplied to the second metal oxide film, and the semiconductor layer 108b also includes the element M in some cases. Also in this case, the element M content percentage in the semiconductor layer 108b is preferably lower than that in each of the semiconductor layer 108a and the semiconductor layer 108c. Alternatively, it is possible that the first metal oxide film is formed, the element Mis supplied, and then the second metal oxide film is formed. Note that the supply of the element M is not limited to the ion implantation method.

### Structure Example 3

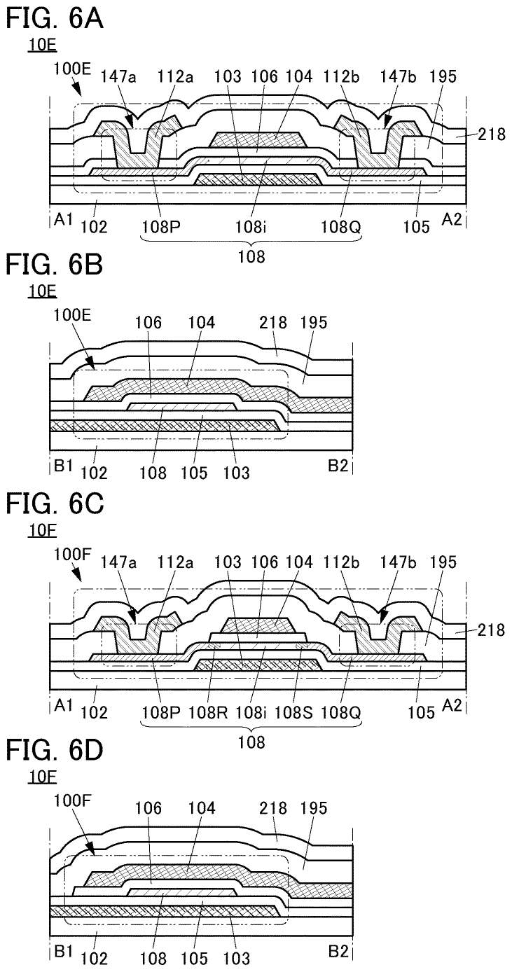

FIGS. 6A and 6B are cross-sectional views of a semiconductor device 10E of one embodiment of the present invention. FIG. 1A can be referred to for a top view of the semiconductor device 10E. FIG. 6A is a cross-sectional view taken along the dashed-dotted line A1-A2 shown in FIG. 1A, and FIG. 6B is a cross-sectional view taken along the dashed-dotted line B1-B2 shown in FIG. 1A.

The semiconductor device 10E includes a transistor 100E. The transistor 100E is different from the transistor 100 shown in FIG. 1B and the like mainly in that the insulating layer 106 includes each regions in contact with the region 108P and the region 108Q.

The insulating layer 106 includes regions in contact with the top surface and the side surface of the semiconductor layer 108 and the top surface of the insulating layer 105. The insulating layer 195 is provided over the insulating layer 106 and the conductive layer 104. The insulating layer 195 and the insulating layer 106 have the opening portion 147a and the opening portion 147b. The conductive layers 112a and 112b are formed to cover the opening portions 147a and 147b, respectively.

The region 108i overlaps with the conductive layer 104 with the insulating layer 106 therebetween. The regions 108P and 108Q each overlap with the insulating layer 106 and do not overlap with the conductive layer 104.

After the conductive layer 104 is formed over the insulating layer 106, the first element can be supplied to the semiconductor layer 108 through the insulating layer 106 with the conductive layer 104 as a mask. In that case, when the first element is supplied to a region of the insulating layer 106 that does not overlap with the conductive layer 104, the region sometimes includes the first element. For the supply of the first element, an ion implantation method can be suitably used, for example.

### Structure Example 4

FIGS. 6C and 6D are cross-sectional views of a semiconductor device 10F of one embodiment of the present invention. FIG. 1A can be referred to for a top view of the semiconductor device 10F. FIG. 6C is a cross-sectional view taken along the dashed-dotted line A1-A2 shown in FIG. 1A, and FIG. 6D is a cross-sectional view taken along the dashed-dotted line B1-B2 shown in FIG. 1A.

The semiconductor device 10F includes a transistor 100F. The transistor 100F is different from the transistor 100 shown in FIG. 1B and the like mainly in that the insulating layer 106 includes a region protruding beyond the conductive layer 104.

The end portion of the insulating layer 106 is positioned over the semiconductor layer 108, and the end portion of the conductive layer 104 is positioned over the insulating layer 106. In other words, the end portion of the insulating layer 106 is positioned outward from the end portion of the conductive layer 104. The insulating layer 106 includes a region overlapping with the conductive layer 104 and a region not overlapping with the conductive layer 104 over the semiconductor layer 108.

The semiconductor layer 108 includes the region 108i, the pair of regions (a region 108R and a region 108S) between which the region 108i is sandwiched, and a pair of regions (the region 108P and the region 108Q) positioned outside the pair of regions. Each of the regions 108R and 108S overlaps with the insulating layer 106 and does not overlap with the conductive layer 104. The region 108R is positioned between the region 108i and the region 108P, and the region 108S is positioned between the region 108i and the region 108Q.

The regions 108R and 108S each function as a buffer region that relieves a drain electric field. Each of the regions 108R and 108S is a region not overlapping with the conductive layer 104 and thus is a region where a channel is hardly formed by application of a gate voltage to the conductive layer 104. The regions 108R and 108S preferably have a higher carrier concentration than the channel formation region. Thus, the regions 108R and 108S can each function as an LDD (Lightly Doped Drain) region.

Each of the regions 108R and 108S can also be referred to as a region whose electric resistance is substantially equal to or lower than that of the channel formation region, a region whose carrier concentration is substantially equal to or higher than that of the channel formation region, a region whose oxygen vacancy density is substantially equal to or higher than that of the channel formation region, or a region whose concentration of the first element is substantially equal to or higher than that of the channel formation region.

The regions 108R and 108S can be referred to as regions whose electric resistances are substantially higher than or equal to those of the regions 108P and 108Q, regions whose carrier concentrations are substantially lower than or equal to those of the regions 108P and 108Q, regions whose oxygen vacancy densities are substantially lower than or equal to those of the regions 108P and 108Q, or regions whose concentrations of the first element are substantially lower than or equal to those of the regions 108P and 108Q.

The insulating layer 195 includes regions in contact with the top surface and the side surface of the semiconductor layer 108, the top surface and the side surface of the insulating layer 106, and the top surface and the side surface of the conductive layer 104.

### Structure Example 5

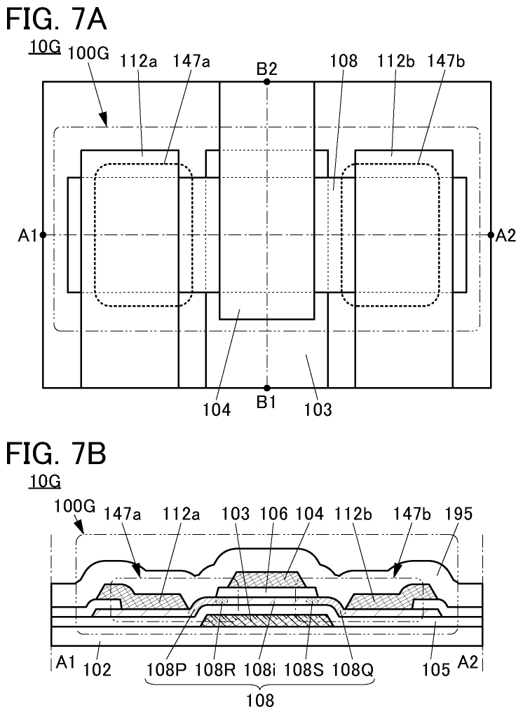

FIG. 7A shows a top view of a semiconductor device 10G of one embodiment of the present invention. FIG. 7B shows a cross-sectional view taken along the dashed-dotted line A1-A2 in FIG. 7A. FIG. 6B can be referred to for a cross-sectional view taken along the dashed-dotted line B1-B2.

The semiconductor device 10G includes a transistor 100G. The transistor 100G is different from the transistor 100F shown in FIG. 6C and the like mainly in that the conductive layers 112a and 112b are formed in the same step as the conductive layer 104.

The insulating layer 106 has the opening portions 147a and 147b each reaching the semiconductor layer 108. The conductive layer 112a and the conductive layer 112b are provided to cover part of the opening portion 147a and part of the opening portion 147b, respectively. The conductive layer 112a includes a region in contact with the semiconductor layer 108 in the opening portion 147a, and the conductive layer 112b includes a region in contact with the semiconductor layer 108 in the opening portion 147b.

The conductive layers 104, 112a, and 112b can be formed using the same material in the same step. For example, an insulating film is formed over the semiconductor layer 108 and processed, so that the insulating layer 106 including the opening portions 147a and 147b is formed. Then, a conductive film is formed to cover the insulating layer 106, the opening portion 147a, and the opening portion 147b and is processed, whereby the conductive layers 104, 112a, and 112b can be formed. When the conductive layers 112a and 112b are formed in the same step as the conductive layer 104, the number of steps can be reduced.

When the first element is supplied to the semiconductor layer 108 using the conductive layers 104, 112a, and 112b as masks, the regions 108P and 108Q can be formed in a self-aligned manner. The regions 108P and 108Q are formed in regions of the semiconductor layer 108 that overlap with none of the conductive layer 104, the conductive layer 112a, the conductive layer 112b, and the insulating layer 106. The regions 108R and 108S are formed in regions of the semiconductor layer 108 that overlap with none of the conductive layers 104, 112a, and 112b and overlap with the insulating layer 106.

In the semiconductor layer 108, a region in contact with the conductive layer 112a and the region 108P in contact with the region function as one of a source region and a drain region.

In the semiconductor layer 108, a region in contact with the conductive layer 112b and the region 108Q in contact with the region function as the other of the source region and the drain region.

The insulating layer 195 is provided over the transistor 100G. Although FIG. 7B shows a structure example in which the insulating layer 218 is not provided, one embodiment of the present invention is not limited thereto. It is also possible to provide the insulating layer 218 over the insulating layer 195.

### Structure Example 6

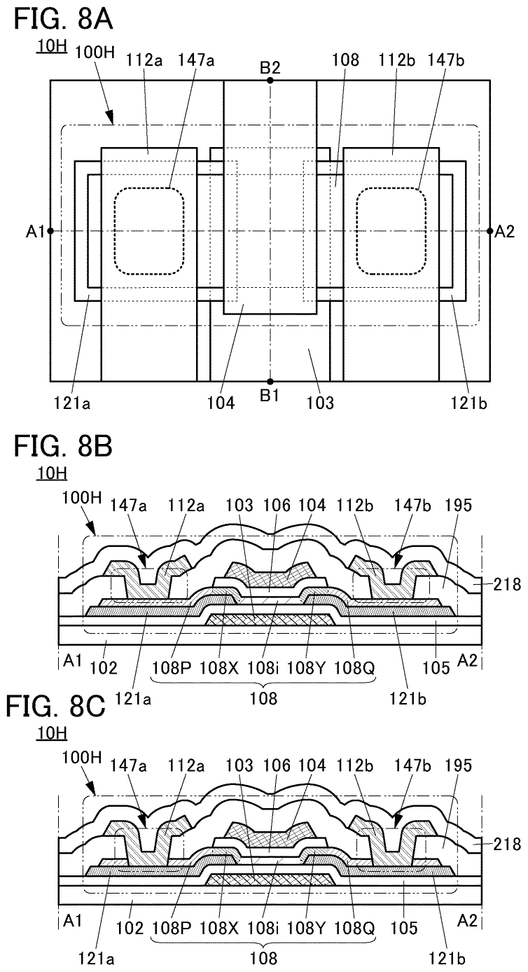

FIG. 8A shows a top view of a semiconductor device 10H of one embodiment of the present invention. FIG. 8B shows a cross-sectional view taken along the dashed-dotted line A1-A2 in FIG. 8A. FIG. 6D can be referred to for a cross-sectional view taken along the dashed-dotted line B1-B2.

The semiconductor device 10H is different from the semiconductor device 10F shown in FIG. 6C and the like mainly in including a layer 121a and a layer 121b. The semiconductor device 10H includes a transistor 100H, the layer 121a, and the layer 121b.

The layers 121a and 121b are each provided between the semiconductor layer 108 and the insulating layer 105. The semiconductor layer 108 includes regions in contact with the layers 121a and 121b and the insulating layer 105.

The semiconductor layer 108 includes the region 108i, a pair of regions (a region 108X and a region 108Y) between which the region 108i is sandwiched, and a pair of regions (the region 108P and the region 108Q) outside the pair of regions (the region 108X and the region 108Y). The region 108i overlaps with the conductive layer 104 with the insulating layer 106 therebetween and is not in contact with either the layer 121a or the layer 121b. Neither the region 108P or 108Q overlaps with the conductive layer 104 or the insulating layer 106. The region 108P and the region 108Q are preferably in contact with the layer 121a and the layer 121b, respectively. The region 108X and the region 108Y are in contact with the layer 121a and the layer 121b, respectively, and are in contact with the insulating layer 106. In the transistor 100H, the region 108P functions as one of a source region and a drain region, and the region 108Q functions as the other of the source region and the drain region.

A conductive layer can be used as each of the layers 121a and 121b. For the conductive layer, any of the materials given for the conductive layers 104, 112a, and 112b can be used. An oxide conductor can be suitably used for the layers 121a and 121b. The use of an oxide conductor can further reduce the contact resistance between the layer 121a and the semiconductor layer 108 and the contact resistance between the layer 121b and the semiconductor layer 108. Alternatively, a semiconductor layer can be used as each of the layers 121a and 121b. For the semiconductor layer, any of the materials given for the semiconductor layer 108 can be used. Typically, ITO, ITSO, or In—Sn—Zn oxide can be suitably used for the layers 121a and 121b.

The thicknesses of the layers 121a and 121b are each preferably larger than the thickness T108 of the semiconductor layer 108. In that case, the electric resistances of the layers 121a and 121b can be reduced. Here, in the case where the thickness T108 of the semiconductor layer 108 is small, the regions 108P and 108Q have high electric resistance in some cases. However, reducing the electric resistances of the layers 121a and 121b can reduce the electric resistances of the source region and the drain region even when the thickness T108 is small.

In FIG. 8B and the like, the layers 121a and 121b each include a region overlapping with the conductive layer 104. That is, the region 108X and the region 108Y each include a region overlapping with the conductive layer 104. Note that in each of the regions 108X and 108Y, the region overlapping with the conductive layer 104 functions as the channel formation region in some cases. In the case where the electric resistance of the region is lower than that of the channel formation region, the region can function as a buffer region that relieves a drain electric field.

As shown in FIG. 8C, the opening portions 147a and 147b can reach the layer 121a and the layer 121b, respectively, penetrating the semiconductor layer 108. In that case, the conductive layer 112a includes a region in contact with the layer 121a and the region 108P in the opening portion 147a. The conductive layer 112b includes a region in contact with the layer 121b and the region 108Q in the opening portion 147b. Thus, even in the case where the thickness T108 is small, the contact resistance between the source electrode and the source region and the contact resistance between the drain electrode and the drain region can each be reduced.

Although FIGS. 8A to 8C show a structure in which the layers 121a and 121b each include the region overlapping with the conductive layer 104, one embodiment of the present invention is not limited thereto. It is possible that one or both of the layer 121a and the layer 121b do not overlap with the conductive layer 104.

A method for manufacturing a semiconductor device of one embodiment of the present invention will be described. As for a material and a formation method of each component, portions described above are not described in some cases.

Thin films included in the semiconductor device (e.g., insulating films, semiconductor films, and conductive films) can be formed by a sputtering method, a chemical vapor deposition (CVD) method, a vacuum evaporation method, a pulsed laser deposition (PLD) method, an ALD method, or the like.

Alternatively, thin films included in the semiconductor device (e.g., insulating films, semiconductor films, and conductive films) can be formed by a wet process such as spin coating, dipping, spray coating, ink-jetting, dispensing, screen printing, offset printing, doctor blade coating, slit coating, roll coating, curtain coating, or knife coating.

In processing thin films included in the semiconductor device, a lithography method or the like can be employed. Alternatively, a nanoimprinting method, a sandblasting method, a lift-off method, or the like can be employed to process the thin films. Alternatively, island-shaped thin films can be directly formed by a film formation method using a shielding mask such as a metal mask.

There are two typical examples of lithography methods. In one of the methods, a resist mask is formed over a thin film to be processed, the thin film is processed by etching or the like, and then the resist mask is removed. In the other method, a photosensitive thin film is formed and then processed into a desired shape by light exposure and development.

As light for exposure in a lithography method, it is possible to use light with the i-line (wavelength: 365 nm), light with the g-line (wavelength: 436 nm), light with the h-line (wavelength: 405 nm), or light in which the i-line, the g-line, and the h-line are mixed. Alternatively, ultraviolet light, KrF laser light, ArF laser light, or the like can be used. Exposure can also be performed by liquid immersion exposure technique. As the light for exposure, extreme ultraviolet (EUV) light or X-rays can also be used. Furthermore, instead of the light used for the exposure, an electron beam can be used. EUV, X-rays, or an electron beam is preferably used to enable extremely minute processing. Note that a photomask is not needed when exposure is performed by scanning with a beam such as an electron beam.

For etching of thin films, one or more of a dry etching method, a wet etching method, and a sandblast method can be used.

### Manufacturing Method Example 1

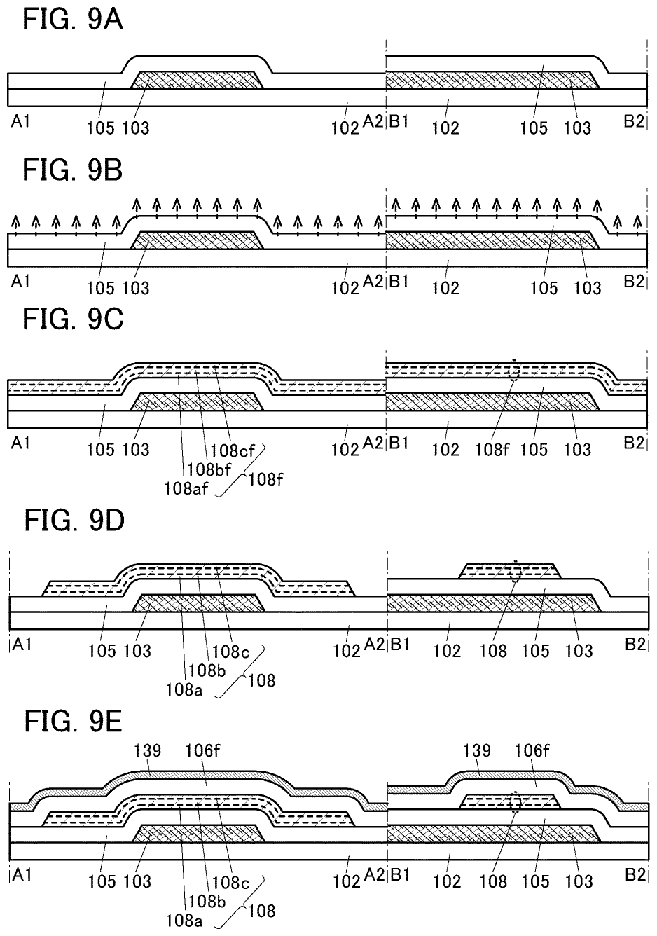

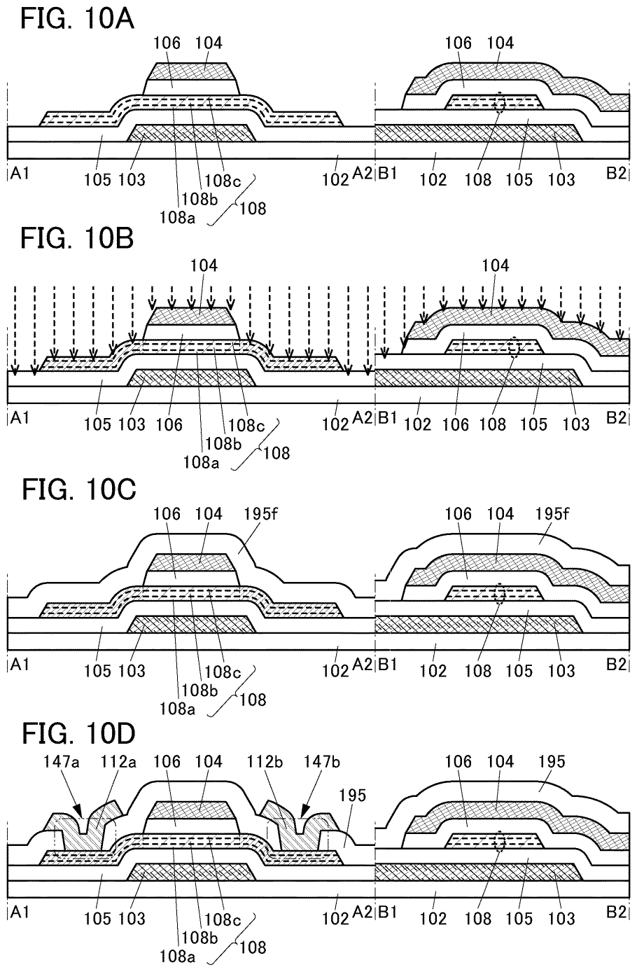

Here, an example of a method for manufacturing the semiconductor device 10B shown in FIGS. 3A and 3B is described with reference to FIGS. 9A to 9E and FIGS. 10A to 10D. FIGS. 9A to 9E and FIGS. 10A to 10D each show a cross-sectional view taken along the dashed-dotted line A1-A2 in FIG. 3A and a cross-sectional view taken along the dashed-dotted line B1-B2 in FIG. 3B.

First, a conductive film is formed over the substrate 102 and processed, whereby the conductive layer 103 is formed. For the formation of the conductive film, a sputtering method can be suitably used.

Next, the insulating layer 105 is formed over the conductive layer 103 and the substrate 102 (FIG. 9A). A sputtering method or a plasma CVD method can be suitably used for the formation of the insulating layer 105.

Then, a metal oxide film 108f to be the semiconductor layer 108 is formed over the insulating layer 105 (FIG. 9C). The metal oxide film 108f is preferably formed by a sputtering method using a metal target or a metal oxide target. Alternatively, the metal oxide film 108f is preferably formed by an ALD method. In an ALD method, the film formation speed can be easily controlled, so that a thin film can be formed with high yield. Thus, an ALD method can be suitably used particularly when the thickness of the metal oxide film 108f is small. The metal oxide film 108f can be formed by a CVD method.

When the substrate temperature at the time of the formation of the metal oxide film 108f is too high, the indium content percentage in the metal oxide film 108f might be low. The metal oxide film 108f is formed at a substrate temperature preferably higher than or equal to room temperature (e.g., 25 °C) and lower than or equal to 200 °C, further preferably higher than or equal to room temperature and lower than or equal to 150 °C, still further preferably higher than or equal to room temperature and lower than or equal to 120 °C, yet still further preferably higher than or equal to room temperature and lower than or equal to 100 °C. Note that the substrate temperature in the formation of the metal oxide film 108f is not limited to the above-described range.

When the substrate temperature in the formation of the metal oxide film 108f is increased, the crystallinity of the metal oxide film 108f is increased and thus defects can be reduced. In that case, a transistor can have high field-effect mobility and high reliability. The substrate temperature can be typically 100 °C.

When the substrate temperature in the formation of the metal oxide film 108f is decreased, the crystallinity of the metal oxide film 108f can be lowered. In that case, the crystal grain size can be increased by heat treatment performed later. It is particularly preferable that the formation of the metal oxide film 108f be performed with the substrate temperature set at room temperature or without heating the substrate.

Here, as the metal oxide film 108f, a metal oxide film 108af to be the semiconductor layer 108a and a metal oxide film 108bf to be the semiconductor layer 108b, and a metal oxide film 108cf to be the semiconductor layer 108c are formed. The metal oxide film 108af, the metal oxide film 108bf, and the metal oxide film 108cf are each preferably formed by a sputtering method. For the metal oxide film 108af, the metal oxide film 108bf, and the metal oxide film 108cf, the above description of the first metal oxide film, the second metal oxide film, and the third metal oxide film can be referred to.

As described above, in the formation of the metal oxide film 108af (the first metal oxide film), it is preferable that the power density be high and the pressure be low. In that case, the kinetic energy of the sputtered particles in the formation of the metal oxide film 108af is increased, so that some hydrogen included in the insulating layer 105 can be desorbed. Then, the hydrogen diffuses into the metal oxide film 108f, whereby the metal oxide film 108f including hydrogen can be obtained. In FIG. 9B, a state where hydrogen is desorbed from the insulating layer 105 is schematically shown by dashed arrows.

In the case of employing an ALD method, a film formation method such as a thermal ALD method or a PEALD method is preferably employed. The thermal ALD method is preferable because of its capability of forming a film with extremely high step coverage. The PEALD method is preferable because of its capability of forming a film at low temperatures, in addition to its capability of forming a film with high step coverage.

The metal oxide films 108af, 108bf, and 108cf can each be formed by an ALD method using an oxidizing agent and a precursor that includes a constituent metal element, for example.

For example, in the case where an indium oxide film is formed, a precursor including indium can be used. For example, in the case where an In—Ga oxide film is formed, it is possible to use two kinds of precursors: a precursor including indium and a precursor including gallium. Alternatively, a precursor including indium and gallium can be used.

Examples of the precursor including indium include triethylindium, trimethylindium, tris(2,2,6,6-tetramethyl-3,5-heptanedionato)indium, cyclopentadienylindium, indium(III) chloride, (3-(dimethylamino)propyl)dimethylindium, [1,1,1-trimethyl-N-(trimethylsilyl)amide]-indium, and the like.

Examples of the precursor including gallium include trimethylgallium, triethylgallium, gallium(III) chloride, tris(dimethylamido)gallium(III), gallium(III) acetylacetonate, tris(2,2,6,6-tetramethyl-3,5-heptanedionato)gallium, dimethylchlorogallium, diethylchlorogallium, and the like.

Examples of a precursor including aluminum include aluminum chloride and trimethylaluminum.

Examples of a precursor including tin include tin(IV) chloride and tetrakis(dimethylamido)tin.

Examples of a precursor including zinc include dimethylzinc, diethylzinc, bis(2,2,6,6-tetramethyl-3,5-heptanedionato) zinc, and zinc chloride.

Examples of the oxidizing agent include ozone, oxygen, hydrogen peroxide, and water.

As an example of a method for controlling the composition of a film to be formed, adjustment of one or more of the kinds, flow rate ratio, flowing time, flowing order, or the like of the source gases is given. By adjusting these, the compositions of the metal oxide films 108af, 108bf, and 108cf can be controlled. By adjusting such conditions, the metal oxide film 108f whose composition is continuously changed can be formed.

Before the formation of the metal oxide film 108f, at least one of treatment for releasing water, hydrogen, an organic substance, and the like adsorbed on a surface of the insulating layer 105, and treatment for supplying oxygen into the insulating layer 105 is preferably performed. For example, heat treatment can be performed at a temperature higher than or equal to 70 °C and lower than or equal to 200 °C in a vacuum. Alternatively, plasma treatment in an atmosphere including oxygen can be performed. Alternatively, oxygen can be supplied to the insulating layer 105 by performing plasma treatment in an atmosphere including an oxidizing gas such as dinitrogen monoxide (N₂O). When plasma treatment is performed in an atmosphere including a dinitrogen monoxide gas, an organic substance on the surface of the insulating layer 105 can be favorably removed and oxygen can be supplied to the insulating layer 105. The metal oxide film 108f is preferably formed successively after such treatment without exposure of the surface of the insulating layer 105 to the air.

Next, the metal oxide film 108f is processed into an island shape to form the semiconductor layer 108 (FIG. 9D). A wet etching method can be suitably used to form the semiconductor layer 108. In that case, part of a region of the insulating layer 105 that does not overlap with the semiconductor layer 108 is etched and the thickness of the region is reduced in some cases. Note that in the etching of the metal oxide film 108f, a reduction in the thickness of the insulating layer 105 can be inhibited when a material having high etching selectivity is used for the insulating layer 105.

Before the metal oxide film 108f is processed into an island shape or after the metal oxide film 108f is processed into an island shape, heat treatment (hereinafter, also referred to as first heat treatment) is performed. The first heat treatment can increase the crystallinity of the semiconductor layer 108 and reduce defects. The heat treatment can remove an impurity included in the semiconductor layer 108 or adsorbed on its surface. Furthermore, oxygen can be supplied from the insulating layer 105 to the metal oxide film 108f or the semiconductor layer 108 by the first heat treatment.

The metal oxide film 108f having low crystallinity is crystallized by the first heat treatment, so that the crystallinity of the metal oxide film 108f can be increased. In addition, crystal grains included in the semiconductor layer 108 can be increased in grain size. Hydrogen included in the metal oxide film is desorbed from the metal oxide film as a result of the crystallization. Accordingly, the hydrogen concentration in the metal oxide film after the first heat treatment is reduced, so that the hydrogen concentration in the semiconductor layer 108 can be reduced.

For the first heat treatment, an apparatus that uses heat conduction or heat radiation from a heater can be used, for example. An oven or a rapid thermal annealing (RTA) apparatus can be used for the first heat treatment, for example. As the RTA apparatus, it is possible to use a lamp RTA (LRTA) apparatus in which an object to be treated is heated by radiation of light (an electromagnetic wave) emitted from a lamp. Examples of the lamp include a halogen lamp, a metal halide lamp, a xenon arc lamp, a carbon arc lamp, a high pressure sodium lamp, and a high pressure mercury lamp. As the RTA apparatus, it is possible to use a gas RTA (GRTA) apparatus that uses a high-temperature gas for heating of the object.

The first heat treatment temperature is preferably higher than or equal to 100 °C and lower than the strain point of the substrate, further preferably higher than or equal to 150 °C and lower than or equal to 670 °C, still further preferably higher than or equal to 100 °C and lower than or equal to 450 °C, yet still further preferably higher than or equal to 150 °C and lower than or equal to 450 °C, yet still further preferably higher than or equal to 200 °C and lower than or equal to 450 °C, yet still further preferably higher than or equal to 300 °C and lower than or equal to 450 °C, yet still further preferably higher than or equal to 350 °C and lower than or equal to 450 °C. In the case where an oven is used for the first heat treatment, typically, heat treatment can be performed at 350 °C for one hour. With the RTA apparatus, the treatment time can be shortened. The treatment time is preferably longer than or equal to 1 minute and shorter than or equal to 10 minutes, further preferably longer than or equal to 3 minutes and shorter than or equal to 10 minutes, still further preferably longer than or equal to 5 minutes and shorter than or equal to 10 minutes. Note that in the case where treatment is performed in a short time with an RTA apparatus, the heating temperature can be higher than or equal to the strain point of the substrate in some cases. This allows the treatment time to be further shortened. In the case where the GRTA apparatus is used for the first heat treatment, typically, heat treatment can be performed at 650 °C for 6 minutes. In the first heat treatment, the substrate temperature is preferably within the above-described range. Note that the temperature in the first heat treatment is not limited to the above range.

The first heat treatment can be performed in an atmosphere including one or more of a noble gas, nitrogen, and oxygen. As an atmosphere including nitrogen or an atmosphere including oxygen, clean dry air (CDA) can be used. The first heat treatment is preferably performed in an atmosphere including oxygen. Performing the first heat treatment in an atmosphere including oxygen sometimes increases an effect such as a reduction of defects and an increase in the grain size of a crystal grain. As the atmosphere of the first heat treatment, CDA can be suitably used. Note that the content of hydrogen, water, or the like in the atmosphere is preferably as low as possible. As the atmosphere, a high-purity gas with a dew point of −60 °C or lower, preferably −100 °C or lower is preferably used. With the use of an atmosphere where the content of hydrogen, water, or the like is as low as possible, entry of hydrogen, water, or the like into the semiconductor layer 108 can be prevented as much as possible.

Note that the heat treatment can be omitted in this step, and heat treatment performed in a later step can also serve as the heat treatment in this step. In some cases, heat application treatment (e.g., film formation step) in a later step can serve as the first heat treatment in this step.

Next, an insulating film 106f to be the insulating layer 106 is formed to cover the semiconductor layer 108 and the insulating layer 105 (FIG. 9E). A plasma CVD method, a sputtering method, or an ALD method can be suitably used for the formation of the insulating layer 106f, for example.

When the temperature at the time of the formation of the insulating film 106f is increased, defects in the gate insulating layer can be reduced. However, the high temperature at the time of the formation of the insulating film 106f sometimes allows desorption of oxygen from the semiconductor layer 108, which increases the amounts of oxygen vacancies and V_{O}H in the semiconductor layer 108. The substrate temperature at the time of the formation of the insulating layer 106 is preferably higher than or equal to 180 °C and lower than or equal to 450 °C, further preferably higher than or equal to 200 °C and lower than or equal to 450 °C, still further preferably higher than or equal to 250 °C and lower than or equal to 450 °C, yet still further preferably higher than or equal to 300 °C and lower than or equal to 450 °C, yet still further preferably higher than or equal to 300 °C and lower than or equal to 400 °C. When the substrate temperature at the time of the formation of the insulating layer 106f is within the above range, desorption of oxygen from the semiconductor layer 108 can be inhibited while the defects in the insulating layer 106 can be reduced. Consequently, the transistor can have favorable electrical characteristics and high reliability.

Before the formation of the insulating film 106f, a surface of the semiconductor layer 108 can be subjected to plasma treatment. By the plasma treatment, impurities such as water adsorbed on the surface of the semiconductor layer 108 can be reduced. Accordingly, impurities at the interface between the semiconductor layer 108 and the insulating layer 106 can be reduced, enabling formation of a highly reliable transistor. Performing the plasma treatment in this manner is particularly favorable in the case where the surface of the semiconductor layer 108 is exposed to the air after the formation of the semiconductor layer 108 but before the formation of the insulating film 106f. The plasma treatment can be performed in an atmosphere of oxygen, ozone, nitrogen, dinitrogen monoxide, argon, or the like. The plasma treatment and the formation of the insulating film 106f are preferably performed successively without exposure to the air.

After the formation of the insulating film 106f, heat treatment (hereinafter, also referred to as second heat treatment) is performed. The second heat treatment can reduce defects in the insulating layer 106. The second heat treatment can remove an impurity included in the insulating layer 106 or adsorbed on its surface. For the second heat treatment, the description of the first heat treatment can be referred to. In the case where an oven is used for the second heat treatment, the second heat treatment is performed at a temperature of preferably higher than or equal to 300 °C and lower than or equal to 500 °C, and typically at 350 °C for one hour.

Here, a region with low crystallinity (e.g., an amorphous region) can exist between the crystal grains in the semiconductor layer 108. In particular, when a region with low crystallinity exists in the channel formation region, the field-effect mobility of the transistor might be decreased by carrier scattering. When heat treatment is performed a plurality of times (here, the first heat treatment and the second heat treatment), the grain size of the crystal grains is increased, so that the region with low crystallinity between the crystal grains can be decreased. With such a structure, a transistor with high field-effect mobility can be formed. In addition, performing the heat treatment a plurality of times can further reduce defects in the semiconductor layer 108. Moreover, impurities included in the semiconductor layer 108 or adsorbed on its surface can be removed efficiently.

After the formation of the insulating layer 106f, oxygen can be supplied to the insulating layer 106f. As a method for supplying oxygen, an ion implantation method or plasma treatment can be used, for example. The plasma treatment is preferably performed in an atmosphere including oxygen. For example, plasma treatment is preferably performed in an atmosphere including one or more of oxygen, dinitrogen monoxide (N₂O), nitrogen dioxide (NO₂), carbon monoxide, and carbon dioxide. The supply amount of oxygen can be adjusted by power and treatment time in the plasma treatment, for example.

A film 139 is preferably formed over the insulating film 106f (FIG. 9E). A sputtering method can be suitably used for the formation of the film 139. When the film 139 is formed in an atmosphere including oxygen, oxygen can be supplied to the insulating film 106f.

The film 139 preferably includes oxygen and can suitably be formed using an oxide or an oxynitride. There is no limitation on the conductivity of the film 139. For the film 139, at least one of an insulating film, a semiconductor film, and a conductive film can be used. For the film 139, aluminum oxide, hafnium oxide, hafnium aluminate, indium oxide, indium gallium oxide, IGZO, ITO, or ITSO can be used, for example.

A metal oxide including one or more elements included in the semiconductor layer 108 is preferably used for the film 139. It is particularly preferable to use a metal oxide that can be used for the semiconductor layer 108. When the semiconductor layer 108 and the film 139 are formed using the same material, the same apparatus can be used for the formation of the film 139 and the metal oxide film 108f; thus, the manufacturing cost can be reduced.

In the formation of the film 139, a larger amount of oxygen can be supplied to the insulating film 106f with a higher oxygen flow rate ratio of the film formation gas introduced into a treatment chamber of a film formation apparatus or with a higher oxygen partial pressure in the treatment chamber. The oxygen flow rate ratio is, for example, preferably higher than or equal to 50% and lower than or equal to 100%, further preferably higher than or equal to 60% and lower than or equal to 100%, still further preferably higher than or equal to 70% and lower than or equal to 100%, yet still further preferably higher than or equal to 80% and lower than or equal to 100%, yet still further preferably higher than or equal to 90% and lower than or equal to 100%. Typically, the oxygen flow rate ratio can be 100%. Note that the oxygen flow rate ratio can be rephrased as a proportion of the oxygen partial pressure to the pressure in the treatment chamber.

When the film 139 is formed by a sputtering method in an atmosphere including oxygen in the above manner, oxygen can be supplied to the insulating film 106f and desorption of oxygen from the insulating film 106f can be prevented during the formation of the film 139. As a result, a large amount of oxygen can be enclosed in the insulating film 106f. Moreover, a large amount of oxygen can be supplied to the semiconductor layer 108 by heat treatment performed later. Thus, the amounts of oxygen vacancies and V_{O}H in the semiconductor layer 108 can be reduced, whereby a transistor with favorable electrical characteristics and high reliability can be obtained.

Note that in the case where the insulating layer 106 includes excess oxygen, defect states are sometimes easily generated at the interface between the semiconductor layer 108 and the insulating layer 106 and the vicinity thereof. In this case, upon application of a high potential to the conductive layer 104 functioning as the gate electrode, electrons that are carriers are sometimes trapped by the defect states to cause the threshold voltage of the transistor to shift in the positive direction, leading to lower reliability. In such a case, it is preferable to reduce the oxygen flow rate ratio or the oxygen partial pressure for the formation of the film 139, thereby reducing the amount of oxygen supplied to the insulating film 106f. The oxygen flow rate ratio is preferably, for example, higher than or equal to 10% and lower than or equal to 60%, further preferably higher than or equal to 20% and lower than or equal to 60%, still further preferably higher than or equal to 30% and lower than or equal to 60%, yet still further preferably higher than or equal to 30% and lower than or equal to 50%. Thus, a change in the threshold voltage is inhibited, and the transistor can have high reliability.

After the formation of the film 139, heat treatment (hereinafter also referred to as third heat treatment) is preferably performed. By the third heat treatment, oxygen can be effectively supplied from the insulating film 106f to the semiconductor layer 108. Furthermore, oxygen can be supplied from the film 139 to the insulating film 106f. For the third heat treatment, the description of the first heat treatment can be referred to. In the case where an oven is used for the third heat treatment, the heat treatment can be performed typically at 350 °C for one hour.

After the formation of the film 139 or after the third heat treatment, oxygen can be further supplied to the insulating film 106f through the film 139. As a method for supplying oxygen, an ion implantation method or plasma treatment can be used, for example. For the plasma treatment, the above description can be referred to.

Next, the film 139 is removed. By the removal of the film 139, the insulating film 106f is exposed. There is no particular limitation on a method for removing the film 139, and a wet etching method can be suitably used. When a wet etching method is used, the film 139 can be inhibited from being etched at the time of the removal of the film 139. In that case, a reduction in the thickness of the insulating film 106f can be inhibited and the thickness of the insulating layer 106 can be uniform.

The treatment for supplying oxygen to the insulating film 106f is not necessarily performed by the above-described method. As a method for supplying oxygen, an ion implantation method or plasma treatment can be used, for example. Furthermore, a film that suppresses oxygen desorption is formed over the insulating film 106f and then, oxygen can be supplied to the insulating film 106f through the film. After the supply of oxygen, the film is preferably removed. The film that suppresses oxygen desorption can be formed using a conductive film or a semiconductor film including one or more of indium, zinc, gallium, tin, aluminum, chromium, tantalum, titanium, molybdenum, nickel, iron, cobalt, and tungsten.

Subsequently, a conductive film is formed over the insulating film 106f. Then, the conductive film and the insulating film 106f are processed to form the conductive layer 104 and the insulating layer 106 (FIG. 10A). For the formation of the conductive film, a sputtering method, a thermal CVD method (including an MOCVD method), or an ALD method can be suitably used, for example.

Next, the first element is supplied to the semiconductor layer 108 using the conductive layer 104 as a mask. Consequently, the region 108P and the region 108Q are formed in the region of the semiconductor layer 108 not overlapping with the conductive layer 104 (FIG. 10B). In FIG. 10B, a state where the first element is supplied to the semiconductor layer 108 is schematically shown by dashed arrows. In supply of the first element, the conditions of the treatment for supplying the first element are preferably determined in consideration of the material and thickness of the conductive layer 104 serving as a mask so that the amount of the first element which is supplied to a region of the semiconductor layer 108 overlapping with the conductive layer 104 is as small as possible. In this manner, the concentration of the first element in the region 108i of the semiconductor layer 108 that overlaps with the conductive layer 104 can be reduced.

Note that the first element can be supplied before removal of the resist mask used for forming the conductive layer 104 and the insulating layer 106. When the first element is supplied to the semiconductor layer 108 using the resist mask and the conductive layer 104 as a mask, the region 108P and the region 108Q can be formed. After that, the resist mask is removed.

In the transistor 100F shown in FIG. 6C and the like, the insulating layer 106 is provided over the regions 108R and 108S; the amount of the first element supplied to these regions is smaller than the amount of the first element supplied to the regions 108P and 108Q. In the transistor 100E shown in FIG. 6A and the like, the first element can be supplied to the semiconductor layer 108 using the conductive layer 104 as a mask after the formation of the insulating layer 106 and the conductive layer 104. In that case, the first element is supplied to the regions 108P and 108Q through the insulating layer 106.

Next, an insulating film 195f to be the insulating layer 195 is formed to cover the conductive layer 104, the insulating layer 106, and the semiconductor layer 108 (FIG. 10C). For the formation of the insulating film 195f, a plasma CVD method can be suitably used.

When the film formation temperature of the insulating film 195f is too high, the first element included in the regions 108P and 108Q might diffuse into a peripheral portion including the channel formation region. Furthermore, the electric resistance of each of the regions 108P and 108Q might be increased. Thus, the film formation temperature of the insulating film 195f is preferably determined in consideration of the diffusion of the first element.

The film formation temperature of the insulating film 195f is preferably higher than or equal to 150 °C and lower than or equal to 400 °C, further preferably higher than or equal to 180 °C and lower than or equal to 360 °C, still further preferably higher than or equal to 200 °C and lower than or equal to 250 °C, for example. When the insulating film 195f is formed at a low temperature, the transistor can have favorable electrical characteristics even with a short channel length.

Heat treatment can be performed after the formation of the insulating film 195f. By the heat treatment, the regions 108P and 108Q can have lower electric resistance in some cases. For the heat treatment, the above description can be referred to. Note that when the temperature of the heat treatment is too high (e.g., higher than or equal to 500 °C), the first element diffuses also into the channel formation region, so that the electrical characteristics and reliability of the transistor might be lowered. The heat treatment is not necessarily performed in this step. The heat treatment can be omitted in this step, and heat treatment performed in a later step can also serve as the heat treatment in this step. In some cases, heat application treatment (e.g., film formation step) in a later step can serve as the heat treatment in this step.

Next, part of the insulating film 195f is removed, so that the opening portion 147a and the opening portion 147b respectively reaching the region 108P and the region 108Q are formed (FIG. 10D). Accordingly, the insulating layer 195 is formed. The opening portions 147a and 147b can be suitably formed by a dry etching method, for example.

Subsequently, the conductive layer 112a and the conductive layer 112b are formed to cover the opening portion 147a and the opening portion 147b, respectively (FIG. 10D).

Next, the insulating layer 218 is formed over the insulating layer 195, the conductive layer 112a, and the conductive layer 112b (FIGS. 3A and 3B). A plasma CVD method can be suitably used for the formation of an inorganic insulating layer included in the insulating layer 218.

Through the above steps, the semiconductor device 10B of one embodiment of the present invention can be manufactured.

### Manufacturing Method Example 2

A manufacturing method example that is different from the manufacturing method example 1 described above will be described below. Note that portions similar to those described in the above the manufacturing method example 1 are not described in some cases.

First, as in the manufacturing method example 1, the processes up to the formation of the insulating layer 105 are performed (FIG. 9A).

As described above, in the case where the hydrogen concentration in the formed insulating layer 105 is high, the amount of hydrogen diffusing from the insulating layer 105 into the metal oxide film 108f is increased, which increases the hydrogen concentration in the semiconductor layer 108 in some cases. In such a case, heat treatment (hereinafter also referred to as fourth heat treatment) is preferably performed after the formation of the insulating layer 105 but before the formation of the metal oxide film 108f. This can reduce the hydrogen concentration in the insulating layer 105, making it possible to reduce the amount of hydrogen diffusing from the insulating layer 105 into the metal oxide film 108f. Furthermore, the fourth heat treatment can reduce defects in the insulating layer 105. For the fourth heat treatment, the description of the first heat treatment can be referred to.

The fourth heat treatment temperature is preferably higher than or equal to 100 °C and lower than the strain point of the substrate, further preferably higher than or equal to 150 °C and lower than or equal to 670 °C, still further preferably higher than or equal to 100 °C and lower than or equal to 450 °C, yet still further preferably higher than or equal to 150 °C and lower than or equal to 450 °C, yet still further preferably higher than or equal to 200 °C and lower than or equal to 450 °C, yet still further preferably higher than or equal to 300 °C and lower than or equal to 450 °C, yet still further preferably higher than or equal to 350 °C and lower than or equal to 450 °C. In the case where an oven is used for the fourth heat treatment, typically, heat treatment can be performed at 350 °C for one hour. In the case where a GRTA apparatus is used for the fourth heat treatment, typically, heat treatment can be performed at 650 °C for 6 minutes. In the fourth heat treatment, the substrate temperature is preferably within the above-described range. Note that the temperature in the fourth heat treatment is not limited to the above range.

Then, the metal oxide film 108f is formed over the insulating layer 105 (FIG. 9C). For the processes after the formation of the metal oxide film 108f, the description of FIGS. 9C to 9E and FIGS. 10A to 10D can be referred to.

Through the above steps, the semiconductor device 10B of one embodiment of the present invention can be manufactured.

### Manufacturing Method Example 3

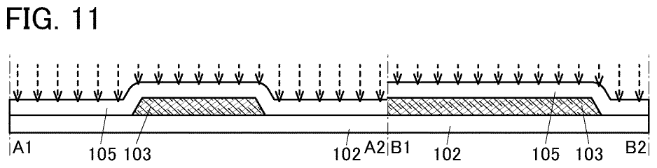

A manufacturing method example different from the manufacturing method example 1 and the manufacturing method example 2 described above is described with reference to FIG. 11. FIG. 11 shows a cross-sectional view taken along the dashed-dotted line A1-A2 in FIG. 3A and a cross-sectional view taken along the dashed-dotted line B1-B2 in FIG. 3B side by side. Note that portions similar to those described in the above manufacturing method example 1 are not described in some cases.

First, as in the manufacturing method example 1, the processes up to the formation of the insulating layer 105 are performed (FIG. 9A).

As described above, in the case where the hydrogen concentration in the formed insulating layer 105 is low, the amount of hydrogen diffusing from the insulating layer 105 into the metal oxide film 108f is reduced, which increases the crystallinity of the formed metal oxide film 108f in some cases. In such a case, plasma treatment is preferably performed in an atmosphere including a gas including a hydrogen element (e.g., H₂) after the formation of the insulating layer 105 but before the formation of the metal oxide film 108f. In FIG. 11, a state where hydrogen is supplied to the insulating layer 105 is schematically shown by dashed arrows. The method for supplying hydrogen is not limited to plasma treatment, and an ion implantation method or treatment employing thermal diffusion by heating can be used. For the method for supplying hydrogen, the description of the method for supplying the first element can be referred to. For example, a plasma CVD apparatus can be used for formation of the insulating layer 105 and supply of hydrogen to the insulating layer 105. In that case, the formation of the insulating layer 105 and the supply of hydrogen can be successively performed in the plasma CVD apparatus, whereby the productivity can be increased. For example, after the insulating layer 105 is formed with a plasma CVD apparatus, plasma treatment is performed in an atmosphere including a gas including a hydrogen element (e.g., H₂ or NH₃) in the same treatment chamber, whereby hydrogen can be supplied to the insulating layer 105.

Then, the metal oxide film 108f is formed over the insulating layer 105 (FIG. 9C). For the processes after the formation of the metal oxide film 108f, the description of FIGS. 9C to 9E and FIGS. 10A to 10D can be referred to.

Through the above steps, the semiconductor device 10B of one embodiment of the present invention can be manufactured.

This embodiment can be combined as appropriate with the other embodiments. In this specification, in the case where a plurality of structure examples are shown in one embodiment, the structure examples can be combined as appropriate.

### Embodiment 2

Described in this embodiment is an indium oxide film that can be used for the semiconductor layer of the transistor included in the semiconductor device of one embodiment of the present invention.

Note that in this specification and the like, indium oxide including at least a crystal part or a crystal region in a film is referred to as crystal indium oxide (crystal IO) or crystalline indium oxide (crystalline IO). Examples of crystal IO or crystalline IO include single-crystalline indium oxide, polycrystalline indium oxide, and microcrystalline indium oxide.

Indium oxide is a semiconductor material having physical properties completely different from those of an oxide semiconductor such as In—Ga—Zn oxide (hereinafter, also referred to as IGZO) or zinc oxide.

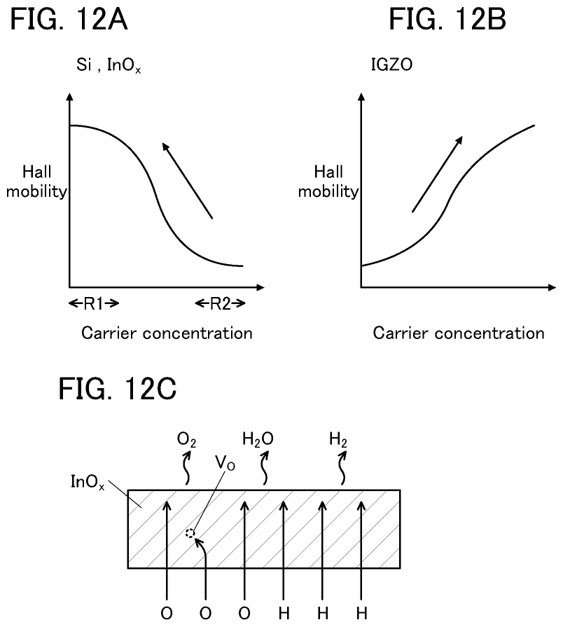

The dependence of the Hall mobility on the carrier concentration of indium oxide, silicon, and IGZO will be described. FIG. 12A is a schematic view showing the dependence of the Hall mobility on the carrier concentration of silicon (Si) and indium oxide (InO_{X}), and FIG. 12B is a schematic view showing the dependence of the Hall mobility on the carrier concentration of IGZO.

As indicated by an arrow in FIG. 12B, IGZO has a tendency in which the Hall mobility is higher as the carrier concentration is higher. By contrast, as indicated by an arrow in FIG. 12A, indium oxide has a tendency in which the Hall mobility is higher as the carrier concentration is lower (see Non-Patent Document 4). This tendency is similar to that of silicon; as the concentration of a dopant (impurity) in a material is lower, impurity scattering is inhibited more and thus the Hall mobility is higher. That is, indium oxide having higher purity and being more intrinsic has higher Hall mobility. Consequently, the physical properties of indium oxide are different from those of IGZO and similar to those of silicon. Note that the characteristics of indium oxide in FIG. 12A are based on the assumption of single-crystalline indium oxide; thus, the characteristics of non-single-crystalline indium oxide (e.g., polycrystalline indium oxide) are sometimes different from those in FIG. 12A.

In FIG. 12A, the Hall mobility is extremely high in a range R1 with a low carrier concentration; thus, the range R1 can be regarded as a carrier concentration range suitable for a channel formation region of a transistor, for example. In the case of indium oxide, for example, the range R1 is a range including a carrier concentration of 1×10¹⁵ cm⁻³, e.g., a range with a carrier concentration higher than or equal to 1×10¹⁴ cm⁻³ and lower than or equal to 1×10¹⁸ cm⁻³. The adequately lowered carrier concentration will increase the Hall mobility to approximately 270 cm²/(V·s).

A region of indium oxide where the carrier concentration falls within the range R1 can include an element that reduces the carrier concentration. Examples of the element that reduces the carrier concentration include magnesium, calcium, zinc, cadmium, and copper. When indium is replaced with any of these elements, the carrier concentration can be reduced. Other examples of the element that reduces the carrier concentration include nitrogen, phosphorus, arsenic, and antimony. For example, when oxygen is replaced with nitrogen, phosphorus, arsenic, or antimony, the carrier concentration can be reduced.

The element that reduces the carrier concentration can be regarded as an element that imparts p-type conductivity. When the element that reduces the carrier concentration is added to the indium oxide film, the indium oxide film easily becomes i-type or substantially i-type in some cases. In that case, the concentration of the element that reduces the carrier concentration in the indium oxide film is preferably higher than or equal to 1×10¹⁶ atoms/cm³ and lower than or equal to 8×10²⁰ atoms/cm³, further preferably higher than or equal to 1×10¹⁶ atoms/cm³ and lower than or equal to 4×10²⁰ atoms/cm³, still further preferably higher than or equal to 1×10¹⁶ atoms/cm³ and lower than or equal to 8×10¹⁹ atoms/cm³, yet still further preferably higher than or equal to 1×10¹⁶ atoms/cm³ and lower than or equal to 5×10¹⁹ atoms/cm³. With such a concentration, the carrier concentration can be reduced while the crystal structure of indium oxide is maintained.

A range R2 with a high carrier concentration has low electric resistance and is a carrier concentration range suitable for a source region and a drain region of a transistor, a resistor, or a transparent conductive film, for example. The range R2 is a range including a carrier concentration of 1×10²⁰ cm⁻³, e.g., a range with a carrier concentration higher than or equal to 1×10¹⁹ cm⁻³ and lower than or equal to 1×10²² cm⁻³. The adequately increased carrier concentration will decrease the resistivity to 1×10⁻⁴ Ω·cm or lower.

A region of indium oxide where the carrier concentration falls within the range R2 can include an element that increases the carrier concentration. For example, the region preferably includes the same element as a source electrode and a drain electrode of a transistor. Examples of the element that increases the carrier concentration include titanium, zirconium, hafnium, tantalum, tungsten, molybdenum, tin, silicon, and boron. It is particularly preferable that an oxide of the element have conductivity or semiconductor properties. As a method for supplying the element that increases the carrier concentration, a method in which a film including the element is formed to diffuse the element, an ion implantation method, an ion doping method, a plasma immersion ion implantation method, or plasma treatment can be employed. In this specification and the like, whether or not mass separation is performed is not limited, unless otherwise specified.

The element that increases the carrier concentration can also be referred to as an element that imparts n-type conductivity. The concentration of the element that increases the carrier concentration in the indium oxide film is preferably higher than or equal to 1×10¹⁶ atoms/cm³ and lower than or equal to 8×10²⁰ atoms/cm³, further preferably higher than or equal to 1×10¹⁶ atoms/cm³ and lower than or equal to 4×10²⁰ atoms/cm³, still further preferably higher than or equal to 1×10¹⁶ atoms/cm³ and lower than or equal to 8×10¹⁹ atoms/cm³, yet still further preferably higher than or equal to 1×10¹⁶ atoms/cm³ and lower than or equal to 5×10¹⁹ atoms/cm³. With such a concentration, the carrier concentration can be increased while the crystal structure of indium oxide is maintained. Note that antimony sometimes functions as an element that increases the carrier concentration.

Since indium oxide is an oxide whose valence electron can be controlled in this manner, indium oxide enables control of the threshold voltage of a transistor using a semiconductor layer including indium oxide. Furthermore, the region with a low carrier concentration and the region with a high carrier concentration of indium oxide are used respectively as a channel formation region and source and drain regions of a transistor. As for IGZO, distortion due to stress of an electrode in contact with IGZO is formed in a source region and a drain region and n-type regions are formed in some cases. Since a valence electron can be controlled in indium oxide unlike in IGZO, formation of distortion can be inhibited in a film of indium oxide. The film with less distortion will have higher reliability. For example, when the region where the carrier concentration falls within the range R1 and the region where the carrier concentration falls within the range R2, which are shown in FIG. 12A, are separately formed in an indium oxide film, what is called an n-i-n junction (a junction between an n-type region, an i-type region, and an n-type region) can be formed. Although valence electron control in a transistor including silicon is generally known, valence electron control in a transistor including indium oxide is a novel technical idea that cannot be conceived usually.

With the use of the above technical idea, a transistor including indium oxide in this specification and the like has two or more, preferably three or more, further preferably four or more, and most preferably all of the following features (1) to (5): (1) high on-state current (i.e., high mobility); (2) low off-state current; (3) normally-off characteristics; (4) high reliability; and (5) high cutoff frequency (fT). For example, the transistor including indium oxide in this specification and the like has high mobility, low off-state current, and normally-off characteristics. This transistor is different from a normally-on transistor having high mobility.

The expression “a semiconductor is of an i-type” can be replaced with the expression “the Fermi level (Ef) is equal to the intrinsic Fermi level (Ei)(Ef=Ei)”. As shown in FIG. 12B, the Hall mobility is lower as the carrier concentration is lower in IGZO. Accordingly, in the case where Ef eventually becomes equal to Ei, carriers disappear (i.e., the physical properties of IGZO become similar to those of an insulator) and a transistor including IGZO cannot operate. By contrast, the Hall mobility is higher as the carrier concentration is lower in indium oxide as shown in FIG. 12A. In the case where Ef eventually becomes equal to Ei, the Hall mobility is the highest. That is, a transistor including indium oxide can have high field-effect mobility when Ef is equal to Ei. Note that a transistor including indium oxide has a low carrier concentration and thus tends to be normally off. Hence, a transistor including indium oxide can have both normally-off characteristics and high field-effect mobility.

Normally off means a state where no current flows through a transistor when a potential is not applied to its gate or its gate-source voltage is 0 V. The normally-off characteristics can be evaluated using the threshold voltage (Vₜₕ) or shift value (Vₛₕ) of a transistor. Note that Vₜₕ is calculated by a constant current method unless otherwise specified. Specifically, Vₜₕ is a gate voltage (V_{g}) at which a value of drain current (I_{d})×channel length (L)÷channel width (W) in the I_{d}-V_{g} characteristics of a transistor is 1 nA (1×10⁻⁹ A). Vₛₕ is gate voltage (V_{g}) at a point of intersection of a straight line of I_{d}=1 pA (1×10⁻¹² A) and a tangent line of drain current (I_{d}) on a logarithmic scale that has the highest gradient in the I_{d}-V_{g} characteristics of the transistor, or a gate voltage (V_{g}) at a point of intersection of a straight line of I_{d}=1 pA and a straight line extrapolated from two points where the slope of I_{d} on a logarithmic scale has the highest gradient in the I_{d}-V_{g} characteristics of the transistor. For example, when at least one of Vₜₕ and Vₛₕ is 0 or a positive value, the transistor can be regarded as being normally off.

In order that a semiconductor can be of an i-type, i.e., Ef can be equal to Ei, in a transistor including indium oxide, the structure of a film in contact with an indium oxide film is important. For example, a transistor including indium oxide can have a film structure in which a silicon oxide film, which is in contact with an indium oxide film, a hafnium oxide film, and a silicon nitride film are stacked. Such a film structure can achieve Ef=Ei, enabling a semiconductor device to have high reliability.

In the above film structure, a film including oxygen, such as a silicon oxynitride film, a silicon nitride oxide film, an aluminum oxide film, or a gallium oxide film, can be used instead of the silicon oxide film. Also in the above film structure, a silicon nitride oxide film, a silicon oxynitride film, or the like can be used instead of the silicon nitride film. The hafnium oxide film that is closer to the indium oxide film than the silicon nitride film is functions as a hydrogen gettering site.

The above film structure can be regarded as a structure in which a film that is capable of supplying oxygen to the indium oxide film (e.g., the silicon oxide film), a film that is capable of gettering hydrogen (e.g., the hafnium oxide film), and a film that is capable of inhibiting entry of oxygen and hydrogen (e.g., the silicon nitride film) are stacked in this order from the indium oxide film side. With this structure, oxygen vacancies in the indium oxide film are filled with oxygen in the silicon oxide film. Moreover, hydrogen in the indium oxide film is captured in the hafnium oxide film by heat treatment or the like. Providing the silicon nitride film inhibits entry of oxygen and hydrogen from the outside. That is, the above film structure enables the indium oxide film to be closer to an i-type film. Thus, a transistor including the indium oxide film has high field-effect mobility and high reliability.

Next, an indium oxide film used for a transistor will be described. The indium oxide film preferably has crystallinity (i.e., has a crystal grain). Examples of a film having a crystal grain include a single-crystalline film, a polycrystalline film, and an amorphous film having a crystal grain (also referred to as a microcrystalline film). In particular, the indium oxide film is preferably a polycrystalline film, further preferably a single-crystalline film. A single-crystalline film does not have a crystal grain boundary (also referred to as a grain boundary). Impurities that block the carrier flow (typically, an insulating impurity, an insulating oxide, or the like) are likely to be segregated at a crystal grain boundary. The use of a single-crystalline film can inhibit carrier scattering or the like at the crystal grain boundary, thereby achieving a transistor having high field-effect mobility. In addition, the use of a single-crystalline film produces an excellent effect of reducing a variation in transistor characteristics caused by the crystal grain boundary.

A polycrystalline film is preferable because it can reduce carrier scattering as compared with a microcrystalline film or an amorphous film and enables a transistor to have high field-effect mobility. In the case of using a polycrystalline film, it is preferable to use a film that has as large a crystal grain size as possible and few crystal grain boundaries. Note that in the case where the crystal grain boundary is neither included nor observed in a channel formation region of a transistor including a polycrystalline indium oxide film, the channel formation region is positioned in a single crystal region included in the polycrystalline film and thus the transistor can be regarded as a transistor including single-crystalline indium oxide.

In this specification and the like, a semiconductor layer where no crystal grain boundary is observed in a channel formation region, a semiconductor layer where a channel formation region is included in one crystal grain, or a semiconductor layer where the directions of crystal axes of at least two regions in a channel formation region are the same can be referred to as a single-crystalline film. A semiconductor layer where the direction of a crystal axis is continuously changed with another crystal axis or a crystal orientation as a rotation axis in one crystal grain in a channel formation region can also be referred to as a single-crystalline film.

A channel formation region refers to a region of a semiconductor layer that overlaps with (or faces) a gate electrode with a gate insulating layer therebetween and is positioned between a region in contact with a source electrode and a region in contact with a drain electrode. A current path in a channel formation region is the shortest distance between a source electrode and a drain electrode. Thus, a crystal grain, a crystal grain boundary, a crystal axis, a crystal orientation, or the like in a channel formation region can be confirmed in observation of a cross section of a semiconductor layer in the channel length direction (e.g., observation of a cross section including a semiconductor layer, a source electrode, and a drain electrode).

The indium oxide film may include an element that can form a trivalent cation like indium as long as the cubic crystal structure (bixbyite structure) is maintained. Examples of the element include Group 13 elements such as gallium and aluminum and Group 3 elements in the periodic table. These elements are each more strongly bonded to oxygen than indium is; thus, the addition of such an element to the indium oxide film can inhibit formation of oxygen vacancies (V_{O}) in the indium oxide film. Since these elements exist mainly as trivalent cations in oxides, the carrier concentration in the indium oxide film can be kept low. In this way, the threshold voltage of the transistor can shift in the positive direction. In addition, a transistor can be normally off. Accordingly, a transistor with favorable electrical characteristics can be provided.

The concentration of the above element in the indium oxide film is, for example, preferably higher than or equal to 1×10¹⁶ atoms/cm³ and lower than or equal to 8×10²⁰ atoms/cm³, further preferably higher than or equal to 1×10¹⁶ atoms/cm³ and lower than or equal to 4×10²⁰ atoms/cm³, still further preferably higher than or equal to 1×10¹⁶ atoms/cm³ and lower than or equal to 8×10¹⁹ atoms/cm³, yet still further preferably higher than or equal to 1×10¹⁶ atoms/cm³ and lower than or equal to 5×10¹⁹ atoms/cm³.

Note that the element that imparts n-type conductivity, the element that imparts p-type conductivity, and the element that can form a trivalent cation can each be added to the indium oxide film by an ion doping method, an ion implantation method, a thermal diffusion method, or the like. Alternatively, the element that imparts n-type conductivity, the element that imparts p-type conductivity, and the element that can form a trivalent cation can each be added to a sputtering target, a film formation gas, a precursor for formation using ALD, or the like in the formation of the indium oxide film. Alternatively, the element that imparts n-type conductivity, the element that imparts p-type conductivity, and the element that can form a trivalent cation can each be added by auto-doping from a chamber in the formation of the indium oxide film. Note that auto-doping refers to addition of an element included in a member of a chamber used for the film formation, for example, into the film in the formation of the indium oxide film.

A transistor including the above indium oxide film can have a field-effect mobility higher than or equal to 50 cm²/(V·s), preferably higher than or equal to 100 cm²/(V·s), further preferably higher than or equal to 150 cm²/(V·s), still further preferably higher than or equal to 200 cm²/(V·s), yet still further preferably higher than or equal to 250 cm²/(V·s).

One feature of an indium oxide film is to have a higher property of transmitting (diffusing) oxygen than an IGZO film. As shown in FIG. 12C, oxygen (O) diffusing in an indium oxide film (denoted as InO_{X}) is transmitted through the indium oxide film and desorbed as an oxygen molecule (O₂). When reacting with hydrogen included in the film, oxygen is desorbed as a water molecule (H₂O) in some cases. In the case where the film includes oxygen vacancies (V^{O}), the oxygen vacancies are filled with diffusing oxygen atoms. Since oxygen easily diffuses in the indium oxide film, oxygen vacancies in the indium oxide film are filled with oxygen more easily than those in an IGZO film.

As described above, the oxygen vacancies in the indium oxide film are reduced more easily than those in the IGZO film; thus, a transistor including such an indium oxide film can have extremely high reliability.

As shown in FIG. 12C, hydrogen diffuses in the indium oxide film. Hydrogen diffusing into the indium oxide film from the outside is transmitted through the indium oxide film and is desorbed as a hydrogen molecule (H₂). When reacting with oxygen included in the film, hydrogen is desorbed as a water molecule. Note that oxygen and hydrogen described above diffuse in the indium oxide film by heat treatment. The temperature of the heat treatment is higher than or equal to 200 °C and lower than or equal to 700 °C, preferably higher than or equal to 350 °C and lower than or equal to 650 °C, further preferably higher than or equal to 400 °C and lower than or equal to 500 °C.

A transistor including an indium oxide film is an accumulation-type transistor in which electrons are majority carriers. Assuming that the relaxation time of carriers is constant, the electron (carrier) mobility is higher as the effective mass of electrons (carriers) is smaller. That is, a transistor including indium oxide with a small effective mass of electrons can have high on-state current or high field-effect mobility.

Table 1 shows the effective mass in each of single-crystalline indium oxide (here, In₂O₃) and single-crystalline silicon (Si). As shown in Table 1, indium oxide has features of a small effective mass of electrons and a large effective mass of holes. In addition, the effective mass of electrons in indium oxide hardly depends on the crystal orientation. Thus, a transistor including indium oxide having crystallinity can have high field-effect mobility and high frequency characteristics (also referred to as f characteristics). A large effective mass of holes allows a transistor to have an extremely low off-state current. For example, the off-state current per micrometer of channel width of a vertical transistor including an indium oxide film can be lower than or equal to 1 fA (1×10⁻¹⁵ A) or lower than or equal to 1 aA (1×10⁻¹⁸ A) at 125 °C, and can be lower than or equal to 1 aA (1×10⁻¹⁸ A) or lower than or equal to 1 zA (1×10⁻²¹ A) at room temperature (25 °C). Since indium oxide has a smaller effective mass of electrons and a larger effective mass of holes than silicon as shown in Table 1, a transistor including indium oxide can have higher field-effect mobility and lower off-state current than a Si transistor.

TABLE 1
Effective mass in In₂O₃

| Electron | | | |
|---|---|---|---|
| [100] | [110] | [111] | |
| direction | direction | direction | Hole |
| 0.17 | 0.18 | 0.19 | 3.56 |

Effective mass in Si

| Electron | Hole |
|---|---|
| 0.26 | 0.17 |

A seed layer is preferably provided in contact with at least part of the indium oxide film having crystallinity. A material of the seed layer is preferably selected such that the difference in a lattice constant (also referred to as lattice mismatch) between the crystal included in indium oxide and the crystal included in the material is small. In this case, the crystallinity of the indium oxide film can be improved. As a layer in contact with at least part of the indium oxide film having crystallinity, a substrate (e.g., a single-crystalline substrate) may be used.

One of methods for evaluating a lattice mismatching level is a method using a value of a lattice mismatch degree described below. A lattice mismatch degree Aa [%] of a crystal included in a film to be formed (here, the indium oxide film) with respect to the crystal included in the seed layer is calculated by the formula: Aa=((L₁−L₂)/L₂)×100. Here, L₁ is the lattice constant or the length of the unit lattice vector of the crystal included in the film to be formed, and L₂ is the lattice constant or the length of the unit lattice vector of the crystal included in the seed layer.

The absolute value of the lattice mismatch degree Aa between the seed layer and the indium oxide film is preferably as small as possible, most preferably 0. For example, Aa can be greater than or equal to −5% and less than or equal to 5%, preferably greater than or equal to −4% and less than or equal to 4%, further preferably greater than or equal to −3% and less than or equal to 3%, still further preferably greater than or equal to −2% and less than or equal to 2%.

An indium oxide crystal has a cubic crystal structure (a bixbyite structure). For example, an yttria-stabilized zirconia (YSZ) crystal can have a cubic crystal structure (a fluorite crystal structure). The lattice mismatch degree of an indium oxide crystal with respect to a YSZ crystal having the cubic crystal structure is within the range of −2% to 2%, which enables epitaxial growth of a single-crystalline film of indium oxide on the YSZ substrate.

The crystal structures of the seed layer and the indium oxide film do not necessarily have the same crystal system or crystal orientation in some cases. For example, a film including a crystal with a hexagonal crystal structure or a trigonal crystal structure can be provided below an indium oxide film including a crystal with a cubic crystal structure. For example, when the crystal orientation of a seed layer surface is set to and the crystal orientation of a bottom surface of the indium oxide film is set to [111], the necessary condition for crystal orientation in epitaxial growth can be satisfied. Examples of a hexagonal or trigonal crystal structure include a wurtzite structure, a YbFe₂O₄-type structure, a Yb₂Fe₃O₇-type structure, and variations of these structures. An example of a crystal having a YbFe₂O₄-type structure or a Yb₂Fe₃O₇-type structure is IGZO. A single-crystalline film of indium oxide can be formed not only over a YSZ substrate but also over an insulating film. By contrast, a single-crystalline film of silicon is not easily formed over an insulating film. Note that a silicon crystal has a diamond structure. Thus, although indium oxide and silicon exhibit similar characteristics as single crystals, they differ in whether a single crystal can be formed over an insulating film.

At least part of this embodiment can be implemented as appropriate in combination with any of the other embodiments described in this specification.

### Embodiment 3

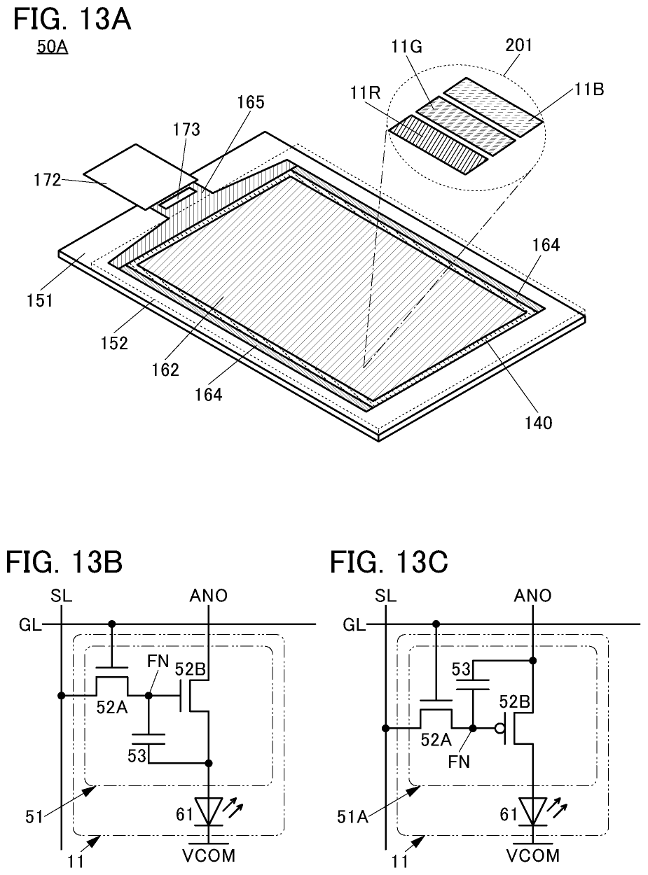

In this embodiment, a display device of one embodiment of the present invention will be described below with reference to FIGS. 13A to 13C, FIGS. 14A and 14B, FIGS. 15A and 15B, FIG. 16, FIG. 17, FIGS. 18A to 18C, FIGS. 19A and 19B, FIGS. 20A and 20B, FIG. 21, FIG. 22, and FIG. 23.

The display device in this embodiment can be a high-resolution display device or a large-sized display device. Accordingly, the display device in this embodiment can be used for display portions of electronic appliances such as a digital camera, a digital video camera, a digital photo frame, a mobile phone, a portable game console, a portable information terminal, and an audio reproducing device, in addition to display portions of electronic appliances with a relatively large screen, such as a television device, a desktop or laptop computer, a monitor of a computer or the like, digital signage, and a large game machine such as a pachinko machine.

The display device in this embodiment can be a high-resolution display device. Accordingly, the display device in this embodiment can be used for display portions of information terminals (wearable devices) such as watch-type and bracelet-type information terminals and display portions of wearable devices capable of being worn on a head, such as a VR device like a head-mounted display (HMD) and a glasses-type AR device.

The semiconductor device of one embodiment of the present invention can be used for a display device or a module including the display device. Examples of the module including the display device include a module in which a connector such as a flexible printed circuit board (hereinafter, also referred to as an FPC) or a tape carrier package (TCP) is attached to the display device and a module in which the display device is mounted with an integrated circuit (IC) by a chip on glass (COG) method, a chip on film (COF) method, or the like.

The display device in this embodiment may have a function of a touch panel. The display device can employ any of a variety of sensor elements that can sense proximity or touch of a sensing target such as a finger, for example.

Examples of a sensor type include a capacitive type, a resistive type, a surface acoustic wave type, an infrared type, an optical type, and a pressure-sensitive type.

Examples of a capacitive type include a surface capacitive type and a projected capacitive type. Examples of a projected capacitive type include a self-capacitive type and a mutual capacitive type. The use of a mutual capacitive type is preferable because multiple points can be detected simultaneously.

Examples of a touch panel include an out-cell touch panel, an on-cell touch panel, and an in-cell touch panel. An in-cell touch panel has a structure in which an electrode included in a sensor element is provided on one or both of a substrate supporting a display element and a counter substrate.

### Structure Example 1 of Display Device

FIG. 13A is a perspective view of a display device 50A.

In the display device 50A, a substrate 152 and a substrate 151 are attached to each other. In FIG. 13A, the substrate 152 is denoted by a dashed line.

The display device 50A includes a display portion 162, a connection portion 140, a circuit portion 164, a conductive layer 165, and the like. FIG. 13A shows an example where an IC 173 and an FPC 172 are implemented onto the display device 50A. Thus, the structure shown in FIG. 13A can be regarded as a display module including the display device 50A, the IC, and the FPC.

The connection portion 140 is provided outside the display portion 162. The connection portion 140 can be provided along one or more sides of the display portion 162. The number of the connection portions 140 may be one or more. FIG. 13A shows an example where the connection portion 140 is provided to surround the four sides of the display portion 162. In the connection portion 140, a common electrode of a display element is connected to a conductive layer so that a potential can be supplied to the common electrode.

The circuit portion 164 includes a scan line driver circuit (also referred to as a gate driver), for example. The circuit portion 164 may include both a scan line driver circuit and a signal line driver circuit (also referred to as a source driver).

As the circuit portion 164, a variety of circuits such as a shift register circuit, a level shifter circuit, an inverter circuit, a latch circuit, an analog switch circuit, a demultiplexer circuit, and a logic circuit can be used. A transistor, a capacitor, and the like can be used in the circuit portion 164. Transistors included in the circuit portion 164 can be formed in the same step as transistors included in the pixel circuit.

The conductive layer 165 has a function of supplying a signal and power to the display portion 162 and the circuit portion 164. The signal and power are input to the conductive layer 165 from the outside of the display device 50A through the FPC 172 or from the IC 173.

FIG. 13A shows an example where the IC 173 is provided on the substrate 151 by a COG method. An IC including one or both of a scan line driver circuit and a signal line driver circuit can be used as the IC 173, for example. Note that the display device 50A and the display module are not necessarily provided with an IC. Alternatively, the IC may be mounted on the FPC by a COF method or the like.

The semiconductor device of one embodiment of the present invention can be used for one or both of the display portion 162 and the circuit portion 164 of the display device 50A, for example. An oxide semiconductor (OS) can be suitably used for a channel formation region of a transistor included in the display device. By using an OS transistor, a display device can have low power consumption. Alternatively, the semiconductor device of one embodiment of the present invention can be used for both the display portion 162 and the circuit portion 164, that is, all the transistors included in the display device can be OS transistors. Using OS transistors as all the transistors included in the display device as described above has an effect of reducing the manufacturing cost.

When the semiconductor device of one embodiment of the present invention is used for a pixel circuit of the display device, the area occupied by the pixel circuit can be reduced and the display device can have high resolution, for example. When the semiconductor device of one embodiment of the present invention is used for a driver circuit (e.g., one or both of a gate line driver circuit and a source line driver circuit) of the display device, the area occupied by the driver circuit can be reduced and the display device can have a narrow bezel, for example. Since the semiconductor device of one embodiment of the present invention has favorable electrical characteristics, a display device can have increased reliability by using the semiconductor device.

The display portion 162 of the display device 50A is a region where an image is to be displayed, and includes a plurality of pixels 201 that are periodically arranged. An enlarged view of one pixel 201 is shown in FIG. 13A.

There is no particular limitation on the arrangement of pixels in the display device of one embodiment of the present invention, and a variety of arrangements can be employed. Examples of the arrangement of pixels include stripe arrangement, S-stripe arrangement, matrix arrangement, delta arrangement, Bayer arrangement, and PenTile arrangement.

The pixel 201 shown in FIG. 13A includes a subpixel 11R that emits red light, a subpixel 11G that emits green light, and a subpixel 11B that emits blue light. Note that the subpixels 11R, 11G, and 11B are collectively referred to as a subpixel 11 in some cases. There is no particular limitation on the number of subpixels included in one pixel.

The subpixels 11R, 11G, and 11B each include a display element and a pixel circuit for controlling the driving of the display element.

Any of a variety of elements can be used as the display element, and a liquid crystal element or a light-emitting element can be used, for example. Alternatively, a micro electro mechanical systems (MEMS) shutter element, an optical interference type MEMS element, or a display element using a microcapsule method, an electrophoretic method, an electrowetting method, an Electronic Liquid Powder (registered trademark) method, or the like can be used. Alternatively, a quantum-dot LED (QLED) employing a light source and color conversion technology using quantum dot materials can be used.

Examples of display devices that include liquid crystal elements include a transmissive liquid crystal display device, a reflective liquid crystal display device, and a transflective liquid crystal display device.

Examples of modes applicable to the display devices that include liquid crystal elements include a vertical alignment (VA) mode, a fringe field switching (FFS) mode, an in-plane-switching (IPS) mode, a twisted nematic (TN) mode, an axially symmetric aligned micro-cell (ASM) mode, an optically compensated birefringence (OCB) mode, a ferroelectric liquid crystal (FLC) mode, an antiferroelectric liquid crystal (AFLC) mode, an electrically controlled birefringence (ECB) mode, and a guest-host mode. Examples of the VA mode include a multi-domain vertical alignment (MVA) mode, a patterned vertical alignment (PVA) mode, and an advanced super view (ASV) mode.

Examples of liquid crystal materials that can be used for the liquid crystal element include a thermotropic liquid crystal, a low-molecular liquid crystal, a high-molecular liquid crystal, a polymer dispersed liquid crystal (PDLC), a polymer network liquid crystal (PNLC), a ferroelectric liquid crystal, and an anti-ferroelectric liquid crystal. Such a liquid crystal material exhibits a cholesteric phase, a smectic phase, a cubic phase, a chiral nematic phase, an isotropic phase, a blue phase, or the like depending on conditions. As the liquid crystal material, either a positive liquid crystal or a negative liquid crystal may be used, and the selection can be made in accordance with the mode or design that is used.

As the light-emitting element, a self-luminous light-emitting element such as a light-emitting diode (LED), an organic LED (OLED), or a semiconductor laser can be used. Examples of the LED include a mini LED and a micro LED.

Examples of a light-emitting substance included in the light-emitting element include a substance emitting fluorescent light (a fluorescent material), a substance emitting phosphorescent light (a phosphorescent material), a substance exhibiting thermally activated delayed fluorescence (a thermally activated delayed fluorescent (TADF) material), and an inorganic compound (e.g., a quantum dot material).

Examples of quantum dot materials include a colloidal quantum dot material, an alloyed quantum dot material, a core-shell quantum dot material, and a core quantum dot material. The quantum dot material including elements belonging to Groups 2 and 16, elements belonging to Groups 13 and 15, elements belonging to Groups 13 and 17, elements belonging to Groups 11 and 17, or elements belonging to Groups 14 and 15 can be used. Alternatively, a quantum dot material including an element such as cadmium (Cd), selenium (Se), zinc (Zn), sulfur(S), phosphorus (P), indium (In), tellurium (Te), lead (Pb), gallium (Ga), arsenic (As), or aluminum (Al) can be used.

The light-emitting element can emit infrared, red, green, blue, cyan, magenta, yellow, or white light, for example. When the light-emitting element has a microcavity structure, higher color purity can be achieved.

One of a pair of electrodes of the light-emitting element serves as an anode, and the other electrode serves as a cathode.

The display device of one embodiment of the present invention can have any of the following structures: a top-emission structure in which light is emitted in a direction opposite to the substrate where the light-emitting element is formed, a bottom-emission structure in which light is emitted toward the substrate where the light-emitting element is formed, and a dual-emission structure in which light is emitted toward both surfaces.

The semiconductor device of one embodiment of the present invention includes a transistor with a high on-state current. An oxide semiconductor (OS) can be suitably used for a channel formation region of the transistor, so that the transistor can have a low off-state current. The semiconductor device of one embodiment of the present invention can be suitably used for one or both of the display portion 162 and the circuit portion 164. Alternatively, the semiconductor device of one embodiment of the present invention can be used for both the display portion 162 and the circuit portion 164, that is, all the transistors included in the display device can be OS transistors. Using OS transistors as all the transistors included in the display device as described above has an effect of reducing the manufacturing cost.

Note that the transistor included in the display device of this embodiment is not limited to the transistor of one embodiment of the present invention. For example, the display device of this embodiment may include the transistor of one embodiment of the present invention and a transistor having another structure in combination.

The display device of this embodiment may include one or more of a planar transistor, a staggered transistor, and an inverted staggered transistor. A transistor included in the display device of this embodiment may have a top-gate structure or a bottom-gate structure. Alternatively, gates may be provided above and below a semiconductor layer where a channel is formed.

The display device of this embodiment may include a transistor using silicon in its channel formation region (also referred to as a Si transistor).

The transistor included in the circuit portion 164 and the transistor included in the display portion 162 may have the same structure or different structures. One structure or two or more kinds of structures may be employed for a plurality of transistors included in the circuit portion 164. Similarly, one structure or two or more kinds of structures may be employed for a plurality of transistors included in the display portion 162.

All of the transistors included in the display device may be OS transistors or Si transistors. Alternatively, some of the transistors included in the display device may be OS transistors and the others may be Si transistors. Examples of silicon include single-crystalline silicon, polycrystalline silicon, microcrystalline silicon, and amorphous silicon. An example of polycrystalline silicon is low-temperature polysilicon (LTPS). A transistor including LTPS in its channel formation region (also referred to as an LTPS transistor) has high field-effect mobility and can operate at high speed.

For example, when both an LTPS transistor and an OS transistor are used in the display portion 162, the display device can have low power consumption and high drive capability. Note that a structure in which an LTPS transistor and an OS transistor are used in combination is referred to as LTPO in some cases. As a favorable example, a structure is given in which the OS transistor is used as a transistor functioning as a switch for controlling electrical continuity and discontinuity between wirings and the LTPS transistor is used as a transistor for controlling a current.

### Structure Example of Subpixel

FIG. 13B shows a structure example of the subpixel 11. The subpixel 11 includes a pixel circuit 51 and a light-emitting device 61.

The pixel circuit 51 includes a transistor 52A, a transistor 52B, and a capacitor 53. The pixel circuit 51 is a 2Tr1C-type pixel circuit including two transistors and one capacitor. Note that there is no particular limitation on the pixel circuit that can be used for the display device of one embodiment of the present invention.

An anode of the light-emitting device 61 is electrically connected to one of a source and a drain of the transistor 52B and one electrode of the capacitor 53. The other of the source and the drain of the transistor 52B is connected to a wiring ANO. A gate of the transistor 52B is connected to one of a source and a drain of the transistor 52A and the other electrode of the capacitor 53. The other of the source and the drain of the transistor 52A is connected to a wiring SL. The gate of the transistor 52A is connected to a wiring GL. A cathode of the light-emitting device 61 is connected to a wiring VCOM.

The wiring VCOM supplies a potential for supplying a current to the light-emitting device 61. The transistor 52A has a function of controlling electrical continuity between the wiring SL and the gate of the transistor 52B in accordance with the potential of the wiring GL. For example, VDD is supplied to the wiring ANO, and VSS is supplied to the wiring VCOM.

In this specification and the like, a high power supply potential VDD (hereinafter also simply referred to as “VDD”) is a power supply potential higher than a low power supply potential VSS. The low power supply potential VSS (hereinafter also simply referred to as “VSS”) is a power supply potential lower than the high power supply potential VDD. In addition, a ground potential GND (hereinafter, also simply referred to as “GND”) can be used as VDD or VSS. For example, VSS is a potential lower than GND when VDD is GND, and VDD is a potential higher than GND when VSS is GND.

The transistor 52A functions as a selection transistor for controlling the selection state of the subpixel 11. The transistor 52B functions as a driving transistor for controlling the amount of current flowing through the light-emitting device 61. The capacitor 53 has a function of holding a gate potential of the transistor 52B. The intensity of light emitted by the light-emitting device 61 can be controlled in accordance with an image signal supplied to the gate of the transistor 52B. The semiconductor device of one embodiment of the present invention can be used in the pixel circuit 51. One or more of the above-described transistors can be suitably used as one or both of the transistor 52A and the transistor 52B.

A transistor having high saturation and high current controllability can be suitably used as the driving transistor. Accordingly, a display device with high display quality can be provided. As the driving transistor, an OS transistor with favorable saturation can be suitably used.

When transistors operate in a saturation region, a change in source-drain current relative to a change in gate-source voltage can be smaller in an OS transistor than in a Si transistor. Accordingly, when an OS transistor is used as the driving transistor, a current flowing between the source and the drain can be set minutely by a change in gate-source voltage; hence, the amount of current flowing through the light-emitting element can be controlled. Consequently, the number of gray levels expressed by the pixel circuit can be increased.

Regarding saturation characteristics of a current flowing when transistors operate in a saturation region, even in the case where the source-drain voltage of an OS transistor increases gradually, a more stable current (saturation current) can be fed through the OS transistor than through a Si transistor. Thus, by using an OS transistor as the driving transistor, a stable current can flow through light-emitting elements even when the current-voltage characteristics of the light-emitting elements vary, for example. In other words, when the OS transistor operates in the saturation region, a change in source-drain current owing to a change in the source-drain voltage is small; hence, the luminance of the light-emitting element can be stable.

To increase the emission luminance of the light-emitting element, it is necessary to increase the amount of current flowing through the light-emitting element. To increase the current amount, the source-drain voltage of the driving transistor needs to be increased. An OS transistor has a higher breakdown voltage between a source and a drain than a Si transistor; hence, high voltage can be applied between the source and the drain of the OS transistor. Thus, with the use of an OS transistor as the driving transistor, the amount of current flowing through the light-emitting element can be increased, resulting in an increase in luminance of the light-emitting element. As described above, when a metal oxide with a high indium content percentage is used for the semiconductor layer, the transistor can have a high on-state current. When such a transistor is used as the driving transistor, the amount of current flowing through the light-emitting element is increased, so that the display device can have high luminance.

An OS transistor has a low off-state current and thus can be suitably used as a selection transistor. Accordingly, the gray level of the pixel can be maintained even with an extremely low frame frequency (e.g., 1 fps or less); thus, power consumption can be reduced by stopping the driver in displaying a still image.

When a transistor with high field-effect mobility is used as the selection transistor, the time required for charging and discharging of a floating node FN can be shortened. This can increase the frame frequency in display, so that the display device can have high display quality.

The use of a plurality of transistors and a plurality of capacitors in the pixel circuit achieves a high-performance display device. With the use of the semiconductor device of one embodiment of the present invention, the occupied area can be reduced even when the numbers of the transistors and the capacitors are increased, so that a high-performance and high-resolution display device can be obtained. For example, the resolution of the display device can be higher than or equal to 300 ppi, higher than or equal to 500 ppi, higher than or equal to 1000 ppi, higher than or equal to 2000 ppi, or higher than or equal to 3000 ppi.

Since the occupied area can be reduced with the use of the semiconductor device of one embodiment of the present invention, the aperture ratio of a pixel can be increased in a display device having a bottom-emission structure. For example, the aperture ratio can be higher than or equal to 50%, higher than or equal to 55%, or higher than or equal to 60% in the display device.

In this specification and the like, the aperture ratio refers to a proportion of the area of the region, where light is transmitted, to the area of a pixel.

FIG. 13C shows a structure example different from that of the subpixel 11 shown in FIG. 13B. The subpixel 11 includes a pixel circuit 51A and the light-emitting device 61.

The pixel circuit 51A is different from the pixel circuit 51 mainly in that the transistor 52B is a p-channel transistor. One electrode of the capacitor 53 is connected to a wiring ANO.

In the pixel circuit 51A, an n-channel OS transistor and a p-channel LTPS transistor can be suitably used as the transistor 52A and the transistor 52B, respectively.

In the pixel circuit 51 shown in FIG. 13B, the transistor (e.g., IO transistor) of one embodiment of the present invention can be suitably used as each of the transistor 52A and the transistor 52B. Thus, the transistor 52A and the transistor 52B can be formed through the same step. Thus, the process can be simplified and the manufacturing cost can be reduced as compared with the structure in which LTPO is used. As described above, in order to increase the emission luminance of the light-emitting element, it is necessary to increase the source-drain voltage of the driving transistor. In the case where the source-drain voltage is high, the drain current of an LTPS transistor might be increased owing to the kink effect. Meanwhile, an OS transistor has a small increase in drain current even when the source-drain voltage is high; thus, the OS transistor can be suitably used as the driving transistor. Since an OS transistor has a smaller hysteresis than an LTPS transistor, the OS transistor can be suitably used as each of the selection transistor and the driving transistor.

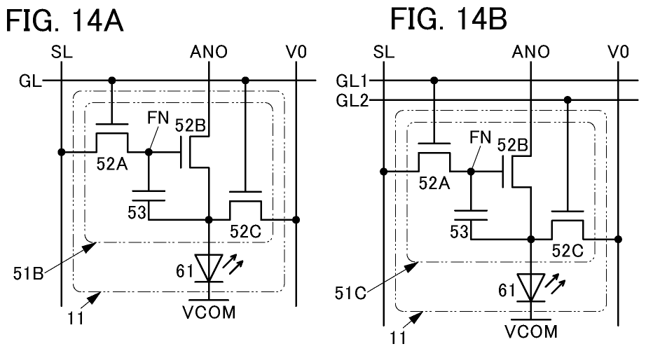

FIG. 14A shows a structure example different from that of the subpixel 11 shown in FIG. 13B. The subpixel 11 includes a pixel circuit 51B and the light-emitting device 61.

The pixel circuit 51B is different from the pixel circuit 51 mainly in including a transistor 52C. The pixel circuit 51B includes the transistor 52A, the transistor 52B, the transistor 52C, and the capacitor 53. The pixel circuit 51B is a 3Tr1C-type pixel circuit including three transistors and one capacitor.

The pixel circuit 51B has a structure in which the transistor 52C is added to the pixel circuit 51 in FIG. 13B. One of a source and a drain of the transistor 52C is connected to one of the source and the drain of the transistor 52B. The other of the source and the drain of the transistor 52C is connected to a wiring V0. For example, a reference potential is supplied to the wiring V0. A gate of the transistor 52C is connected to the wiring GL. The transistor 52C has a function of controlling electrical continuity between the wiring V0 and one of the source and the drain of the transistor 52B in accordance with the potential of the wiring GL.

A current value that can be used for setting pixel parameters can be obtained with the use of the wiring V0. Specifically, the wiring V0 can function as a monitor line for outputting a current flowing in the transistor 52B or a current flowing in the light-emitting device 61 to the outside. A current output to the wiring V0 is converted into a voltage by a source follower circuit and can be output to the outside. Alternatively, the current is converted into a digital signal by an A/D converter and can be output to the outside.

FIG. 14B shows a structure example different from that of the subpixel 11 shown in FIG. 14A. The subpixel 11 includes a pixel circuit 51C and the light-emitting device 61. A gate of the transistor 52A is electrically connected to a wiring GL1. A gate of the transistor 52C is electrically connected to a wiring GL2. The transistor 52C has a function of controlling electrical continuity between one of the source and the drain of the transistor 52B and the wiring V0 in accordance with the potential of the wiring GL2. With the structure in which the gate of the transistor 52A and the gate of the transistor 52C are connected to different wirings, the operation of the transistor 52A and the operation of the transistor 52C can be controlled independently.

Some or all of the transistors included in the pixel circuit can be provided with back gates. For example, it is possible that the transistor 52B includes a back gate and the back gate is connected to one of the source and the drain of the transistor 52B. In that case, reliability can be increased. Note that a structure where the back gate of the transistor 52B is electrically connected to the gate of the transistor 52B can also be employed. In that case, the transistor 52B can have a high on-state current.

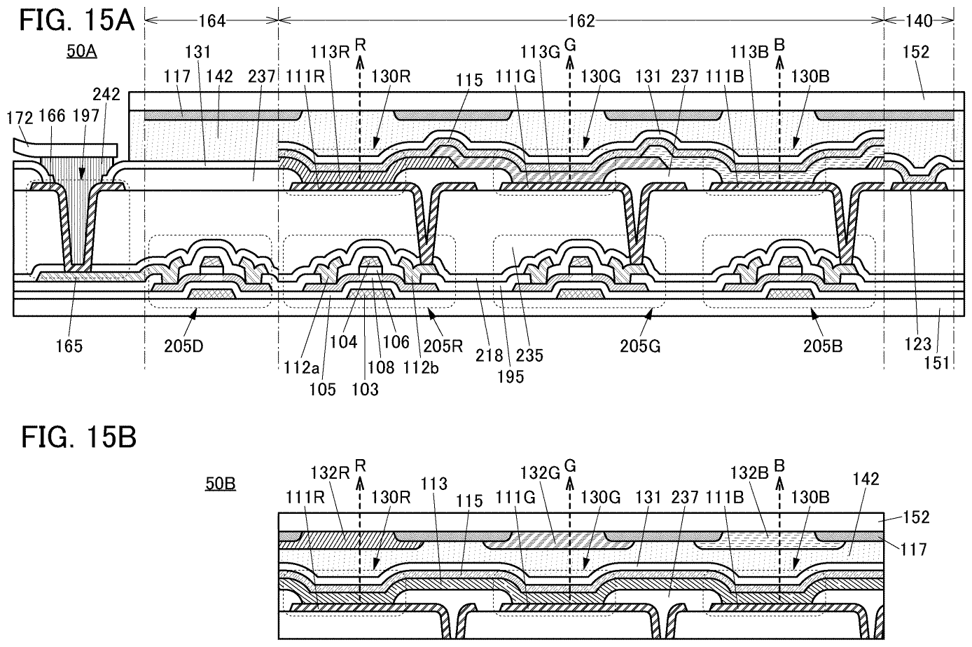

FIG. 15A shows an example of cross sections of part of a region including the FPC 172, part of the circuit portion 164, part of the display portion 162, part of the connection portion 140, and part of a region including the end portion of the display device 50A.

The display device 50A shown in FIG. 15A includes transistors 205D, 205R, 205G, and 205B, light-emitting elements 130R, 130G, and 130B, and the like between the substrates 151 and 152. The light-emitting elements 130R, 130G, and 130B are display elements included in the subpixel 11R that emits red light, the subpixel 11G that emits green light, and the subpixel 11B that emits blue light, respectively.

The display device 50A employs an SBS structure. The SBS structure can optimize materials and structures of light-emitting elements and thus can extend freedom of choice of materials and structures, whereby the luminance and the reliability can be easily improved.

The display device 50A has a top-emission structure. The aperture ratio of pixels in a top-emission structure can be higher than that of pixels in a bottom-emission structure because a transistor and the like can be provided to overlap with a light-emitting region of a light-emitting element in the top-emission structure.

The transistors 205D, 205R, 205G, and 205B are formed over the substrate 151. These transistors can be manufactured through the same process. FIG. 15A shows a structure example in which the transistor 100 shown in FIG. 1B is used as each of the transistors 205R, 205G, 205B, and 205D. The use of a TGSA transistor can reduce the parasitic capacitance between the gate electrode and each of the source electrode and the drain electrode. Thus, a degradation of display quality due to the parasitic capacitance can be inhibited. Note that the transistors 205D, 205R, 205G, and 205B may have different structures.

This embodiment describes an example where OS transistors are used as the transistors 205D, 205R, 205G, and 205B. Any of the transistors of embodiments of the present invention can be used as the transistors 205D, 205R, 205G, and 205B. In other words, the display device 50A includes any of the transistors of embodiments of the present invention in both the display portion 162 and the circuit portion 164. When the display portion 162 includes the transistor of one embodiment of the present invention, the pixel size can be reduced and the display device can have high resolution. When the circuit portion 164 includes the transistor of one embodiment of the present invention, the area occupied by the circuit portion 164 can be reduced and a narrower bezel can be achieved. The description in the above embodiment can be referred to for the transistor of one embodiment of the present invention.

Specifically, the transistors 205D, 205R, 205G, and 205B each include the conductive layer 104 functioning as a gate electrode, the insulating layer 106 functioning as a gate insulating layer, the conductive layer 103 functioning as a back gate electrode, the insulating layer 105 functioning as a back gate insulating layer, the conductive layer 112a and the conductive layer 112b functioning as a source electrode and a drain electrode, and the semiconductor layer 108 including a metal oxide. Here, a plurality of layers obtained by processing the same conductive film are shown with the same hatching pattern.

The insulating layer 218 is provided to cover the transistors 205D, 205R, 205G, and 205B and an insulating layer 235 is provided over the insulating layer 218. The above description can be referred to for the insulating layer 218.

The insulating layer 235 preferably has a function of a planarization layer, and an organic insulating layer is suitably used. Alternatively, the insulating layer 235 can have a stacked-layer structure of an organic insulating layer and an inorganic insulating layer. The outermost layer of the insulating layer 235 preferably has a function of an etching protective layer. Thus, the formation of a depression in the insulating layer 235 can be inhibited in processing pixel electrodes 111R, 111G, and 111B, for example. Alternatively, a depression may be formed in the insulating layer 235 in processing the pixel electrodes 111R, 111G, and 111B, for example. Note that the pixel electrodes 111R, 111G, and 111B are collectively referred to as a pixel electrode 111 in some cases.

The light-emitting elements 130R, 130G, and 130B are provided over the insulating layer 235.

The light-emitting element 130R includes the pixel electrode 111R over the insulating layer 235, an EL layer 113R over the pixel electrode 111R, and a common electrode 115 over the EL layer 113R. The light-emitting element 130R shown in FIG. 15A emits red light (R). The EL layer 113R includes a light-emitting layer that emits red light.

The light-emitting element 130G includes the pixel electrode 111G over the insulating layer 235, an EL layer 113G over the pixel electrode 111G, and the common electrode 115 over the EL layer 113G. The light-emitting element 130G shown in FIG. 15A emits green light (G). The EL layer 113G includes a light-emitting layer that emits green light.

The light-emitting element 130B includes the pixel electrode 111B over the insulating layer 235, an EL layer 113B over the pixel electrode 111B, and the common electrode 115 over the EL layer 113B. The light-emitting element 130B shown in FIG. 15A emits blue light (B). The EL layer 113B includes a light-emitting layer that emits blue light.

Although the EL layers 113R, 113G, and 113B have the same thickness in FIG. 15A, the present invention is not limited thereto. The EL layers 113R, 113G, and 113B may have different thicknesses. For example, the thicknesses of the EL layers 113R, 113G, and 113B are preferably set to match an optical path length that intensifies light emitted from each EL layer. In that case, a microcavity structure is obtained, and the color purity of light emitted from each light-emitting element can be improved.

The pixel electrode 111R is in contact with the conductive layer 112b included in the transistor 205R in an opening portion provided in the insulating layers 218 and 235 and is connected to the conductive layer 112b. In a similar manner, the pixel electrode 111G is connected to the conductive layer 112b included in the transistor 205G, and the pixel electrode 111B is connected to the conductive layer 112b included in the transistor 205B.

End portions of the pixel electrodes 111R, 111G, and 111B are covered with an insulating layer 237. The insulating layer 237 can have a single-layer structure or a stacked-layer structure including one or both of an inorganic insulating material and an organic insulating material. The insulating layer 237 can be formed using any of the materials given for the insulating layer 218 and the insulating layer 235, for example. The insulating layer 237 can electrically isolate the pixel electrode and the common electrode. Furthermore, the insulating layer 237 can electrically isolate light-emitting elements adjacent to each other.

The insulating layer 237 is provided in at least the display portion 162. The insulating layer 237 may be provided in not only the display portion 162 but also the connection portion 140 and the circuit portion 164. The insulating layer 237 may be provided to extend to the end portion of the display device 50A.

The common electrode 115 is one continuous film shared by the light-emitting elements 130R, 130G, and 130B. The common electrode 115 shared by the plurality of light-emitting elements is connected to a conductive layer 123 provided in the connection portion 140. The conductive layer 123 is preferably formed using a conductive layer formed using the same material through the same process as the pixel electrodes 111R, 111G, and 111B.

In the display device of one embodiment of the present invention, a conductive film that transmits visible light is used for the electrode through which light is extracted, which is either the pixel electrode or the common electrode. A conductive film that reflects visible light is preferably used for the electrode through which light is not extracted.

A conductive film that transmits visible light may be used also for the electrode through which light is not extracted. In that case, this electrode is preferably provided between a reflective layer and the EL layer. In other words, light emitted by the EL layer may be reflected by the reflective layer to be extracted from the display device.

As the material of the pair of electrodes of the light-emitting element, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy including any of these metals in appropriate combination. Other examples of the material include ITO, ITSO, In—Zn oxide, and In—W—Zn oxide. Other examples of the material include an alloy including aluminum (aluminum alloy), such as an alloy of aluminum, nickel, and lanthanum (Al—Ni—La), and an alloy including silver, such as an alloy of silver and magnesium and an alloy of silver, palladium, and copper (also referred to as Ag—Pd—Cu or APC). Other examples of the material include an element belonging to Group 1 or Group 2 of the periodic table that is not described above (e.g., lithium, cesium, calcium, or strontium), a rare earth metal such as europium or ytterbium, an alloy including an appropriate combination of any of these elements, and graphene.

The light-emitting element preferably employs a microcavity structure. Thus, one of the pair of electrodes of the light-emitting element is preferably an electrode having properties of transmitting and reflecting visible light (a transflective electrode), and the other is preferably an electrode having a property of reflecting visible light (a reflective electrode). When the light-emitting element has a microcavity structure, light obtained from the light-emitting layer can be resonated between the electrodes, whereby light emitted from the light-emitting element can be intensified.

The transparent electrode has a light transmittance higher than or equal to 40%. For example, an electrode having a visible light (light with wavelengths greater than or equal to 400 nm and less than 750 nm) transmittance higher than or equal to 40% is preferably used as the transparent electrode of the light-emitting element. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have an electric resistivity lower than or equal to 1×10⁻² Ωcm.

The EL layers 113R, 113G, and 113B are each provided into an island shape. In FIG. 15A, end portions of the EL layers 113R and 113G adjacent to each other overlap with each other, end portions of the EL layers 113G and 113B adjacent to each other overlap with each other, and end portions of the EL layers 113R and 113B adjacent to each other overlap with each other. When island-shaped EL layers are formed using a fine metal mask, end portions of adjacent EL layers may overlap with each other as shown in FIG. 15A; however, the present invention is not limited thereto. That is, it is also possible that the EL layers adjacent to each other do not overlap with each other and are apart from each other. Moreover, the display device may include both a region where adjacent EL layers overlap with each other and a region where adjacent EL layers are apart from each other without overlap.

Each of the EL layers 113R, 113G, and 113B includes at least a light-emitting layer. The light-emitting layer includes one or more kinds of light-emitting substances. As the light-emitting substance, a substance whose emission color is blue, violet, bluish violet, green, yellowish green, yellow, orange, red, or the like is appropriately used. As the light-emitting substance, a substance that emits near-infrared light can also be used.

The light-emitting layer may include one or more kinds of organic compounds (e.g., a host material or an assist material) in addition to the light-emitting substance (a guest material). As the one or more kinds of organic compounds, one or both of a substance with a high hole-transport property (a hole-transport material) and a substance with a high electron-transport property (an electron-transport material) can be used. As the one or more kinds of organic compounds, a substance with a bipolar property (a substance with a high electron-transport property and a high hole-transport property) or a TADF material may be used.

The light-emitting layer preferably includes a phosphorescent material and a combination of a hole-transport material and an electron-transport material that easily forms an exciplex, for example. With such a structure, light emission can be efficiently obtained by exciplex-triplet energy transfer (ExTET), which is energy transfer from the exciplex to the light-emitting substance (the phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of the light-emitting element can be achieved.

In addition to the light-emitting layer, the EL layer can include one or more of a layer including a substance having a high hole-injection property (a hole-injection layer), a layer including a hole-transport material (a hole-transport layer), a layer including a substance having a high electron-blocking property (an electron-blocking layer), a layer including a substance having a high electron-injection property (an electron-injection layer), a layer including an electron-transport material (an electron-transport layer), and a layer including a substance having a high hole-blocking property (a hole-blocking layer). The EL layer may further include one or both of a bipolar substance and a TADF material.

Either a low molecular compound or a high molecular compound can be used in the light-emitting element, and an inorganic compound may also be included. Each layer included in the light-emitting element can be formed by any of the following methods: an evaporation method (including a vacuum evaporation method), a transfer method, a printing method, an inkjet method, a coating method, and the like.

The light-emitting element may employ a single structure (a structure including only one light-emitting unit) or a tandem structure (a structure including a plurality of light-emitting units). The light-emitting unit includes at least one light-emitting layer. In a tandem structure, a plurality of light-emitting units are connected in series with a charge-generation layer therebetween. The charge-generation layer has a function of injecting electrons into one of two light-emitting units and injecting holes to the other when voltage is applied between the pair of electrodes. The tandem structure enables a light-emitting element to emit light at high luminance. Furthermore, the amount of current needed for obtaining a predetermined luminance can be smaller in a tandem structure than in a single structure; thus, a tandem structure enables higher reliability. The tandem structure can also be referred to as a stack structure.

In the case of using a tandem light-emitting element in FIG. 15A, the EL layer 113R preferably includes a plurality of light-emitting units that emit red light, the EL layer 113G preferably includes a plurality of light-emitting units that emit green light, and the EL layer 113B preferably includes a plurality of light-emitting units that emit blue light.

A protective layer 131 is provided over the light-emitting elements 130R, 130G, and 130B. The protective layer 131 and the substrate 152 are bonded to each other with an adhesive layer 142. The substrate 152 is provided with a light-blocking layer 117. A solid sealing structure, a hollow sealing structure, or the like can be employed to seal the light-emitting elements. In FIG. 15A, a solid sealing structure is employed, in which a space between the substrate 152 and the substrate 151 is filled with the adhesive layer 142. Alternatively, a hollow sealing structure may be employed, in which the space is filled with an inert gas (e.g., nitrogen or argon). In that case, the adhesive layer 142 may be provided in a frame shape not to overlap with the light-emitting element. Furthermore, the space may be filled with a resin other than the frame-shaped adhesive layer 142.

The protective layer 131 is provided at least in the display portion 162, and preferably provided to cover the entire display portion 162. The protective layer 131 is preferably provided to cover not only the display portion 162 but also the connection portion 140 and the circuit portion 164. The protective layer 131 is further preferably provided to extend to the end portion of the display device 50A. Meanwhile, a connection portion 197 has a region not provided with the protective layer 131 so that the FPC 172 and a conductive layer 166 are connected to each other.

By providing the protective layer 131 over the light-emitting elements 130R, 130G, and 130B, the reliability of the light-emitting elements can be increased.

The protective layer 131 can have a single-layer structure or a stacked-layer structure of two or more layers. There is no limitation on the conductivity of the protective layer 131. For the protective layer 131, at least one of an insulating film, a semiconductor film, and a conductive film can be used.

The protective layer 131 including an inorganic film can inhibit deterioration of the light-emitting elements by preventing oxidation of the common electrode 115 and inhibiting entry of impurities (e.g., moisture and oxygen) into the light-emitting elements, for example; thus, the reliability of the display device can be increased.

The protective layer 131 preferably includes one or more inorganic insulating layers. For the protective layer 131, the material given as an example for the insulating layer 106 and the insulating layer 105 can be used. In particular, the protective layer 131 preferably includes a nitride or a nitride oxide, and further preferably includes a nitride.

An inorganic film including ITO, In—Zn oxide, Ga—Zn oxide, Al—Zn oxide, IGZO, or the like can be used for the protective layer 131. The inorganic film preferably has high resistance, specifically, higher resistance than the common electrode 115. The inorganic film may further include nitrogen.

When light emitted from the light-emitting element is extracted through the protective layer 131, the protective layer 131 preferably has a high visible-light-transmitting property. For example, ITO, IGZO, and aluminum oxide are preferable because they are inorganic materials having a high visible-light-transmitting property.

The protective layer 131 can have, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (e.g., water and oxygen) into the EL layer.

Furthermore, the protective layer 131 may include an organic film. For example, the protective layer 131 may include both an organic film and an inorganic film. Examples of an organic film that can be used for the protective layer 131 include organic insulating layer that can be used for the insulating layer 235.

The connection portion 197 is provided in a region of the substrate 151 not overlapping with the substrate 152. In the connection portion 197, the conductive layer 165 is connected to the FPC 172 through the conductive layer 166 and a connection layer 242. FIG. 15A shows an example in which the conductive layer 165 is formed by processing the same conductive film as the conductive layer 112a and the conductive layer 112b, and the conductive layer 166 is formed by processing the same conductive film as the pixel electrodes 111R, 111G, and 111B. A structure similar to that of the connection portion between the pixel electrode 111 and the conductive layer 112b can be employed for the connection portion between the conductive layer 165 and the conductive layer 166. Specifically, FIG. 15A shows an example where an opening portion is provided in the upper layer of the conductive layer 165 and the conductive layer 166 is in contact with the top surface of the conductive layer 165 in the opening portion. On the upper surface of the connection portion 197, the conductive layer 166 is exposed. Thus, the connection portion 197 and the FPC 172 can be connected to each other through the connection layer 242.

The display device 50A has a top-emission structure. Light from the light-emitting element is emitted toward the substrate 152. For the substrate 152, a material having a high visible-light-transmitting property is preferably used. The pixel electrodes 111R, 111G, and 111B include a material that reflects visible light, and the counter electrode (the common electrode 115) includes a material that transmits visible light.

The light-blocking layer 117 is preferably provided on the surface of the substrate 152 on the substrate 151 side. The light-blocking layer 117 can be provided over a region between adjacent light-emitting elements, in the connection portion 140, in the circuit portion 164, and the like.

A coloring layer such as a color filter may be provided on the surface of the substrate 152 on the substrate 151 side or over the protective layer 131. When the color filter is provided so as to overlap with the light-emitting element, the color purity of light emitted from the pixel can be increased.

The coloring layer is a colored layer that selectively transmits light in a specific wavelength range and absorbs light in the other wavelength ranges. For example, a red (R) color filter for transmitting light in the red wavelength range, a green (G) color filter for transmitting light in the green wavelength range, a blue (B) color filter for transmitting light in the blue wavelength range, or the like can be used. Each coloring layer can be formed using one or more of a metal material, a resin material, a pigment, and a dye. Each coloring layer is formed in a desired position by a printing method, an ink-jet method, an etching method using a photolithography method, or the like.

Moreover, a variety of optical members can be provided on the outer surface of the substrate 152 (the surface opposite to the substrate 151). Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer surface of the substrate 152. For example, it is preferable to provide, as the surface protective layer, a glass layer or a silica layer (SiOₓ layer) because the surface contamination or damage can be prevented. The surface protective layer may be formed using diamond-like carbon (DLC), aluminum oxide, a polyester-based material, a polycarbonate-based material, or the like. For the surface protective layer, a material having a high visible-light-transmittance is preferably used. The surface protective layer is preferably formed using a material with high hardness.

For each of the substrates 151 and 152, glass, quartz, ceramic, sapphire, a resin, a metal, an alloy, a semiconductor, or the like can be used. The substrate on the side from which light from the light-emitting element is extracted is formed using a material that transmits the light. When a flexible material is used for the substrates 151 and 152, the display device can have increased flexibility and a flexible display can be obtained. Furthermore, a polarizing plate may be used as at least one of the substrates 151 and 152.

For each of the substrates 151 and 152, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used as at least one of the substrates 151 and 152.

In the case where a circularly polarizing plate overlaps with the display device, a highly optically isotropic substrate is preferably used as the substrate included in the display device. A highly optically isotropic substrate has a low birefringence (in other words, a small amount of birefringence). Examples of a highly optically isotropic film include a triacetyl cellulose (TAC, also referred to as cellulose triacetate) film, a cycloolefin polymer (COP) film, a cycloolefin copolymer (COC) film, and an acrylic film.

For the adhesive layer 142, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a polyvinyl chloride (PVC) resin, a polyvinyl butyral (PVB) resin, and an ethylene-vinyl acetate (EVA) resin. In particular, a material with low moisture permeability, such as an epoxy resin, is preferable. A two-component resin may be used. An adhesive sheet or the like may be used.

As the connection layer 242, an anisotropic conductive film (ACF), an anisotropic conductive paste (ACP), or the like can be used.

### Structure Example 2 of Display Device

FIG. 15B shows an example of a cross section of the display portion 162 of a display device 50B. The display device 50B is different from the display device 50A mainly in that the subpixels of different colors include respective coloring layers (color filters or the like) and the light-emitting elements that share an EL layer 113. The structure shown in FIG. 15B can be combined with the structure of the region including the FPC 172, the circuit portion 164, the stacked-layer structure from the substrate 151 to the insulating layer 235 in the display portion 162, the connection portion 140, and the end portion, which is shown in FIG. 15A. Note that in the following description of display devices, the description of portions similar to those of the above-described display devices may be omitted.

In the display device 50B shown in FIG. 15B, the light-emitting elements 130R, 130G, and 130B, the coloring layer 132R transmitting red light, the coloring layer 132G transmitting green light, the coloring layer 132B transmitting blue light, and the like are provided.

The light-emitting element 130R includes the pixel electrode 111R, the EL layer 113 over the pixel electrode 111R, and the common electrode 115 over the EL layer 113. Light emitted from the light-emitting element 130R is extracted as red light to the outside of the display device 50B through the coloring layer 132R.

The light-emitting element 130G includes the pixel electrode 111G, the EL layer 113 over the pixel electrode 111G, and the common electrode 115 over the EL layer 113. Light emitted from the light-emitting element 130G is extracted as green light to the outside of the display device 50B through the coloring layer 132G.

The light-emitting element 130B includes the pixel electrode 111B, the EL layer 113 over the pixel electrode 111B, and the common electrode 115 over the EL layer 113. Light emitted from the light-emitting element 130B is extracted as blue light to the outside of the display device 50B through the coloring layer 132B.

The EL layer 113 and the common electrode 115 are shared between the light-emitting elements 130R, 130G, and 130B. The number of manufacturing steps can be smaller in the case where the EL layer 113 is shared between the subpixels of different colors than the case where the subpixels of different colors include different EL layers.

The light-emitting elements 130R, 130G, and 130B shown in FIG. 15B emit white light, for example. When white light emitted from the light-emitting elements 130R, 130G, and 130B passes through the respective coloring layers 132R, 132G, and 132B, light of a desired color can be obtained.

In the light-emitting element that emits white light, two or more light-emitting layers are preferably included. For example, the light-emitting element can include two light-emitting layers whose emission colors are complementary colors or three or more light-emitting layers that emit white light as a whole when the emission colors are combined.

For example, the EL layer 113 preferably includes a light-emitting layer including a light-emitting substance that emits blue light and a light-emitting layer including a light-emitting substance that emits visible light having a longer wavelength than blue light. The EL layer 113 preferably includes a light-emitting layer that emits yellow light and a light-emitting layer that emits blue light, for example. Alternatively, the EL layer 113 preferably includes a light-emitting layer that emits red light, a light-emitting layer that emits green light, and a light-emitting layer that emits blue light, for example.

A light-emitting element emitting white light preferably has a tandem structure. Specific examples include a two-unit tandem structure including a light-emitting unit that emits yellow light and a light-emitting unit that emits blue light; a two-unit tandem structure including a light-emitting unit that emits red and green light and a light-emitting unit that emits blue light; a three-unit tandem structure including a light-emitting unit that emits blue light, a light-emitting unit that emits yellow, yellow-green, or green light, and a light-emitting unit that emits blue light in this order; and a three-unit tandem structure including a light-emitting unit that emits blue light, a light-emitting unit that emits yellow, yellow-green, or green light and red light, and a light-emitting unit that emits blue light in this order. Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from the anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

In the case where the light-emitting element configured to emit white light has a microcavity structure, light with a specific wavelength (e.g., red, green, or blue) is sometimes intensified to be emitted.

Alternatively, the light-emitting elements 130R, 130G, and 130B shown in FIG. 15B emit blue light, for example. In this case, the EL layer 113 includes one or more light-emitting layers that emit blue light. In the subpixel 11B that emits blue light, blue light emitted from the light-emitting element 130B can be extracted. In each of the subpixel 11R that emits red light and the subpixel 11G that emits green light, a color conversion layer is provided between the light-emitting element 130R or 130G and the substrate 152 so that blue light emitted from the light-emitting element 130R or 130G is converted into light with a longer wavelength, whereby red light or green light can be extracted. A quantum dot material is preferably used for the color conversion layer. Furthermore, it is preferable that over the light-emitting element 130R, the coloring layer 132R be provided between the color conversion layer and the substrate 152 and over the light-emitting element 130G, the coloring layer 132G be provided between the color conversion layer and the substrate 152. In some cases, part of light emitted from the light-emitting element is transmitted through the color conversion layer without being converted. When light passing through the color conversion layer is extracted through the coloring layer, light other than light of a desired color can be absorbed by the coloring layer, and color purity of light exhibited by a subpixel can be improved.

### Structure Example 3 of Display Device

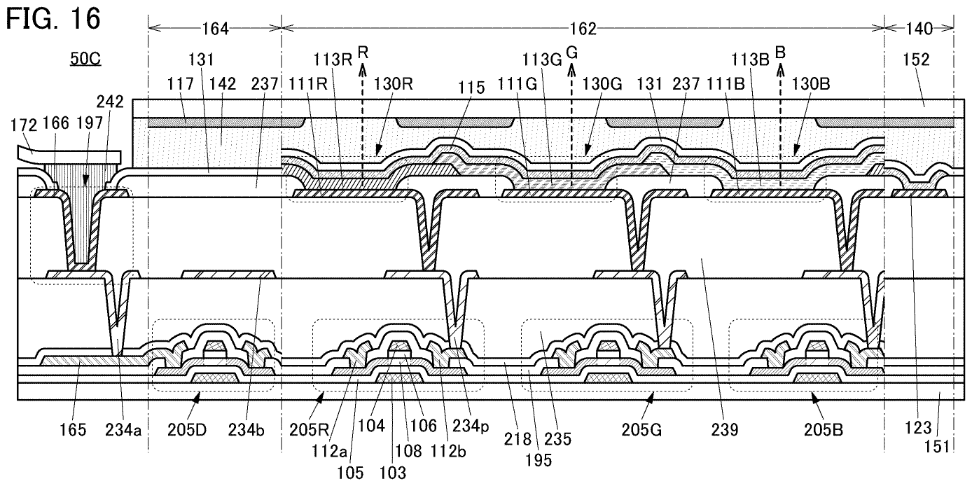

A display device 50C shown in FIG. 16 is different from the display device 50A mainly in including a conductive layer 234p, a conductive layer 234a, a conductive layer 234b, and an insulating layer 239.

The insulating layer 239 is provided over the insulating layer 235, and the light-emitting elements 130R, 130G, and 130B are provided over the insulating layer 239.

The conductive layer 234p is provided to cover an opening portion provided in the insulating layer 218 and the insulating layer 235. The conductive layer 234p is in contact with the conductive layer 112b included in the transistor 205R in the opening portion and is connected to the conductive layer 112b.

The insulating layer 239 is provided over the conductive layer 234p and the insulating layer 235. The insulating layer 239 can be formed using any of the materials given for the insulating layer 235.

The pixel electrode 111R is provided to cover an opening portion provided in the insulating layer 239. The pixel electrode 111R is in contact with the conductive layer 234p in the opening portion and is connected to the conductive layer 234p. That is, the pixel electrode 111R is connected to the conductive layer 112b through the conductive layer 234p. The same applies to the pixel electrode 111G and the pixel electrode 111B.

The conductive layer 234a is provided to cover an opening portion provided in the insulating layer 218 and the insulating layer 235. The conductive layer 234a is in contact with the conductive layer 165 in the opening portion and is connected to the conductive layer 165.

The conductive layer 166 is provided to cover an opening portion provided in the insulating layer 239. The conductive layer 166 is in contact with the conductive layer 234a in the opening portion and is connected to the conductive layer 234a. That is, the conductive layer 166 is connected to the conductive layer 165 through the conductive layer 234a.

FIG. 16 shows a structure in which the circuit portion 164 includes the conductive layer 234b. Note that the conductive layer 234b can be connected to the transistor 205D.

The conductive layers 234p, 234a, and 234b each function as a wiring, for example. The conductive layers 234p, 234a, and 234b are provided in a layer different from a layer of the conductive layers 112a, 112b, and 104. Accordingly, the wirings can be placed in their respective layers, leading to high layout flexibility and a reduction in the area occupied by the circuit.

The conductive layers 234p, 234a, and 234b can be formed using any of the materials given for the conductive layers 112a, 112b, and 104. The conductive layers 234p, 234a, and 234b can be formed in the same steps. For example, a conductive film is formed and processed, so that the conductive layers 234p, 234a, and 234b can be formed.

### Structure Example 4 of Display Device

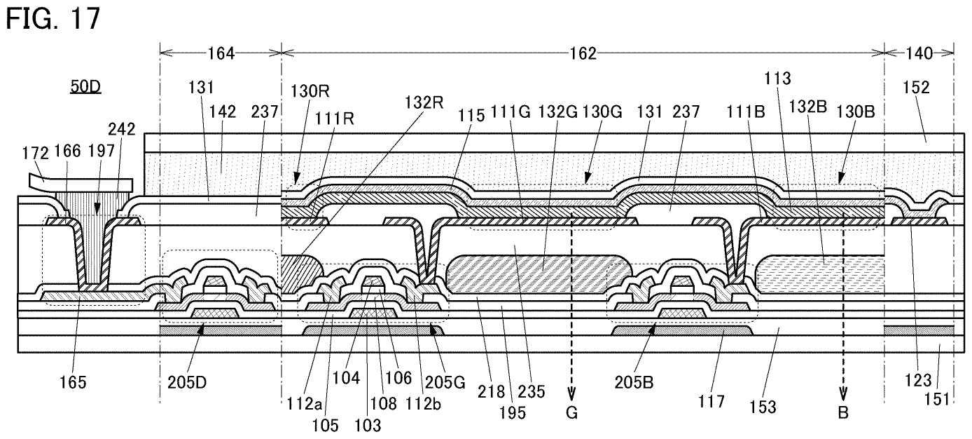

A display device 50D shown in FIG. 17 is different from the display device 50B mainly in having a bottom-emission structure.

Light from the light-emitting element is emitted toward the substrate 151. For the substrate 151, a material having a high visible-light-transmitting property (also referred to as a light-transmitting property) is preferably used. By contrast, there is no limitation on the light-transmitting property of a material used for the substrate 152.

The light-blocking layer 117 is preferably formed between the substrate 151 and the transistor. FIG. 17 shows an example where the light-blocking layers 117 are provided over the substrate 151, an insulating layer 153 is provided over the light-blocking layers 117, and the transistors 205D, 205R (not shown), 205G, and 205B and the like are provided over the insulating layer 153. In addition, the coloring layers 132R, 132G, and 132B are provided over the insulating layer 218, and the insulating layer 235 is provided over the coloring layers 132R, 132G, and 132B.

The light-emitting element 130R overlapping with the coloring layer 132R includes the pixel electrode 111R, the EL layer 113, and the common electrode 115.

The light-emitting element 130G overlapping with the coloring layer 132G includes the pixel electrode 111G, the EL layer 113, and the common electrode 115.

The light-emitting element 130B overlapping with the coloring layer 132B includes the pixel electrode 111B, the EL layer 113, and the common electrode 115.

A material having a high visible-light-transmitting property is used for each of the pixel electrodes 111R, 111G, and 111B. A material that reflects visible light is preferably used for the common electrode 115. In the display device having a bottom-emission structure, a metal or the like having low electric resistivity can be used for the common electrode 115; thus, a voltage drop due to the electric resistance of the common electrode 115 can be suppressed and the display quality can be improved.

With the use of the transistor of one embodiment of the present invention, the area occupied by the pixel circuit can be reduced, so that the aperture ratio of the pixel can be increased or the pixel size can be reduced in the display device having a bottom-emission structure.

### Structure Example 5 of Display Device

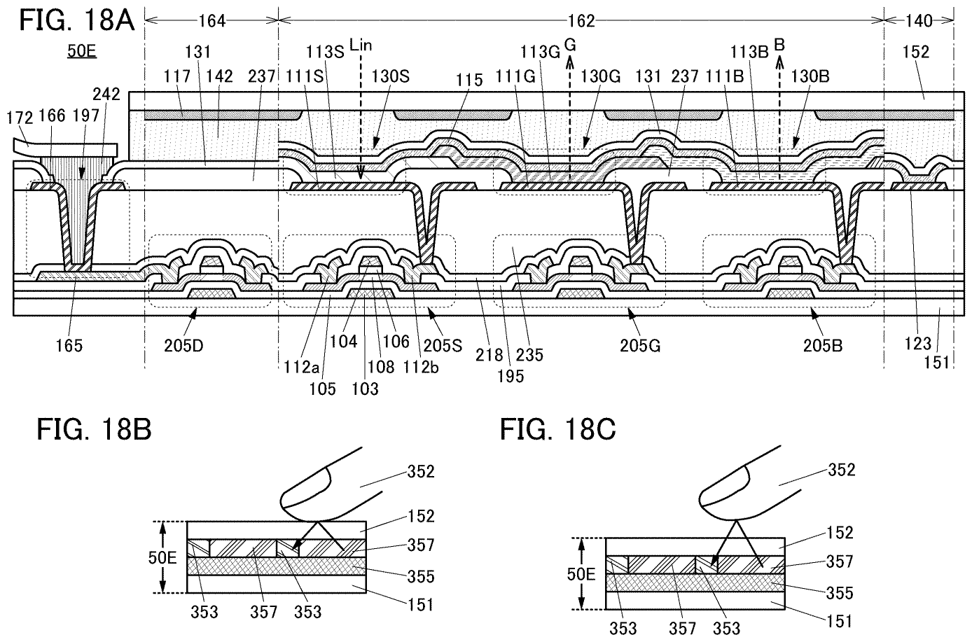

A display device 50E shown in FIG. 18A is different from the display device 50A mainly in including a light-receiving element 130S.

The display device 50E includes light-emitting elements and a light-receiving element in a pixel. In the display device 50E, organic EL elements are preferably used as the light-emitting elements and an organic photodiode is preferably used as the light-receiving element. The organic EL elements and the organic photodiode can be formed over the same substrate. Thus, the organic photodiode can be incorporated in a display device including the organic EL elements.

In the display device 50E including the light-emitting elements and the light-receiving element in each pixel, the pixel has a light-receiving function; thus, the display device can detect the touch or proximity of an object while displaying an image. Accordingly, the display portion 162 has one or both of an image capturing function and a sensing function in addition to a function of displaying an image. For example, an image can be displayed by using all the subpixels included in the display device 50E; or light can be emitted by some of the subpixels as a light source, light can be detected by some other subpixels, and an image can be displayed by using the remaining subpixels.

Accordingly, a light-receiving portion and a light source do not need to be provided separately from the display device 50E; hence, the number of components of an electronic appliance can be reduced. For example, a biometric authentication device or a capacitive touch panel for scroll operation or the like is not necessarily provided separately in the electronic appliance. Thus, with the use of the display device 50E, the electronic appliance can be provided at lower manufacturing costs.

When the light-receiving elements are used for an image sensor, the display device 50E can capture an image using the light-receiving elements. For example, image capturing for personal authentication with the use of a fingerprint, a palm print, the iris, the shape of a blood vessel (including the shape of a vein and the shape of an artery), a face, or the like is possible by using the image sensor.

The light-receiving element can be used in a touch sensor (also referred to as a direct touch sensor), a contactless sensor (also referred to as a hover sensor, a hover touch sensor, or a touchless sensor), or the like. The touch sensor can detect an object (e.g., a finger, a hand, or a pen) when the display device and the object come in direct contact with each other. Furthermore, the contactless sensor can detect the object even when the object is not in contact with the display device.

The light-receiving element 130S includes a pixel electrode 111S over the insulating layer 235, a functional layer 113S over the pixel electrode 111S, and the common electrode 115 over the functional layer 113S. The functional layer 113S is irradiated with light Lin coming from the outside of the display device 50E.

The pixel electrode 111S is in contact with the conductive layer 112b included in a transistor 205S in an opening portion provided in the insulating layers 218 and 235 and is connected to the conductive layer 112b.

An end portion of the pixel electrode 111S is covered with the insulating layer 237.

The common electrode 115 is one continuous film shared by the light-receiving element 130S and the light-emitting elements 130R (not shown), 130G, and 130B. The common electrode 115 shared by the light-emitting elements and the light-receiving element is connected to the conductive layer 123 provided in the connection portion 140.

The functional layer 113S includes at least an active layer (also referred to as a photoelectric conversion layer). The active layer includes a semiconductor. Examples of the semiconductor include an inorganic semiconductor such as silicon and an organic semiconductor including an organic compound. This embodiment shows an example where an organic semiconductor is used as the semiconductor included in the active layer. An organic semiconductor is preferably used, in which case the light-emitting layer and the active layer can be formed by the same method (e.g., a vacuum evaporation method) and thus the same manufacturing apparatus can be used.

In addition to the active layer, the functional layer 113S may further include a layer including a substance having a high hole-transport property, a substance having a high electron-transport property, a substance having a bipolar property, or the like. Without limitation to the above, the functional layer 113S may further include a layer including a substance having a high hole-injection property, a hole-blocking material, a substance having a high electron-injection property, an electron-blocking material, or the like. The functional layer 113S can be formed using a material that can be used for the light-emitting element.

Either a low molecular compound or a high molecular compound can be used in the light-receiving element, and an inorganic compound may also be included. Each layer included in the light-receiving element can be formed by any of the following methods: an evaporation method (including a vacuum evaporation method), a transfer method, a printing method, an inkjet method, a coating method, and the like.

In the display device 50E shown in FIGS. 18B and 18C, a layer 353 including a light-receiving element, a circuit layer 355, and a layer 357 including a light-emitting element are provided between the substrates 151 and 152.

The layer 353 includes the light-receiving element 130S, for example. The layer 357 includes the light-emitting elements 130R, 130G, and 130B, for example.

The circuit layer 355 includes a circuit for driving a light-receiving element and a circuit for driving a light-emitting element. The circuit layer 355 includes the transistors 205R, 205G, and 205B, for example. The circuit layer 355 can further include one or more of a switch, a capacitor, a resistor, a wiring, a terminal, and the like.

FIG. 18B shows an example where the light-receiving element 130S is used as a touch sensor. Light emitted from the light-emitting element in the layer 357 is reflected by a finger 352 that touches the display device 50E as shown in FIG. 18B; then, the light-receiving element in the layer 353 detects the reflected light. Thus, the touch of the finger 352 on the display device 50E can be detected.

FIG. 18C shows an example where the light-receiving element 130S is used as a contactless sensor. Light emitted from the light-emitting element in the layer 357 is reflected by the finger 352 that is close to (i.e., that does not touch) the display device 50E as shown in FIG. 18C; then, the light-receiving element in the layer 353 detects the reflected light.

### Structure Example 6 of Display Device

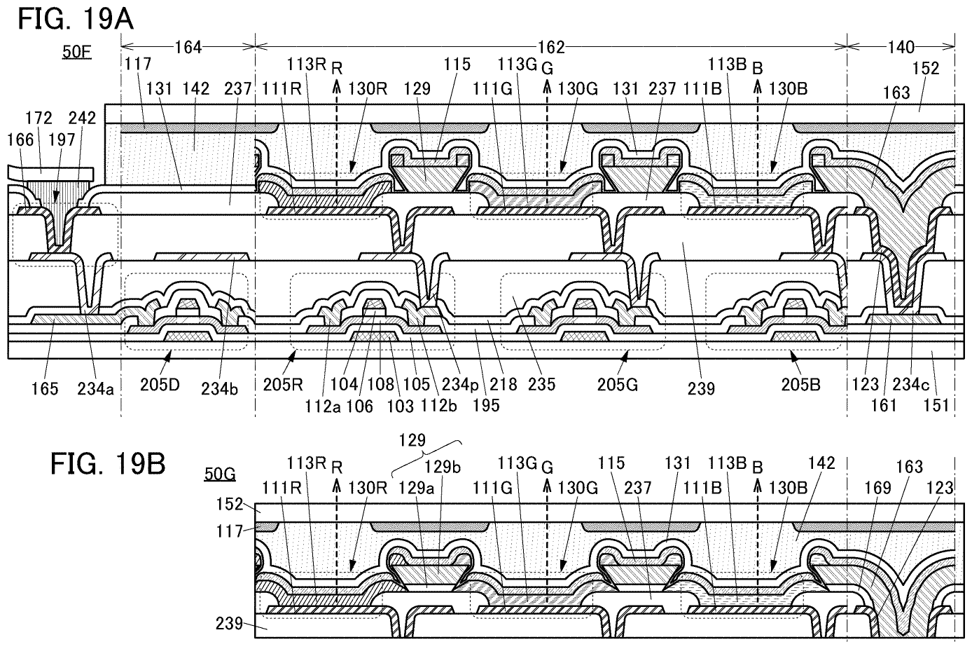

A display device 50F shown in FIG. 19A is different from the display device 50C mainly in including a partition wall 129. The stacked-layer structure from the substrate 151 to the insulating layer 239 and the stacked-layer structure from the protective layer 131 to the substrate 152 are similar to those in the display device 50C; thus, the description thereof is omitted.

The partition wall 129 is provided between adjacent light-emitting elements. The top surface shape of the partition wall 129 can be a lattice shape. It can be said that the light-emitting elements 130R, 130G, and 130B are provided in regions surrounded by the partition wall 129. Note that although a plurality of partition walls 129 are shown in the cross-sectional view in FIG. 19A, the partition walls 129 are connected to each other when the display device 50F is seen from above. It can also be said that the partition wall 129 is continuous.

The partition wall 129 is provided over the insulating layer 237. In a cross-sectional view, the side surface of the partition wall 129 preferably has an inverse tapered shape. In the cross-sectional view, the partition wall 129 has a shape such that its upper portion extends in the horizontal direction beyond the lower portion. Thus, when a film to be the EL layer 113R is formed, the film is disconnected by the partition wall 129, so that the EL layer 113R having an island shape can be formed. The same applies to the EL layer 113G and the EL layer 113B. In the cross-sectional view, the shape of the partition wall 129 can be a trapezoidal or substantially trapezoidal shape in which the upper base is longer than the lower base. Note that there is no particular limitation on the shape of the partition wall 129.

The partition wall 129 is positioned between the adjacent EL layers 113. The EL layer 113R, the EL layer 113G, and the EL layer 113B are separated from each other. When the EL layer is provided to have an island shape for each light-emitting element, a leakage current between adjacent light-emitting elements can be inhibited. This can prevent crosstalk-induced unintended light emission, so that the display device can achieve extremely high contrast.

The partition wall 129 preferably has conductivity. The partition wall 129 can be formed using any of the materials given for the conductive layers 112a, 112b, 103, and 104. For example, molybdenum can be suitably used for the partition wall 129. In the case where the partition wall 129 has conductivity, it is preferable that each of the EL layers 113R, 113G, and 113B not include a region in contact with the partition wall 129. In that case, leakage current between adjacent light-emitting elements can be inhibited.

The common electrode 115 includes regions in contact with the top surface and the side surface of the partition wall 129, the top surface and the side surface of the EL layer 113, and the top surface of the insulating layer 237. The common electrode 115 is preferably formed by a film formation method which provides higher step coverage than that for the EL layer 113. Here, since the side surface of the partition wall 129 has an inverse tapered shape, step disconnection occurs in the common electrode 115 on the side surface of the partition wall 129 in some cases. However, portions of the common electrode 115 that are separated by step disconnection are in contact with the partition wall 129. That is, the separated portions of the common electrode 115 are electrically connected to each other through the partition wall 129.

The partition wall 129 can also function as a wiring for supplying a potential to the common electrode 115. Furthermore, when the common electrode 115 includes a region in contact with the partition wall 129, the electric resistance of the common electrode 115 can be reduced. In that case, a voltage drop due to the electric resistance of the common electrode 115 can be inhibited, and high display quality can be achieved.

FIG. 19A shows a structure in which a conductive layer 163 is provided between the common electrode 115 and the conductive layer 123 in the connection portion 140. The conductive layer 163 can be formed in the same step as the partition wall 129. The common electrode 115 is connected to the conductive layer 123 through the conductive layer 163. With the conductive layer 163, coverage with the common electrode 115 in the connection portion 140 can be improved, so that a connection defect due to step disconnection can be inhibited. In addition, an increase in the electric resistance which is caused by local thinning of the common electrode 115 due to the step can be inhibited. The conductive layer 163 is preferably provided in contact with the conductive layer 123 and the common electrode 115, in which case the electric resistance of these conductive layers can be reduced. Note that a structure without the conductive layer 163 can be employed (see the connection portion 140 in FIG. 16).

FIG. 19A shows a structure in which the conductive layer 123 includes a region in contact with the conductive layer 234c and the conductive layer 234c includes a region in contact with the conductive layer 161. The conductive layer 123 is provided to cover an opening portion provided in the insulating layer 239. The conductive layer 234c is provided to cover the opening portion provided in the insulating layer 218 and the insulating layer 235 and can be formed by processing the same conductive film as the conductive layers 234p, 234a, and 234b. The conductive layer 161 can be formed by processing the same conductive film as the conductive layers 165, 112a, and 112b. The common electrode 115, the conductive layer 163, the conductive layer 123, the conductive layer 234c, and the conductive layer 161 are connected to each other, so that the electric resistances of these conductive layers can be reduced. Note that there is no particular limitation on a structure of the connection portion 140. A structure without the conductive layer 161 can be employed. Alternatively, a structure without the conductive layer 161 and the conductive layer 234c can be employed (see the connection portion 140 in FIG. 16).

FIG. 19B shows an example of a cross section of the display portion 162 and the connection portion 140 of a display device 50G. The display device 50G is different from the display device 50F mainly in that the partition wall 129 has a stacked-layer structure.

FIG. 19B shows a structure in which the partition wall 129 has a two-layer structure of an insulating layer 129a and a conductive layer 129b over the insulating layer 129a. As the insulating layer 129a, one or both of an inorganic insulating film and an organic insulating film can be used. For the insulating layer 129a, aluminum oxide can be suitably used, for example.

The EL layers 113R, 113G, and 113B can each include a region in contact with the insulating layer 129a. Meanwhile, it is preferable that the EL layers 113R, 113G, and 113B each not include a region in contact with the conductive layer 129b. Providing the insulating layer 129a on the insulating layer 237 side of the partition wall 129 can inhibit leakage current between adjacent light-emitting elements.

FIG. 19B shows a structure in which an insulating layer 169 is provided between the conductive layer 163 and the insulating layer 237. The insulating layer 169 can be formed in the same step as the insulating layer 129a. The insulating layer 169 has an opening portion, and the conductive layer 163 and the conductive layer 123 are in contact with each other in the opening portion. Accordingly, the common electrode 115 is connected to the conductive layer 123 through the conductive layer 163. Note that there is no particular limitation on a structure of the connection portion 140. The conductive layer 163 can be formed in the same step as the conductive layer 129b.

### Structure Example 7 of Display Device

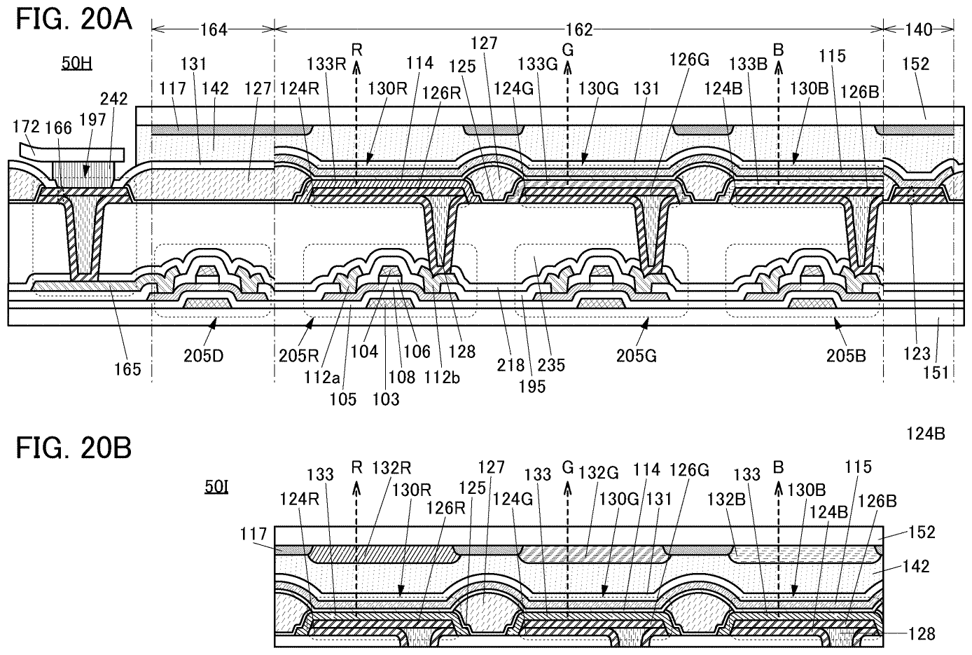

A display device 50H shown in FIG. 20A is an example of a display device having a metal maskless (MML) structure. In other words, the display device 50H includes a light-emitting element that is formed without using a fine metal mask.

An island-shaped light-emitting layer of the light-emitting element included in the display device having the MML structure is formed in the following manner: a light-emitting layer is formed on the entire surface and then the light-emitting layer is processed by a photolithography method. Accordingly, a high-resolution display device or a display device with a high aperture ratio, which has been difficult to form so far, can be obtained. Moreover, light-emitting layers can be formed separately for the respective colors, enabling the display device to perform extremely clear display with high contrast and high display quality. For example, in the case where the display device includes three kinds of light-emitting elements, which are a light-emitting element emitting blue light, a light-emitting element emitting green light, and a light-emitting element emitting red light, three kinds of island-shaped light-emitting layers can be formed by repeating formation of a light-emitting layer and processing by photolithography three times.

A device having the MML structure can be manufactured without using a metal mask, and thus can break through the resolution limit due to alignment accuracy of the metal mask. Furthermore, manufacturing a device without using a metal mask can eliminate the need for the manufacturing equipment of a metal mask and the cleaning step of the metal mask. For processing by photolithography, an apparatus that is the same as or similar to an apparatus used for manufacturing a transistor can be used; thus, there is no need to introduce a special apparatus to manufacture the device having the MML structure. The MML structure can reduce the manufacturing cost as described above, and thus is suitable for mass production of devices.

A display device having the MML structure does not require a pseudo improvement in resolution by employing unique pixel arrangement such as PenTile arrangement, for example; thus, the display device can achieve a high resolution (e.g., higher than or equal to 500 ppi, higher than or equal to 1000 ppi, higher than or equal to 2000 ppi, higher than or equal to 3000 ppi, or higher than or equal to 5000 ppi) while having what is called stripe arrangement where R, G, and B subpixels are arranged in one direction.

Providing a sacrificial layer over the light-emitting layer can reduce damage to the light-emitting layer in the manufacturing process of the display device, resulting in an increase in reliability of the light-emitting element.

Employing a formation step using an area mask and a processing step using a resist mask enables a light-emitting element to be manufactured by a relatively easy process.

The stacked-layer structure from the substrate 151 to the insulating layer 235 and the stacked-layer structure from the protective layer 131 to the substrate 152 are similar to those in the display device 50A; thus, the description thereof is omitted.

In FIG. 20A, the light-emitting elements 130R, 130G, and 130B are provided over the insulating layer 235.

The light-emitting element 130R includes a conductive layer 124R over the insulating layer 235, a conductive layer 126R over the conductive layer 124R, a layer 133R over the conductive layer 126R, a common layer 114 over the layer 133R, and the common electrode 115 over the common layer 114. The light-emitting element 130R shown in FIG. 20A emits red light (R). The layer 133R includes a light-emitting layer that emits red light. In the light-emitting element 130R, the layer 133R and the common layer 114 can be collectively referred to as an EL layer. One or both of the conductive layer 124R and the conductive layer 126R can be referred to as a pixel electrode.

The light-emitting element 130G includes a conductive layer 124G over the insulating layer 235, a conductive layer 126G over the conductive layer 124G, a layer 133G over the conductive layer 126G, the common layer 114 over the layer 133G, and the common electrode 115 over the common layer 114. The light-emitting element 130G shown in FIG. 20A emits green light (G). The layer 133G includes a light-emitting layer that emits green light. In the light-emitting element 130G, the layer 133G and the common layer 114 can be collectively referred to as an EL layer. One or both of the conductive layer 124G and the conductive layer 126G can be referred to as a pixel electrode.

The light-emitting element 130B includes a conductive layer 124B over the insulating layer 235, a conductive layer 126B over the conductive layer 124B, a layer 133B over the conductive layer 126B, the common layer 114 over the layer 133B, and the common electrode 115 over the common layer 114. The light-emitting element 130B shown in FIG. 20A emits blue light (B). The layer 133B includes a light-emitting layer that emits blue light. In the light-emitting element 130B, the layer 133B and the common layer 114 can be collectively referred to as an EL layer. One or both of the conductive layer 124B and the conductive layer 126B can be referred to as a pixel electrode.

In this specification and the like, in the EL layers included in the light-emitting elements, the island-shaped layer provided in each light-emitting element is referred to as the layer 133B, the layer 133G, or the layer 133R, and the layer shared by the plurality of light-emitting elements is referred to as the common layer 114. Note that in this specification and the like, only the layers 133R, 133G, and 133B are sometimes referred to as island-shaped EL layers, EL layers formed in an island shape, or the like, in which case the common layer 114 is not included in the EL layer. The light-emitting elements formed without using a metal mask do not necessarily include a common layer, and all the layers included in the EL layer may be formed in island shapes.

The layers 133R, 133G, and 133B are apart from each other. When the EL layer is provided to have an island shape for each light-emitting element, a leakage current between adjacent light-emitting elements can be inhibited. This can prevent crosstalk-induced unintended light emission, so that the display device can achieve extremely high contrast.

Although the layers 133R, 133G, and 133B have the same thickness in FIG. 20A, the present invention is not limited thereto. The layers 133R, 133G, and 133B may have different thicknesses.

The conductive layer 124R is in contact with the conductive layer 112b included in the transistor 205R in an opening portion provided in the insulating layers 218 and 235 and is connected to the conductive layer 112b. In a similar manner, the conductive layer 124G is connected to the conductive layer 112b included in the transistor 205G, and the conductive layer 124B is connected to the conductive layer 112b included in the transistor 205B.

The conductive layers 124R, 124G, and 124B are formed to cover the opening portions provided in the insulating layer 235. A layer 128 is embedded in the depression of the conductive layers 124R, 124G, and 124B.

The layer 128 has a function of filling the depressions formed by the conductive layers 124R, 124G, and 124B. The conductive layers 126R, 126G, and 126B electrically connected to the conductive layers 124R, 124G, and 124B, respectively, are provided over the conductive layers 124R, 124G, and 124B and the layer 128. Thus, regions overlapping with the depressions of the conductive layers 124R, 124G, and 124B can also be used as the light-emitting regions, increasing the aperture ratio of the pixels. The conductive layer 124R and the conductive layer 126R each preferably include a conductive layer functioning as a reflective electrode.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. For the layer 128, an organic insulating material that can be used for the insulating layer 237 can be used, for example.

Although FIG. 20A shows an example where the top surface of the layer 128 includes a flat portion, the shape of the layer 128 is not particularly limited. The top surface of the layer 128 can include at least one of a convex surface, a concave surface, and a flat surface.

The level of the top surface of the layer 128 and the level of the top surface of the conductive layer 124R may be the same or substantially the same, or may be different from each other. For example, the level of the top surface of the layer 128 may be either lower or higher than the level of the top surface of the conductive layer 124R.

An end portion of the conductive layer 126R may be aligned with an end portion of the conductive layer 124R or may cover the side surface of the end portion of the conductive layer 124R. The end portions of the conductive layers 124R and 126R each preferably have a tapered shape. Specifically, the end portions of the conductive layers 124R and 126R each preferably have a tapered shape with a taper angle greater than 0° and less than 90°. In the case where the end portion of the pixel electrode has a tapered shape, the layer 133R provided along the side surface of the pixel electrode has an inclined portion. When the side surface of the pixel electrode has a tapered shape, coverage with an EL layer provided along the side surface of the pixel electrode can be improved.

Since the conductive layers 124G and 126G and the conductive layers 124B and 126B are similar to the conductive layers 124R and 126R, the detailed description thereof is omitted.

The top and side surfaces of the conductive layer 126R are covered with the layer 133R. Similarly, the top and side surfaces of the conductive layers 126G are covered with the layer 133G, and the top and side surfaces of the conductive layers 126B are covered with the layer 133B. Accordingly, regions provided with the conductive layers 126R, 126G, and 126B can be entirely used as the light-emitting regions of the light-emitting elements 130R, 130G, and 130B, thereby increasing the aperture ratio of the pixels.

The side surface and part of the top surface of each of the layers 133R, 133G, and 133B are covered with insulating layers 125 and 127. The common layer 114 is provided over the layers 133R, 133G, and 133B and the insulating layers 125 and 127, and the common electrode 115 is provided over the common layer 114. The common layer 114 and the common electrode 115 are each one continuous film shared by a plurality of light-emitting elements.

In FIG. 20A, the insulating layer 237 shown in FIG. 15A or the like is not provided between the conductive layer 126R and the layer 133R. Similarly, the insulating layer 237 is not provided between the conductive layer 126G and the layer 133G and between the conductive layer 126B and the layer 133B. That is, the display device 50H is not provided with an insulating layer (also referred to as a bank or a spacer) that is in contact with the pixel electrode and covers an end portion of the top surface of the pixel electrode. Thus, the distance between adjacent light-emitting elements can be extremely narrowed. Accordingly, the display device can have high resolution or high definition. In addition, a mask for forming the insulating layer is not needed, which leads to a reduction in manufacturing cost of the display device.

As described above, the layers 133R, 133G, and 133B each include a light-emitting layer. The layers 133R, 133G, and 133B each preferably include the light-emitting layer and a carrier-transport layer (an electron-transport layer or a hole-transport layer). Alternatively, the layers 133R, 133G, and 133B each preferably include a light-emitting layer and a carrier-blocking layer (a hole-blocking layer or an electron-blocking layer). Alternatively, the layers 133R, 133G, and 133B each preferably include a light-emitting layer, a carrier-blocking layer, and a carrier-transport layer over the carrier-blocking layer. It is further preferable that the carrier-transport layer be provided over the light-emitting layer and the carrier-blocking layer be provided over the light-emitting layer. In the case where the surfaces of the layers 133R, 133G, and 133B are exposed to the air in the manufacturing process of the display device, providing one or both of the carrier-transport layer and the carrier-blocking layer over the light-emitting layer prevents exposure of the light-emitting layer as the outermost layer, so that the light-emitting layer can be inhibited from being exposed to the air. Thus, damage to the light-emitting layer can be reduced, and the reliability of the light-emitting element can be increased.

The common layer 114 includes, for example, an electron-injection layer or a hole-injection layer. Alternatively, the common layer 114 may be a stack of an electron-transport layer and an electron-injection layer, or may be a stack of a hole-transport layer and a hole-injection layer. The common layer 114 is shared by the light-emitting elements 130R, 130G, and 130B.

The side surfaces of the layers 133R, 133G, and 133B are covered with the insulating layer 125. The insulating layer 127 covers the side surfaces of the layers 133R, 133G, and 133B with the insulating layer 125 therebetween.

The side surfaces (and part of the top surfaces) of the layers 133R, 133G, and 133B are covered with at least one of the insulating layers 125 and 127, so that the common layer 114 (or the common electrode 115) can be inhibited from being in contact with the side surfaces of the pixel electrodes and the layers 133R, 133G, and 133B, leading to inhibition of a short circuit of the light-emitting elements. Thus, the reliability of the light-emitting element can be increased.

The insulating layer 125 preferably includes regions in contact with the side surfaces of the layers 133R, 133G, and 133B. The insulating layer 125 in contact with the layers 133R, 133G, and 133B can prevent film separation of the layers 133R, 133G, and 133B, whereby the reliability of the light-emitting element can be increased.

The insulating layer 127 is provided over the insulating layer 125 to fill a depression defined by the insulating layer 125. The insulating layer 127 preferably covers at least part of the side surface of the insulating layer 125.

The insulating layers 125 and 127 can fill a gap between adjacent island-shaped layers, whereby the formation surface of the layers (e.g., the carrier-injection layer and the common electrode) provided over the island-shaped layers can have higher flatness with small unevenness. Consequently, coverage with the carrier-injection layer, the common electrode, and the like can be improved.

The common layer 114 and the common electrode 115 are provided over the layer 133R, the layer 133G, the layer 133B, the insulating layer 125, and the insulating layer 127. Before the insulating layers 125 and 127 are provided, a step is generated due to a level difference between a region where the pixel electrode and the island-shaped EL layer are provided and a region where neither the pixel electrode nor the island-shaped EL layer is provided (a region between the light-emitting elements). In the display device of one embodiment of the present invention, the step can be eliminated with the insulating layers 125 and 127, and the coverage with the common layer 114 and the common electrode 115 can be improved. Thus, poor connection caused by step disconnection can be inhibited. In addition, an increase in electric resistance, which is caused by local thinning of the common electrode 115 due to the step, can be inhibited.

The top surface of the insulating layer 127 preferably has a shape with high flatness. The top surface of the insulating layer 127 may include at least one of a flat surface, a convex surface, and a concave surface. For example, the top surface of the insulating layer 127 preferably has a convex shape with a large radius of curvature.

The insulating layer 125 can have a single layer structure or a stacked-layer structure of two or more layers. The insulating layer 125 preferably includes one or more inorganic insulating layers. For the insulating layer 125, any of the materials given for the insulating layers 106 and 105 can be used. In particular, aluminum oxide is preferably used because it has high selectivity with respect to the EL layer in etching and has a function of protecting the EL layer in forming the insulating layer 127. In particular, when an inorganic insulating layer such as an aluminum oxide film, a hafnium oxide film, or a silicon oxide film is formed by an ALD method as the insulating layer 125, the insulating layer 125 can have few pinholes and an excellent function of protecting the EL layer. The insulating layer 125 may have a stacked-layer structure of a film formed by an ALD method and a film formed by a sputtering method. For example, the insulating layer 125 may have a stacked-layer structure of an aluminum oxide film formed by an ALD method and a silicon nitride film formed by a sputtering method.

The insulating layer 125 preferably has a function of a barrier film against at least one of water and oxygen. The insulating layer 125 preferably has a function of inhibiting diffusion of at least one of water and oxygen. Alternatively, the insulating layer 125 preferably has a function of capturing or fixing (also referred to as gettering) at least one of water and oxygen.

When the insulating layer 125 has a function of the barrier film, entry of impurities (typically, at least one of water and oxygen) that would diffuse into the light-emitting elements from the outside can be inhibited. With this structure, a highly reliable light-emitting element and a highly reliable display device can be provided.

The insulating layer 127 provided over the insulating layer 125 has a function of filling large unevenness of the insulating layer 125, which is formed between the adjacent light-emitting elements. In other words, the insulating layer 127 has an effect of improving the flatness of the formation surface of the common electrode 115.

As the insulating layer 127, an insulating layer including an organic material can be suitably used. As the organic material, a photosensitive organic resin is preferably used, and for example, a photosensitive resin composite including an acrylic resin is preferably used. In this specification and the like, an acrylic resin refers not only to a polymethacrylic acid ester or a methacrylic resin, but also to all the acrylic polymer in a broad sense in some cases.

Alternatively, the insulating layer 127 may be formed using an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like. The insulating layer 127 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used as the photosensitive resin. As the photosensitive resin, either a positive-type material or a negative-type material may be used.

The insulating layer 127 may be formed using a material absorbing visible light. When the insulating layer 127 absorbs light emitted from the light-emitting element, light leakage (stray light) from the light-emitting element to the adjacent light-emitting element through the insulating layer 127 can be suppressed. Thus, the display quality of the display device can be improved. Since no polarizing plate is required to improve the display quality of the display device, the weight and thickness of the display device can be reduced.

Examples of the material absorbing visible light include materials including pigment of black or the like, materials including dye, light-absorbing resin materials (e.g., polyimide), and resin materials that can be used for color filters (color filter materials). Using a resin material obtained by stacking or mixing color filter materials of two or three or more colors is particularly preferable to enhance the effect of blocking visible light. In particular, mixing color filter materials of three or more colors enables the formation of a black or nearly black resin layer.

### Structure Example 8 of Display Device

FIG. 20B shows an example of a cross section of the display portion 162 of a display device 50I. The display device 50I is different from the display device 50H mainly in that the subpixels of different colors are provided with coloring layers (color filters or the like). The structure shown in FIG. 20B can be combined with the structure of the region including the FPC 172, the circuit portion 164, the stacked-layer structure from the substrate 151 to the insulating layer 235 in the display portion 162, the connection portion 140, and the end portion, which is shown in FIG. 20A.

The display device 50I shown in FIG. 20B includes the light-emitting elements 130R, 130G, and 130B, the coloring layers 132R, 132G, and 132B, and the like.

Light emitted from the light-emitting element 130R is extracted as red light to the outside of the display device 50I through the coloring layer 132R. Similarly, light emitted from the light-emitting element 130G is extracted as green light to the outside of the display device 50I through the coloring layer 132G. Light emitted from the light-emitting element 130B is extracted as blue light to the outside of the display device 50I through the coloring layer 132B.

The light-emitting elements 130R, 130G, and 130B each include the layer 133. These three layers 133 are formed using the same material in the same step. The three layers 133 are isolated from each other. When the EL layer is provided to have an island shape for each light-emitting element, a leakage current between adjacent light-emitting elements can be inhibited. This can prevent crosstalk-induced unintended light emission, so that the display device can achieve extremely high contrast.

The light-emitting elements 130R, 130G, and 130B shown in FIG. 20B emit white light, for example. When white light emitted from the light-emitting elements 130R, 130G, and 130B passes through the respective coloring layers 132R, 132G, and 132B, light of a desired color can be obtained.

Alternatively, the light-emitting elements 130R, 130G, and 130B shown in FIG. 20B emit blue light, for example. In this case, the layer 133 includes one or more light-emitting layers that emit blue light. In the subpixel 11B that emits blue light, blue light emitted from the light-emitting element 130B can be extracted. In each of the subpixel 11R that emits red light and the subpixel 11G that emits green light, a color conversion layer is provided between the light-emitting element 130R or 130G and the substrate 152 so that blue light emitted from the light-emitting element 130R or 130G is converted into light with a longer wavelength, whereby red light or green light can be extracted. Furthermore, it is preferable that over the light-emitting element 130R, the coloring layer 132R be provided between the color conversion layer and the substrate 152 and over the light-emitting element 130G, the coloring layer 132G be provided between the color conversion layer and the substrate 152. When light passing through the color conversion layer is extracted through the coloring layer, light other than light of a desired color can be absorbed by the coloring layer, and color purity of light exhibited by a subpixel can be improved.

### Structure Example 9 of Display Device

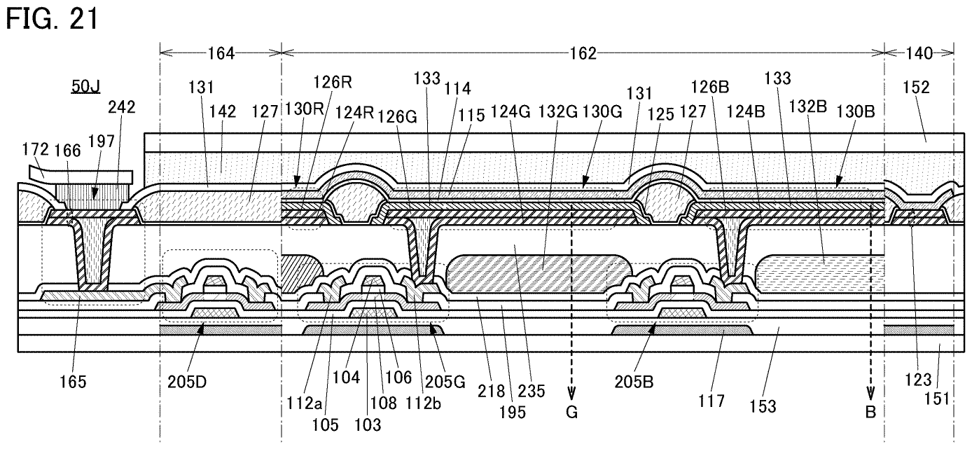

A display device 50J shown in FIG. 21 is different from the display device 50I mainly in having a bottom-emission structure.

Light from the light-emitting element is emitted toward the substrate 151. For the substrate 151, a material having a high visible-light-transmitting property is preferably used. By contrast, there is no limitation on the light-transmitting property of a material used for the substrate 152.

The light-blocking layer 117 is preferably provided between the substrate 151 and the transistor. FIG. 21 shows an example where the light-blocking layers 117 are provided over the substrate 151, the insulating layer 153 is provided over the light-blocking layers 117, and the transistors 205D, 205R (not shown), 205G, and 205B and the like are provided over the insulating layer 153. In addition, the coloring layers 132R, 132G, and 132B are provided over the insulating layer 218, and the insulating layer 235 is provided over the coloring layers 132R, 132G, and 132B.

The light-emitting element 130R overlapping with the coloring layer 132R includes the conductive layer 124R, the conductive layer 126R, the layer 133, the common layer 114, and the common electrode 115.

The light-emitting element 130G overlapping with the coloring layer 132G includes the conductive layer 124G, the conductive layer 126G, the layer 133, the common layer 114, and the common electrode 115.

The light-emitting element 130B overlapping with the coloring layer 132B includes the conductive layer 124B, the conductive layer 126B, the layer 133, the common layer 114, and the common electrode 115.

A material having a high visible-light-transmitting property is used for each of the conductive layers 124R, 124G, 124B, 126R, 126G, and 126B. A material that reflects visible light is preferably used for the common electrode 115. In the display device having a bottom-emission structure, a metal or the like having low electric resistance can be used for the common electrode 115; thus, a voltage drop due to the electric resistance of the common electrode 115 can be suppressed and the display quality can be improved.

With the use of the transistor of one embodiment of the present invention for the pixel circuit, the occupied area can be reduced, so that the aperture ratio of the pixel can be increased or the pixel size can be reduced in the display device having a bottom-emission structure.

### Structure Example 10 of Display Device

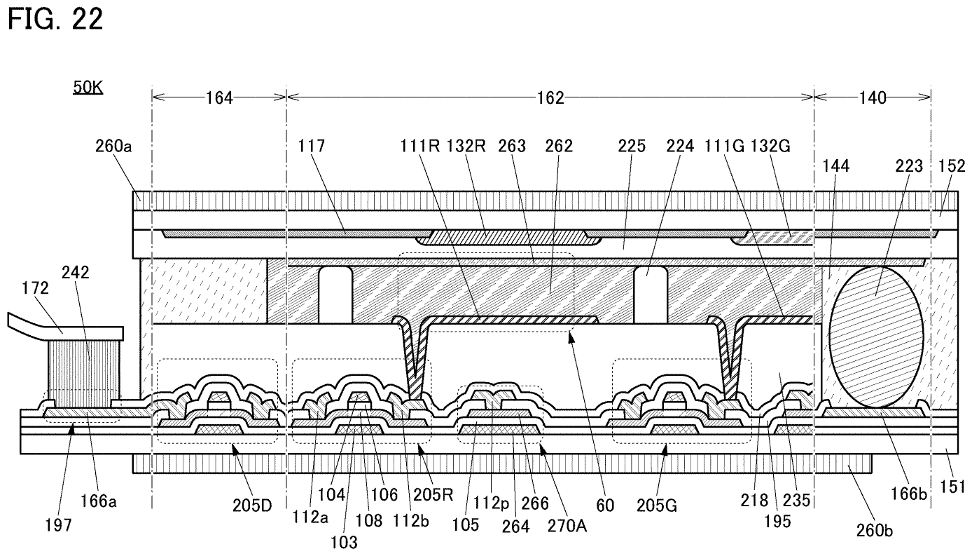

A display device 50K shown in FIG. 22 is a liquid crystal display device in a VA mode.

The substrates 151 and 152 are bonded to each other with an adhesive layer 144. A region surrounded by the substrates 151 and 152 and the adhesive layer 144 is filled with liquid crystal 262. A polarizing plate 260a is positioned on the outer surface of the substrate 152, and a polarizing plate 260b is positioned on the outer surface of the substrate 151. Although not shown, a backlight can be provided outside the polarizing plate 260a or 260b.

The substrate 151 is provided with the transistors 205D, 205R, and 205G, the connection portion 197, a spacer 224, and the like. The transistor 205D is provided in the circuit portion 164, and the transistors 205R and 205G are provided in the display portion 162.

The insulating layer 218 is provided over the transistors 205R, 205G, and 205D, the insulating layer 235 is provided over the insulating layer 218, and a liquid crystal element 60 is provided over the insulating layer 235.

The substrate 152 is provided with the coloring layers 132R and 132G, the light-blocking layer 117, an insulating layer 225, a conductive layer 263, and the like. The conductive layer 263 functions as a common electrode of the liquid crystal element 60.

A subpixel included in the display portion 162 includes a transistor, the liquid crystal element 60, and a coloring layer. For example, a subpixel that emits red light includes the transistor 205R, the liquid crystal element 60, and the coloring layer 132R that transmits red light. A subpixel that emits green light includes the transistor 205G, the liquid crystal element 60, and the coloring layer 132G that transmits green light. Similarly, although not shown, a subpixel that emits blue light includes a transistor, the liquid crystal element 60, and a coloring layer that transmits blue light.

The liquid crystal element 60 includes the pixel electrode 111, the conductive layer 263, and the liquid crystal 262 sandwiched therebetween.

A conductive layer 264 is provided on the same surface as the conductive layer 103. The conductive layer 264 can be formed in the same step as the conductive layer 103. An electrode 266 is provided on the same surface as the semiconductor layer 108. The electrode 266 is formed in the same step as the regions 108P and 108Q of the semiconductor layer 108 (see FIG. 1B) and has low electric resistance like the source region and the drain region of the transistor. The conductive layer 264 includes a region overlapping with the electrode 266 with the insulating layer 105 therebetween. The conductive layer 264, the electrode 266, and the insulating layer 105, which is positioned therebetween, form a capacitor. In other words, the display device 50K includes a capacitor 270A in a region where the conductive layer 264, the electrode 266, and the insulating layer 105 overlap with each other. A conductive layer 112p is connected to the electrode 266. The conductive layer 112p is formed in the same step as the conductive layers 112a and 112b and functions as a wiring. Although FIG. 22 shows the structure which includes a region where the capacitor 270A overlaps with the liquid crystal element 60, one embodiment of the present invention is not limited thereto. A structure can be employed which does not include a region where the capacitor 270A overlaps with the liquid crystal element 60. There is no particular limitation on the structure of the capacitor 270A.

The insulating layer 225 is provided on the substrate 152 side to cover the coloring layers 132R and 132G and the light-blocking layer 117. The insulating layer 225 may function as a planarization layer. The insulating layer 225 enables the conductive layer 263 to have an almost flat surface, resulting in a uniform alignment state of the liquid crystal 262.

Note that an alignment film (not shown) for controlling the alignment of the liquid crystal 262 can be provided on surfaces of the conductive layer 263, the insulating layer 218, and the like which are in contact with the liquid crystal 262.

The pixel electrode 111 and the conductive layer 263 transmit visible light. That is, a transmissive liquid crystal device can be obtained. For example, in the case where a backlight is provided on the substrate 152 side, light from the backlight which is polarized by the polarizing plate 260a passes through the substrate 152, the conductive layer 263, the liquid crystal 262, the pixel electrode 111, and the substrate 151, and then reaches the polarizing plate 260b. In that case, alignment of the liquid crystal 262 is controlled with a voltage that is applied between the pixel electrode 111 and the conductive layer 263, and thus optical modulation of light can be controlled. That is, the intensity of light emitted through the polarizing plate 260b can be controlled. Light other than one in a particular wavelength region of the incident light is absorbed by the coloring layer, and thus, emitted light is red light, for example.

As the polarizing plate 260b, a linear polarizing plate or a circularly polarizing plate can be used. An example of a circularly polarizing plate is a stack including a linear polarizing plate and a quarter-wave retardation plate. Reflection of external light can be suppressed with a circularly polarizing plate used as the polarizing plate 260b.

In the case where a circularly polarizing plate is used as the polarizing plate 260b, a circularly polarizing plate or a general linear polarizing plate may be used as the polarizing plate 260a. The cell gap, alignment, driving voltage, and the like of the liquid crystal element used as the liquid crystal element 60 can be controlled in accordance with the kinds of polarizing plates used as the polarizing plates 260a and 260b so that desirable contrast can be obtained.

The conductive layer 263 is connected to a conductive layer 166b provided on the substrate 151 side through a connector 223 in the connection portion 140. Thus, a potential or a signal can be supplied from an FPC or an IC provided on the substrate 151 side to the conductive layer 263. FIG. 22 shows an example in which the conductive layer 166b is formed by processing the same conductive film as the conductive layer 112a and the conductive layer 112b.

As the connector 223, a conductive particle can be used, for example. As the conductive particle, a particle of an organic resin, silica, or the like coated with a metal material can be used. It is preferable to use nickel or gold as the metal material to reduce contact resistance. It is also preferable to use a particle coated with layers of two or more kinds of metal materials, such as a particle coated with nickel and further with gold. As the connector 223, a material capable of elastic deformation or plastic deformation is preferably used. As shown in FIG. 22, the conductive particle has a shape that is vertically crushed in some cases. This increases the contact area between the connector 223 and a conductive layer connected with the connector 223, thereby reducing contact resistance and inhibiting generation of defects such as poor connection. The connector 223 is preferably provided so as to be covered with the adhesive layer 144. For example, the connectors 223 are preferably dispersed in the adhesive layer 144 before curing.

The connection portion 197 is provided in a region near an end portion of the substrate 151. In the connection portion 197, a conductive layer 166a is connected to the FPC 172 through the connection layer 242. FIG. 22 shows an example in which the conductive layer 166a is formed by processing the same conductive film as the conductive layer 112a and the conductive layer 112b.

### Structure Example 11 of Display Device

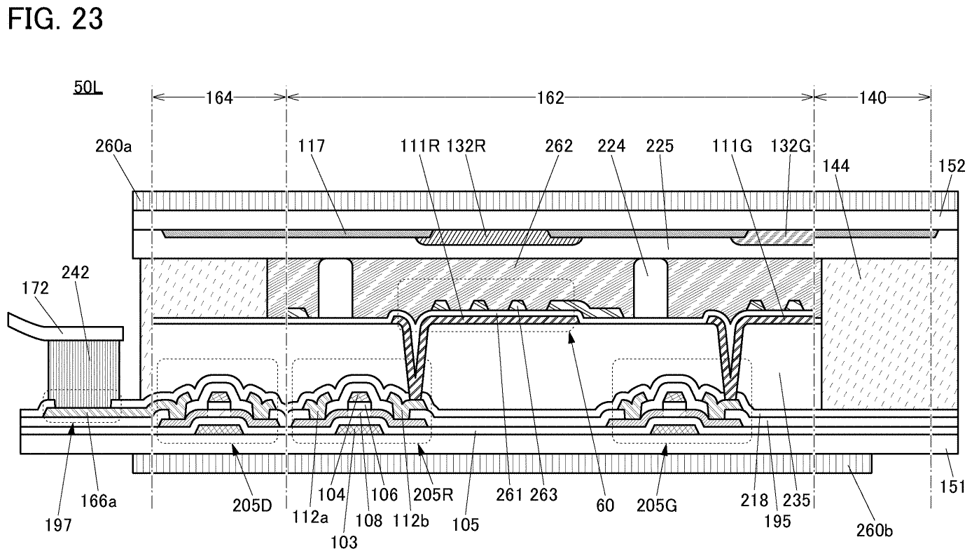

A display device 50L shown in FIG. 23 is an FFS liquid crystal display device. The display device 50L is different from the display device 50K mainly in the structure of the liquid crystal element 60.

An insulating layer 261 is provided over the pixel electrode 111 and the insulating layer 235, and the conductive layer 263 functioning as a common electrode of the liquid crystal element 60 is provided over the insulating layer 261.

In a plan view, the conductive layer 263 has a comb-like shape or a shape with a slit. The conductive layer 263 is provided to overlap with the pixel electrode 111. There is a region where the conductive layer 263 is not provided over the pixel electrode 111 in a region overlapping with the coloring layer.

The pixel electrode 111 and the conductive layer 263 are stacked with the insulating layer 261 therebetween, whereby a capacitor is formed. Accordingly, it is not necessary to provide a capacitor additionally, and thus the aperture ratio of the pixel can be increased.

Note that in the liquid crystal element 60, both the pixel electrode 111 and the conductive layer 263 may have a comb-like top surface shape. Meanwhile, as shown in the display device 50L, only one of the pixel electrode 111 and the conductive layer 263 has a comb-like top surface shape in the liquid crystal element 60, whereby the pixel electrode 111 and the conductive layer 263 partly overlap with each other. In this structure, capacitance between the pixel electrode 111 and the conductive layer 263 can be used as a storage capacitor, and thus a capacitor does not need to be provided additionally; accordingly, the aperture ratio of the display device can be increased.

This embodiment can be combined as appropriate with the other embodiments.

### Embodiment 4

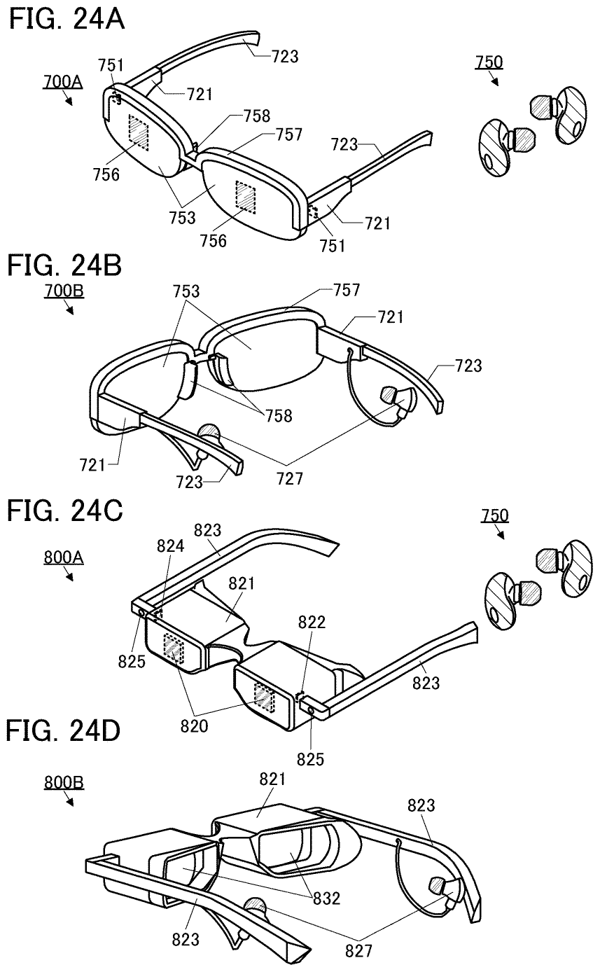

In this embodiment, electronic appliances of embodiments of the present invention will be described with reference to FIGS. 24A to 24D, FIGS. 25A to 25F, and FIGS. 26A to 26G.

Electronic appliances of this embodiment are each provided with the display device of one embodiment of the present invention in a display portion. The display device of one embodiment of the present invention can have high resolution and definition. Thus, the display device of one embodiment of the present invention can be used for a display portion of a variety of electronic appliances.

A semiconductor device of one embodiment of the present invention can also be applied to any other portion of an electronic appliance than a display portion. For example, the semiconductor device of one embodiment of the present invention is preferably used for a control portion or the like of an electronic appliance because lower power consumption can be achieved.

Examples of the electronic appliances include a digital camera, a digital video camera, a digital photo frame, a mobile phone, a portable game console, a portable information terminal, and an audio reproducing device, in addition to electronic appliances with a relatively large screen, such as a television device, desktop and laptop computers, a monitor of a computer and the like, digital signage, and a large game machine such as a pachinko machine.

In particular, the display device of one embodiment of the present invention can have a high resolution, and thus can be favorably used for an electronic appliance having a relatively small display portion. Examples of such an electronic appliance include watch-type and bracelet-type information terminal devices (wearable devices) and wearable devices worn on the head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display device of one embodiment of the present invention is preferably 100 ppi or higher, further preferably 300 ppi or higher, further preferably 500 ppi or higher, further preferably 1000 ppi or higher, still further preferably 2000 ppi or higher, still further preferably 3000 ppi or higher, still further preferably 5000 ppi or higher, yet further preferably 7000 ppi or higher. The use of the display device having one or both of such high definition and high resolution can further increase realistic sensation, sense of depth, and the like. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic appliance in this embodiment can include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic appliance in this embodiment can have a variety of functions. For example, the electronic appliance in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of head-mounted wearable devices will be described with reference to FIGS. 24A to 24D. The wearable devices have at least one of a function of displaying AR contents, a function of displaying VR contents, a function of displaying SR contents, and a function of displaying MR contents. The electronic appliance having a function of displaying contents of at least one of AR, VR, SR, MR, and the like enables the user to feel a higher level of immersion.

An electronic appliance 700A shown in FIG. 24A and an electronic appliance 700B shown in FIG. 24B each include a pair of display panels 751, a pair of housings 721, a communication portion (not shown), a pair of wearing portions 723, a control portion (not shown), an image capturing portion (not shown), a pair of optical members 753, a frame 757, and a pair of nose pads 758.

The display device of one embodiment of the present invention can be used for the display panels 751. Thus, the electronic appliances are capable of performing ultrahigh-resolution display.

The electronic appliances 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic appliances 700A and 700B are electronic appliances capable of AR display.

In the electronic appliances 700A and 700B, a camera that captures images of the front side can be provided as the image capturing portion. Furthermore, when the electronic appliances 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic appliances 700A and 700B are provided with a battery (not shown) so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion element can be used as a light-receiving element. One or both of an inorganic semiconductor and an organic semiconductor can be used for an active layer of the photoelectric conversion element.

An electronic appliance 800A shown in FIG. 24C and an electronic appliance 800B shown in FIG. 24D each include a pair of display portions 820, a housing 821, a communication portion 822, a pair of wearing portions 823, a control portion 824, a pair of image capturing portions 825, and a pair of lenses 832. Note that the display portions 820, the communication portion 822, and the image capturing portions 825 are omitted in FIG. 24D.

The display device of one embodiment of the present invention can be used in the display portions 820. Thus, the electronic appliances are capable of performing ultrahigh-resolution display. Such electronic appliances provide a high sense of immersion to the user.

The display portions 820 are positioned inside the housing 821 so as to be seen through the lenses 832. When the pair of display portions 820 display different images, three-dimensional display using parallax can be performed.

The electronic appliances 800A and 800B can be regarded as electronic appliances for VR. The user who wears the electronic appliance 800A or the electronic appliance 800B can see images displayed on the display portions 820 through the lenses 832.

The electronic appliances 800A and 800B preferably include a mechanism for adjusting the lateral positions of the lenses 832 and the display portions 820 so that the lenses 832 and the display portions 820 are positioned optimally in accordance with the positions of the user's eyes. Moreover, the electronic appliances 800A and 800B preferably include a mechanism for adjusting focus by changing the distance between the lenses 832 and the display portions 820.

The electronic appliance 800A or the electronic appliance 800B can be mounted on the user's head with the wearing portions 823. FIG. 24C and the like show that the wearing portion 823 has a shape like a temple of glasses; however, there is no particular limitation on the shape of the wearing portion 823. The wearing portion 823 can have any shape with which the user can wear the electronic appliance, such as a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

Although an example where the image capturing portion 825 is provided is shown here, a range sensor (hereinafter also referred to as a sensing portion) capable of measuring a distance between the user and an object just needs to be provided. In other words, the image capturing portion 825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic appliance 800A may include a vibration mechanism that functions as bone-conduction earphones. For example, at least one of the display portion 820, the housing 821, and the wearing portion 823 can include the vibration mechanism. Thus, without additionally requiring an audio device such as headphones, earphones, or a speaker, the user can enjoy video and sound only by wearing the electronic appliance 800A.

The electronic appliances 800A and 800B may each include an input terminal. To the input terminal, a cable for supplying a video signal from a video output device or the like, power for charging the battery provided in the electronic appliance, and the like can be connected.

The electronic appliance of one embodiment of the present invention can transmit information to earphones by wire or wirelessly.

The electronic appliance of one embodiment of the present invention may have a function of performing wireless communication with earphones 750. The earphones 750 include a communication portion (not shown) and have a wireless communication function. The earphones 750 can receive information (e.g., audio data) from the electronic appliance with the wireless communication function. For example, the electronic appliance 700A in FIG. 24A has a function of transmitting information to the earphones 750 with the wireless communication function. As another example, the electronic appliance 800A in FIG. 24C has a function of transmitting information to the earphones 750 with the wireless communication function.

The electronic appliance may include an earphone portion. The electronic appliance 700B in FIG. 24B includes earphone portions 727. For example, the earphone portion 727 can be connected to the control portion by wire. Part of a wiring that connects the earphone portion 727 and the control portion may be positioned inside the housing 721 or the mounting portion 723.

Similarly, the electronic appliance 800B in FIG. 24D includes earphone portions 827. For example, the earphone portion 827 can be connected to the control portion 824 by wire. Part of a wiring that connects the earphone portion 827 and the control portion 824 may be positioned inside the housing 821 or the mounting portion 823. Alternatively, the earphone portions 827 and the mounting portions 823 may include magnets. This is preferable because the earphone portions 827 can be fixed to the mounting portions 823 with magnetic force and thus can be easily housed.

The electronic appliance may include an audio output terminal to which earphones, headphones, or the like can be connected. The electronic appliance may include one or both of an audio input terminal and an audio input mechanism. As the audio input mechanism, a sound collecting device such as a microphone can be used, for example. The electronic appliance may have a function of a headset by including the audio input mechanism.

As described above, both the glasses-type device (e.g., the electronic appliances 700A and 700B) and the goggles-type device (e.g., the electronic appliances 800A and 800B) are preferable as the electronic appliance of one embodiment of the present invention.

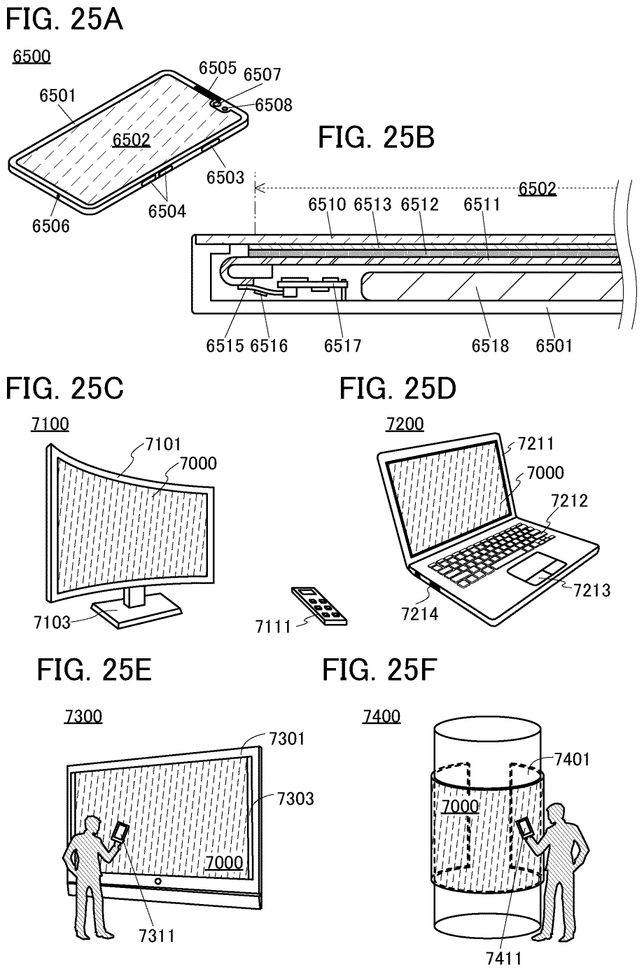

An electronic appliance 6500 shown in FIG. 25A is a portable information terminal that can be used as a smartphone.

The electronic appliance 6500 includes a housing 6501, a display portion 6502, a power button 6503, buttons 6504, a speaker 6505, a microphone 6506, a camera 6507, and a light source 6508. The display portion 6502 has a touch panel function.

The display device of one embodiment of the present invention can be used in the display portion 6502.

FIG. 25B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not shown).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A display device of one embodiment of the present invention can be used as the display panel 6511. Thus, an extremely lightweight electronic appliance can be achieved. Since the display panel 6511 is extremely thin, the battery 6518 with high capacity can be mounted without an increase in the thickness of the electronic appliance. Moreover, part of the display panel 6511 is folded back so that a connection portion with the FPC 6515 is provided on the back side of the pixel portion, whereby an electronic appliance with a narrow bezel can be achieved.

The electronic appliances shown in FIGS. 25C to 25F each include a display portion 7000. The display device of one embodiment of the present invention can be used for the display portion 7000.

FIG. 25C shows an example of a television device. In a television device 7100, a display portion 7000 is incorporated in a housing 7101. Here, the housing 7101 is supported by a stand 7103.

Operation of the television device 7100 shown in FIG. 25C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may be provided with a display portion for displaying information output from the remote control 7111. With operation keys or a touch panel provided in the remote control 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 25D shows an example of a laptop computer. The laptop computer 7200 includes a housing 7211, a keyboard 7212, a pointing device 7213, an external connection port 7214, and the like. The display portion 7000 is incorporated in the housing 7211.

FIGS. 25E and 25F show examples of digital signage.

Digital signage 7300 shown in FIG. 25E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 25F shows digital signage 7400 attached to a cylindrical pillar 7401. The digital signage 7400 includes the display portion 7000 provided along a curved surface of the pillar 7401.

A larger area of the display portion 7000 can increase the amount of information that can be provided at a time. The larger display portion 7000 attracts more attention, so that the effectiveness of the advertisement can be increased, for example.

The use of a touch panel in the display portion 7000 is preferable because in addition to display of a still image or a moving image on the display portion 7000, intuitive operation by a user is possible. Moreover, for an application for providing information such as route information or traffic information, usability can be enhanced by intuitive operation.

As shown in FIGS. 25E and 25F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

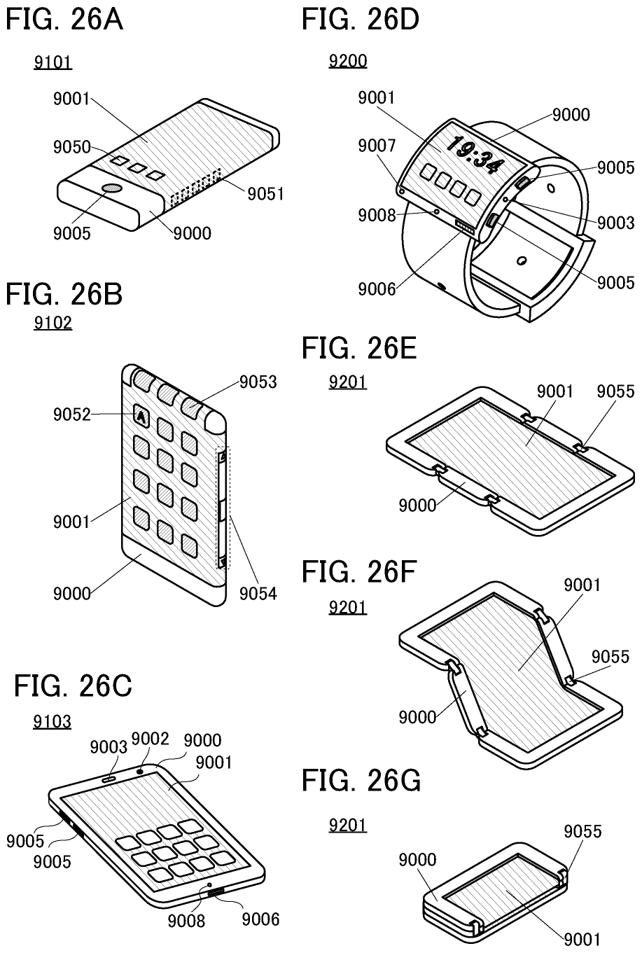

Electronic appliances shown in FIGS. 26A to 26G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

In FIGS. 26A to 26G, the display device of one embodiment of the present invention can be used in the display portion 9001.

The electronic appliances shown in FIGS. 26A to 26G have a variety of functions. For example, the electronic appliances can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic appliances are not limited thereto, and the electronic appliances can have a variety of functions. The electronic appliances may include a plurality of display portions. The electronic appliances may be provided with a camera or the like and have a function of capturing a still image or a moving image, a function of storing the captured image in a storage medium (an external storage medium or a storage medium incorporated in the camera), a function of displaying the captured image on the display portion, and the like.

The electronic appliances in FIGS. 26A to 26G will be described in detail below.

FIG. 26A is a perspective view of a portable information terminal 9101. The portable information terminal 9101 can be used as a smartphone, for example. The portable information terminal 9101 may include the speaker 9003, the connection terminal 9006, the sensor 9007, or the like. The portable information terminal 9101 can display text and image information on its plurality of surfaces. FIG. 26A shows an example where three icons 9050 are displayed.

Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 26B is a perspective view of a portable information terminal 9102. The portable information terminal 9102 has a function of displaying information on three or more surfaces of the display portion 9001. Here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 26C is a perspective view of a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, the camera 9002, the microphone 9008, and the speaker 9003 on the front surface of the housing 9000; the operation keys 9005 as buttons for operation on the side surface of the housing 9000; and the connection terminal 9006 on the bottom surface of the housing 9000.

FIG. 26D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 26E to 26G are perspective views of a foldable portable information terminal 9201. FIG. 26E is a perspective view showing the portable information terminal 9201 that is opened. FIG. 26G is a perspective view showing the portable information terminal 9201 that is folded. FIG. 26F is a perspective view showing the portable information terminal 9201 that is shifted from one of the states in FIGS. 26E and 26G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined as appropriate with the other embodiments.

### Example 1

In this example, semiconductor devices including TGSA transistors of one embodiment of the present invention were fabricated, and the electrical characteristics and reliability of the transistors were evaluated.

In this example, three kinds of samples (Sample A1 to Sample A3) each including the transistor of one embodiment of the present invention were fabricated. For the structures of Sample A1 to Sample A3, the description of FIGS. 3A to 3C can be referred to. For the fabrication method, the description of FIGS. 9A to 9E and FIGS. 10A to 10D can be referred to.

### <Sample Fabrication>

First, an approximately 100-nm-thick tungsten film was formed over the substrate 102 by a sputtering method, and then processed to form the conductive layer 103. Note that in this example, transistors including the conductive layer 103 and transistors not including the conductive layer 103 were fabricated.

Next, the insulating layer 105a and the insulating layer 105b were formed by a plasma CVD method as the insulating layer 105. An approximately 17-nm-thick silicon nitride film was formed as the insulating layer 105a, and an approximately 90-nm-thick silicon oxynitride film was formed as the insulating layer 105b. For the formation of the insulating layer 105a, a mixed gas of a silane gas, a nitrogen gas, and an ammonia gas was used. For the formation of the insulating layer 105b, a mixed gas of a silane gas and a dinitrogen monoxide (N₂O) gas was used. A glass substrate with a size of 600 mm×720 mm was used as the substrate 102.

Subsequently, as the metal oxide film 108f, an approximately 6-nm-thick indium oxide film was formed by a magnetron sputtering method. The metal oxide film 108f had a three-layer structure of the metal oxide film 108af with a thickness of approximately 1 nm, the metal oxide film 108bf with a thickness of approximately 4 nm, and the metal oxide film 108cf with a thickness of approximately 1 nm. The metal oxide film 108af, the metal oxide film 108bf, and the metal oxide film 108cf were successively formed in the same treatment chamber using the same In₂O₃ sputtering target. The substrate was not heated at the time of the film formation.

The film formation conditions (first film formation conditions) of the metal oxide film 108af were as follows: the pressure was 0.2 Pa and the power was 1.0 KW (power density: 0.66 W/cm²). The film formation conditions (second film formation conditions) of the metal oxide film 108bf were as follows: the pressure was 0.6 Pa and the power was 0.5 kW (power density: 0.33 W/cm²). The film formation conditions (third film formation conditions) of the metal oxide film 108cf were the same as the first film formation conditions. Note that the power density is a value obtained by dividing power by a magnet area.

The kinds of gases used for the film formation and the flow rate ratios of the gases were different between Sample A1 to Sample A3.

For Sample A1, argon, hydrogen, and oxygen were used as film formation gases for the metal oxide film 108af, the metal oxide film 108bf, and the metal oxide film 108cf. In the formation of the metal oxide film 108af and the metal oxide film 108cf, the argon flow rate ratio was 91%, the hydrogen flow rate ratio was 5%, and the oxygen flow rate ratio was 4%. In the formation of the metal oxide film 108bf, the argon flow rate ratio was 92%, the hydrogen flow rate ratio was 5%, and the oxygen flow rate ratio was 3%.

For Sample A2, argon and oxygen were used as film formation gases for the metal oxide film 108af, the metal oxide film 108bf, and the metal oxide film 108cf, and hydrogen was not used. In the formation of the metal oxide film 108af and the metal oxide film 108cf, the argon flow rate ratio was 96% and the oxygen flow rate ratio was 4%. In the formation of the metal oxide film 108bf, the argon flow rate ratio was 97% and the oxygen flow rate ratio was 3%.

For Sample A3, argon and oxygen were used as film formation gases for the metal oxide film 108af, the metal oxide film 108bf, and the metal oxide film 108cf, and hydrogen was not used. In the formation of the metal oxide film 108af and the metal oxide film 108cf, the argon flow rate ratio was 98% and the oxygen flow rate ratio was 2%. In the formation of the metal oxide film 108bf, the argon flow rate ratio was 99% and the oxygen flow rate ratio was 1%.

Then, the metal oxide film 108f was processed to form the semiconductor layer 108. The processing of the metal oxide film 108f was performed by a wet etching method.

Next, as the first heat treatment, heat treatment was performed at 350 °C in a dry air (CDA, dew point: lower than or equal to −70 °C) atmosphere for one hour. This increased the crystallinity of the semiconductor layer 108. An oven was used for the first heat treatment.

Subsequently, the insulating film 106f was formed using an approximately 100-nm-thick silicon oxynitride film by a plasma CVD method. For the formation of the insulating film 106f, a mixed gas of a silane gas and a dinitrogen monoxide (N₂O) gas was used.

Then, as the second heat treatment, heat treatment was performed at 350 °C in a dry air atmosphere for one hour. An oven was used for the second heat treatment.

Next, an approximately 20-nm-thick metal oxide film was formed as the film 139. The metal oxide film was formed by a sputtering method using an IGZO sputtering target with an atomic ratio of metal elements of In:Ga:Zn=1:1:1.

Then, as the third heat treatment, heat treatment was performed at 350 °C in a dry air atmosphere for one hour. An oven was used for the third heat treatment.

Next, the film 139 was removed. The removal of the film 139 was performed by a wet etching method.

Subsequently, a conductive film was formed and processed to form the conductive layer 104. For the conductive layer 104, a stacked-layer structure in which an approximately 100-nm-thick titanium film, an approximately 300-nm-thick copper film, and an approximately 10-nm-thick titanium film were formed in this order was used. The insulating film 106f was processed to form the insulating layer 106.

Next, plasma treatment was performed in an atmosphere including hydrogen, and hydrogen was supplied as the first element to the semiconductor layer 108. Consequently, the region 108P and the region 108Q each including hydrogen were formed in the region of the semiconductor layer 108 not overlapping with the conductive layer 104. Then, as the insulating film 195f, a silicon nitride oxide film with a thickness of approximately 300 nm was formed by a plasma CVD method. The plasma treatment and formation of the insulating film 195f were successively performed in the same treatment chamber of a plasma CVD apparatus. For the plasma treatment and formation of the insulating film 195f, a mixed gas of a silane gas, a nitrogen gas, a dinitrogen monoxide (N₂O) gas, and an ammonia gas was used.

Subsequently, the insulating film 195f was partly etched, so that the opening portion 147a and the opening portion 147b respectively reaching the region 108P and the region 108Q were formed. Accordingly, the insulating layer 195 was obtained.

Next, an approximately 100-nm-thick molybdenum film was formed by a sputtering method to cover the opening portion 147a and the opening portion 147b and processed to form the conductive layer 112a and the conductive layer 112b.

Then, a polyimide resin film with a thickness of approximately 1.5 μm was formed as the insulating layer 218.

Subsequently, heat treatment was performed at 250 °C in a nitrogen atmosphere for one hour. An oven was used for the heat treatment.

Through the above process, Samples A1 to A3 were obtained.

<I_{d}-V_{g} Characteristics>

Next, I_{d}-V_{g} characteristics of the transistors of Samples A1 to A3 were measured.

The I_{d}-V_{g} characteristics of the transistors were measured under the following conditions. A voltage applied to the gate electrode (hereinafter also referred to as a gate voltage (V_{g})) was changed from −10 V to +20 V in increments of 0.25 V. A voltage applied to the source electrode (hereinafter also referred to as a source voltage (Vₛ)) was 0 V (comm), and a voltage applied to the drain electrode (hereinafter also referred to as a drain voltage (V_{d})) was 0.1 V or 5.1 V.

Here, transistors with a channel length of approximately 6 μm and a channel width of approximately 3 μm and transistors with a channel length of approximately 50 μm and a channel width of approximately 3 μm were measured. Note that the transistors did not include the conductive layer 103. The number of measurements was set to 20 in the substrate plane for each of the two types of transistors.

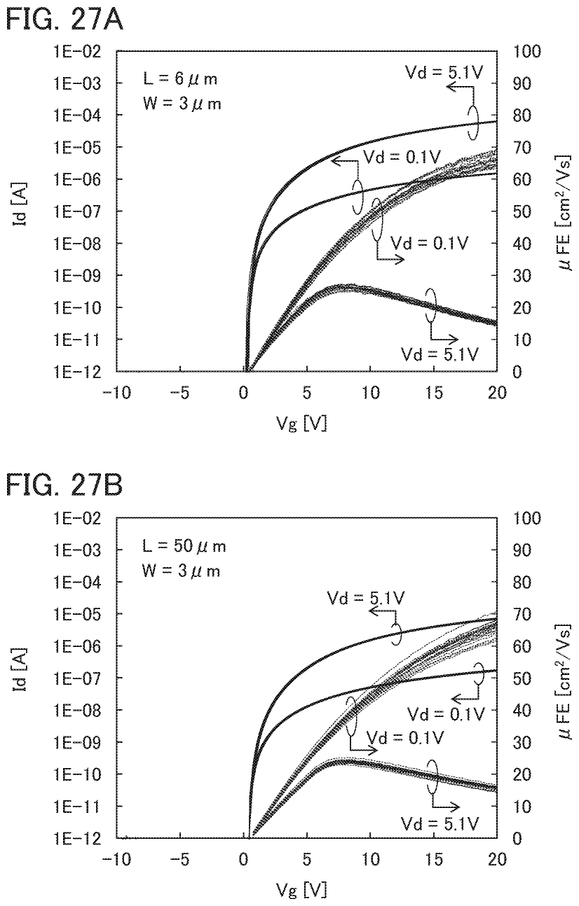

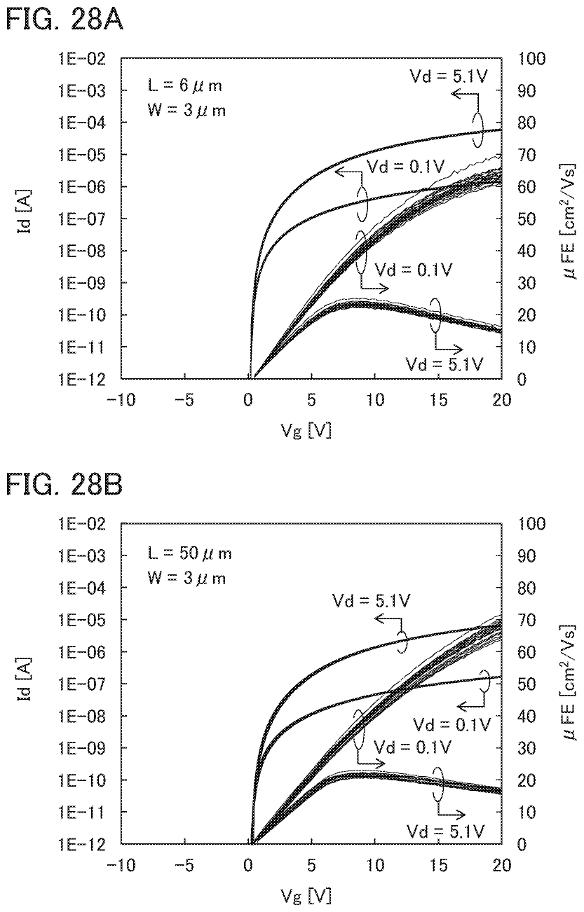

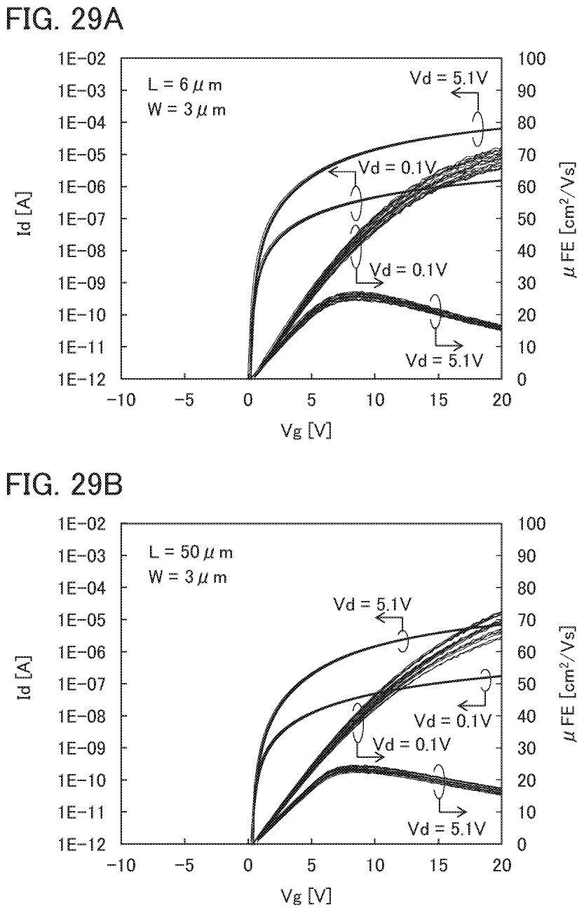

FIGS. 27A and 27B show the I_{d}-V_{g} characteristics of the transistors of Sample A1, FIGS. 28A and 28B show the I_{d}-V_{g} characteristics of the transistors of Sample A2, and FIGS. 29A and 29B show the I_{d}-V_{g} characteristics of the transistors of Sample A3. FIGS. 27A, 28A, and 29A show the I_{d}-V_{g} characteristics of the transistors with a channel length of approximately 6 μm and a channel width of approximately 3 μm, and FIGS. 27B, 28B, and 29B show the I_{d}-V_{g} characteristics of the transistors with a channel length of approximately 50 μm and a channel width of approximately 3 μm. In FIGS. 27A to 29B, the horizontal axis represents a gate voltage (V_{g}), the left vertical axis represents a drain current (I_{d}), and the right vertical axis represents field-effect mobility (also referred to as μFE). FIGS. 27A to 29B show I_{d} and μFE at V_{d} of 0.1 V and I_{d} and μFE at V_{d} of 5.1 V. FIGS. 27A to 29B each show superimposed I_{d}-V_{g} characteristics of 20 transistors.

In Sample A1, the average value of μFE in the linear region (here, V_{d}=0.1 V) obtained from the I_{d}-V_{g} characteristics of the transistors with a channel length of approximately 6 μm and a channel width of approximately 3 μm was 66.3 cm²/(V·s). The average value of I_{d} (also referred to as an on-state current or Iₒₙ) was 63.5 μA and the average value of Vₜₕ was 0.58 V in the saturation region (here, V_{d}=5.1 V) at V_{g} of 20 V. The average value of FE in the linear region obtained from the I_{d}-V_{g} characteristics of the transistors with a channel length of approximately 50 μm and a channel width of approximately 3 μm was 65.9 cm²/(V·s). The average value of Iₒₙ in the saturation region at V_{g} of 20 V was 7.0 μA, and the average value of Vₜₕ was 0.67 V.

In Sample A2, the average value of μFE in the linear region obtained from the I_{d}-V_{g} characteristics of the transistors with a channel length of approximately 6 μm and a channel width of approximately 3 μm was 64.2 cm²/(V·s). The average value of Iₒₙ in the saturation region at V_{g} of 20 V was 58.5 μA, and the average value of Vₜₕ was 0.47 V. The average value of μFE in the linear region obtained from the I_{d}-V_{g} characteristics of the transistors with a channel length of approximately 50 μm and a channel width of approximately 3 μm was 67.9 cm²/(V·s). The average value of Iₒₙ in the saturation region at V_{g} of 20 V was 6.7 μA, and the average value of Vₜₕ was 0.56 V.

In Sample A3, the average value of μFE in the linear region obtained from the I_{d}-V_{g} characteristics of the transistors with a channel length of approximately 6 μm and a channel width of approximately 3 μm was 68.8 cm²/(V·s). The average value of Iₒₙ in the saturation region at V_{g} of 20 V was 64.0 ρA, and the average value of Vₜₕ was 0.51 V. The average value of μFE in the linear region obtained from the I_{d}-V_{g} characteristics of the transistors with a channel length of approximately 50 μm and a channel width of approximately 3 μm was 69.3 cm²/(V·s). The average value of Iₒₙ in the saturation region at V_{g} of 20 V was 7.1 μA, and the average value of Vₜₕ was 0.60 V.

The transistors in Samples A1 to A3 were confirmed to be normally off and exhibit high field-effect mobility. It was confirmed that a transistor having favorable electrical characteristics can be obtained without using a gas including a hydrogen element (e.g., H₂) in formation of the metal oxide film to be the semiconductor layer 108. An H₂ gas is preferable not used, in which case capital investment for explosion prevention actions is not required.

### <Reliability>

Next, the reliability of the transistors in Samples A1 and A3 was evaluated.

For the reliability evaluation, a gate bias temperature (GBT) stress test was performed. Specifically, a positive bias temperature stress (PBTS) test and a negative bias temperature illumination stress (NBTIS) test were performed.

The test in which a transistor is kept at a high temperature with a positive potential (positive bias) with respect to a source potential and a drain potential supplied to its gate is referred to as a PBTS test, and the test in which a transistor is kept at a high temperature with a negative potential (negative bias) supplied to its gate is referred to as a negative bias temperature stress (NBTS) test. The PBTS test and the NBTS test conducted in a state where irradiation with light is performed are respectively referred to as a positive bias temperature illumination stress (PBTIS) test and an NBTIS test.

In the PBTS test, the substrate over which the transistor was formed was held at 60 °C, a voltage of 0 V was applied to the source and the drain of the transistor, and a voltage of 30 V was applied to the gate; this state was held for one hour. The test was performed in a dark environment.

In the NBTIS test, a voltage of 0 V was applied to the source and the drain of the transistor and a voltage of −30 V was applied to the gate in a state where the substrate over which the transistor was formed was held at 60 °C and light irradiation with white LED light at 8000 1× was performed; this state was held for one hour. The irradiation with white LED light was performed from the glass substrate side.

In the PBTS test and the NBTIS test, the transistors each having a channel length of approximately 6 μm and a channel width of approximately 3 μm were used. Note that the I_{d}-V_{g} measurement was performed on each transistor including the conductive layer 103 as the bottom gate connected to the top gate, by applying a gate voltage (V_{g}) to the top gate. The number of measurements was set to 1 in the substrate plane.

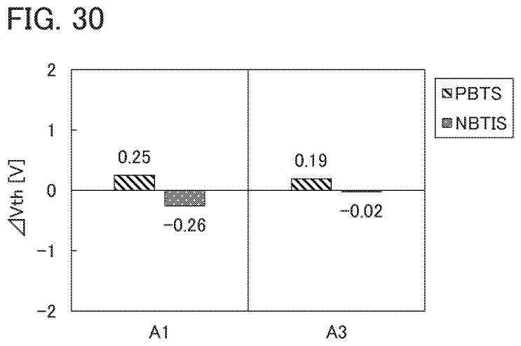

FIG. 30 shows the amount of change in threshold voltage (ΔVₜₕ) before and after the PBTS test and before and after the NBTIS test. In FIG. 30, the horizontal axis represents the sample names, and the vertical axis represents ΔVₜₕ.

As shown in FIG. 30, as for Sample A1, ΔVₜₕ in the PBTS test was 0.25 V, and ΔVₜₕ in the NBTIS test was −0.26 V. As for Sample A3, ΔVₜₕ in the PBTS test was 0.19 V, and ΔVₜₕ in the NBTIS test was −0.02 V.

As described above, the transistor of one embodiment of the present invention was confirmed to have small ΔVₜₕ in the PBTS test and the NBTIS test and have high reliability.

### Example 2

In this example, the amount of hydrogen desorbed from the insulating layer that can be used as the insulating layer 105 was evaluated. In this example, three kinds of samples (Sample B1 to Sample B3) were fabricated.

### <Sample Fabrication>

As the insulating layer, an approximately 17-nm-thick silicon nitride film and an approximately 90-nm-thick silicon oxynitride film were formed in this order over a glass substrate by a plasma CVD method. For the formation of the silicon nitride film, a mixed gas of a silane gas, a nitrogen gas, and an ammonia gas was used. For the formation of the silicon oxynitride film, a mixed gas of a silane gas and a dinitrogen monoxide (N₂O) gas was used.

Next, for Sample B₂, heat treatment was performed at 650 °C in a dry air (CDA, dew point: −70 °C or lower) atmosphere for 6 minutes with a GRTA apparatus. Sample B1 and Sample B3 were not subjected to the heat treatment.

For Sample B3, plasma treatment was performed in a hydrogen gas atmosphere, and hydrogen was supplied to the insulating layer. A plasma CVD apparatus was used for the plasma treatment. Neither Sample B1 nor Sample B2 was subjected to the plasma treatment.

Next, the samples were each divided into a square of 1 cm×1 cm.

Through the above steps, Samples B1 to B3 were obtained.

### <TDS>

The amounts of hydrogen desorbed from Samples B1 to B3 were evaluated using a TDS. In the TDS measurement, the substrate temperatures of the samples were increased from approximately 50 °C to approximately 520 °C at a substrate temperature rising rate of approximately 16 °C/min.

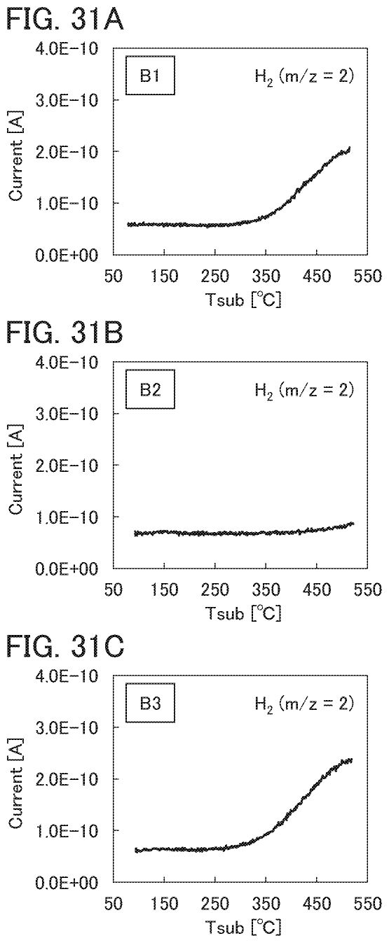

FIG. 31A shows the measurement result of hydrogen (H₂, m/z=2) of Sample B1, FIG. 31B shows the measurement result of Sample B2, and FIG. 31C shows the measurement result of Sample B3. In FIGS. 31A to 31C, the horizontal axis represents the substrate temperature (Tsub) of the sample and the vertical axis represents the current value (Current) of the mass analyzer.

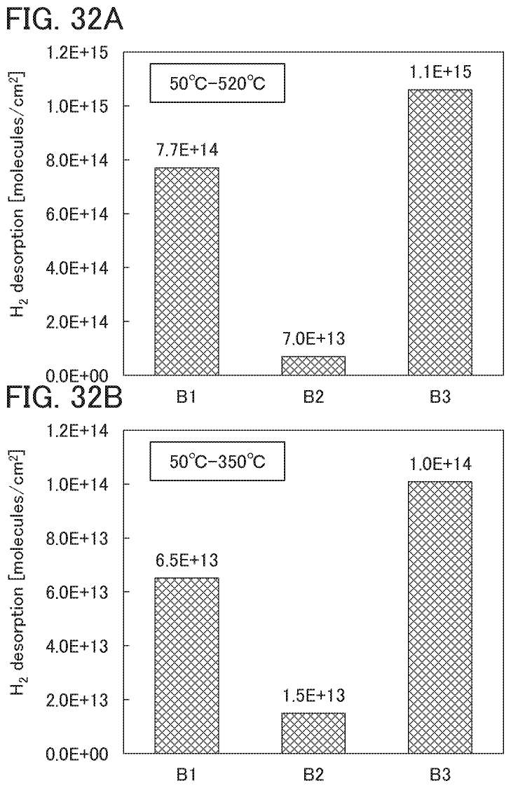

FIGS. 32A and 32B show the amount of desorbed hydrogen molecules which was obtained from the TDS measurement results. In FIGS. 32A and 32B, the horizontal axis represents the sample names and the vertical axis represents the amount of desorbed hydrogen molecules (H₂ desorption). FIG. 32A shows the amount of desorbed hydrogen molecules in the entire measurement temperature range (a Tsub range higher than or equal to 50 °C and lower than or equal to 520 °C). FIG. 32B shows the amount of desorbed hydrogen molecules in a Tsub range higher than or equal to 50 °C and lower than or equal to 350 °C. Note that for quantification of the desorbed amount, current values obtained by background processing were used. As the background processing, the minimum value of the current value in the entire measurement temperature range as the background value was subtracted from the measured current value.

As shown in FIG. 32A, the amount of desorbed hydrogen molecules in a Tsub range higher than or equal to 50 °C and lower than or equal to 520 °C is 7.7×10¹⁴ molecules/cm² for Sample B1, 7.0×10¹³ molecules/cm² for Sample B2, and 1.1×10¹⁵ molecules/cm² for Sample B3. For example, in the case where heat treatment at 520 °C is performed on the formed insulating layer, the amount of hydrogen molecules desorbed from the insulating layer by the heat treatment is estimated to be approximately 7.7×10¹⁴ molecules/cm². In the case where heat treatment at 650 °C for 6 minutes is performed on the formed insulating layer using a GRTA apparatus and then heat treatment at 520 °C is performed, the amount of hydrogen molecules desorbed from the insulating layer by the heat treatment is estimated to be approximately 7.0×10¹³ molecules/cm². In the case where hydrogen is supplied to the formed insulating layer in a manner similar to that for Sample B3 and then heat treatment at 520 °C is performed, the amount of hydrogen molecules desorbed from the insulating layer by the heat treatment is estimated to be approximately 1.1×10¹⁵ molecules/cm².

As shown in FIG. 32B, the amount of desorbed hydrogen molecules in the range where Tsub is higher than or equal to 50 °C and lower than or equal to 350 °C is 6.5×10¹³ molecules/cm² in Sample B1, 1.5×10¹³ molecules/cm² in Sample B2, and 1.0×10¹⁴ molecules/cm² in Sample B3. For example, in the case where heat treatment at 350 °C is performed on the formed insulating layer, the amount of hydrogen molecules desorbed from the insulating layer by the heat treatment is estimated to be approximately 6.5×10¹³ molecules/cm². In the case where heat treatment at 650 °C is performed on the formed insulating layer using a GRTA apparatus for 6 minutes and then heat treatment at 350 °C is performed, the amount of hydrogen molecules desorbed from the insulating layer by the heat treatment is estimated to be approximately 1.5×10¹³ molecules/cm².

In the case where hydrogen is supplied to the formed insulating layer in a manner similar to that for Sample B3 and then heat treatment at 350 °C is performed, the amount of hydrogen molecules desorbed from the insulating layer by the heat treatment is estimated to be approximately 1.0×10¹⁴ molecules/cm².

As shown in FIGS. 32A and 32B, it was confirmed that the amount of hydrogen molecules desorbed from Sample B2 subjected to heat treatment was smaller than that from Sample B1. It was also confirmed that the amount of hydrogen molecules desorbed from Sample B3 supplied with hydrogen was larger than that in Sample B1.

The above results confirmed that hydrogen molecules were desorbed, by heat application, from the insulating layer formed using a gas including a hydrogen element. It was also confirmed that performing heat treatment on the insulating layer decreased the amount of hydrogen molecules desorbed when heat was subsequently applied, and supplying hydrogen to the insulating layer increased the amount of hydrogen molecules desorbed when heat was subsequently applied. In this manner, the amount of hydrogen molecules desorbed from the insulating layer can be controlled by heat treatment or supply of hydrogen with respect to the insulating layer.

### Example 3

In this example, a semiconductor device including a TGSA transistor of one embodiment of the present invention was fabricated, and electrical characteristics of the transistor were evaluated.

In this example, two kinds of samples (Sample C1 and Sample C2) including the transistor of one embodiment of the present invention were fabricated. For the structures of Sample C1 and Sample C2, the description of FIGS. 3A to 3C can be referred to. Note that the conductive layer 103 was not provided. For the fabrication method of Sample C1, the description of the manufacturing method example 1 can be referred to. For the fabrication method of Sample C2, the description of the manufacturing method example 2 can be referred to.

### <Sample Fabrication>

First, as the insulating layer 105, the insulating layer 105a and the insulating layer 105b were formed over the substrate 102 by a plasma CVD method. An approximately 17-nm-thick silicon nitride film was formed as the insulating layer 105a, and an approximately 90-nm-thick silicon oxynitride film was formed as the insulating layer 105b. For the formation of the insulating layer 105a, a mixed gas of a silane gas, a nitrogen gas, and an ammonia gas was used. For the formation of the insulating layer 105b, a mixed gas of a silane gas and a dinitrogen monoxide (N₂O) gas was used. A glass substrate with a size of 600 mm×720 mm was used as the substrate 102.

Next, as the fourth heat treatment for Sample C2, heat treatment was performed at 650 °C in a dry air (CDA, dew point: lower than or equal to −70 °C) atmosphere for 6 minutes. A GRTA apparatus was used for the fourth heat treatment. Sample C1 was not subjected to the fourth heat treatment.

Subsequently, as the metal oxide film 108f, an approximately 6-nm-thick indium oxide film was formed by a magnetron sputtering method. The metal oxide film 108f had a three-layer structure of the metal oxide film 108af with a thickness of approximately 1 nm, the metal oxide film 108bf with a thickness of approximately 4 nm, and the metal oxide film 108cf with a thickness of approximately 1 nm. The metal oxide film 108af, the metal oxide film 108bf, and the metal oxide film 108cf were successively formed in the same treatment chamber using the same In₂O₃ sputtering target. The substrate was not heated at the time of the film formation.

The film formation conditions (first film formation conditions) of the metal oxide film 108af were as follows: the pressure was 0.2 Pa and the power was 1.0 kW (power density: 0.66 W/cm²). The film formation conditions (second film formation conditions) of the metal oxide film 108bf were as follows: the pressure was 0.6 Pa and the power was 0.5 kW (power density: 0.33 W/cm²). The film formation conditions (third film formation conditions) of the metal oxide film 108cf were the same as the first film formation conditions. Note that the power density is a value obtained by dividing power by a magnet area.

Argon and oxygen were used as film formation gases for the metal oxide film 108af, the metal oxide film 108bf, and the metal oxide film 108cf, and hydrogen was not used. In the formation of the metal oxide film 108af and the metal oxide film 108cf, the argon flow rate ratio was 96% and the oxygen flow rate ratio was 4%. In the formation of the metal oxide film 108bf, the argon flow rate ratio was 97% and the oxygen flow rate ratio was 3%.

Then, the metal oxide film 108f was processed to form the semiconductor layer 108. The processing of the metal oxide film 108f was performed by a wet etching method.

Next, as the first heat treatment, heat treatment was performed at 350 °C in a dry air (CDA, dew point: lower than or equal to −70 °C) atmosphere for one hour. This increased the crystallinity of the semiconductor layer 108. An oven was used for the first heat treatment.

Subsequently, the insulating film 106f was formed using an approximately 100-nm-thick silicon oxynitride film by a plasma CVD method. For the formation of the insulating film 106f, a mixed gas of a silane gas and a dinitrogen monoxide (N₂O) gas was used.

Then, as the second heat treatment, heat treatment was performed at 350 °C in a dry air atmosphere for one hour. An oven was used for the second heat treatment.

Next, an approximately 20-nm-thick metal oxide film was formed as the film 139. The metal oxide film was formed by a sputtering method using an IGZO sputtering target with an atomic ratio of metal elements of In:Ga:Zn=1:1:1.

Then, as the third heat treatment, heat treatment was performed at 350 °C in a dry air atmosphere for one hour. An oven was used for the third heat treatment.

Next, the film 139 was removed. The removal of the film 139 was performed by a wet etching method.

Subsequently, a conductive film was formed and processed to form the conductive layer 104. For the conductive layer 104, a stacked-layer structure in which an approximately 100-nm-thick titanium film, an approximately 300-nm-thick copper film, and an approximately 10-nm-thick titanium film were formed in this order was used. The insulating film 106f was processed to form the insulating layer 106.

Next, plasma treatment was performed in an atmosphere including hydrogen, and hydrogen was supplied as the first element to the semiconductor layer 108. Consequently, the region 108P and the region 108Q each including hydrogen were formed in the region of the semiconductor layer 108 not overlap with the conductive layer 104. Then, as the insulating film 195f, a silicon nitride oxide film with a thickness of approximately 300 nm was formed by a plasma CVD method. The plasma treatment and formation of the insulating film 195f were successively performed in the same treatment chamber of a plasma CVD apparatus. For the plasma treatment and formation of the insulating film 195f, a mixed gas of a silane gas, a nitrogen gas, a dinitrogen monoxide (N₂O) gas, and an ammonia gas was used.

Subsequently, the insulating film 195f was partly etched, so that the opening portion 147a and the opening portion 147b respectively reaching the region 108P and the region 108Q were formed. Accordingly, the insulating layer 195 was obtained.

Next, an approximately 100-nm-thick molybdenum film was formed by a sputtering method to cover the opening portion 147a and the opening portion 147b and processed to form the conductive layer 112a and the conductive layer 112b.

Then, a polyimide resin film with a thickness of approximately 1.5 μm was formed as the insulating layer 218.

Subsequently, heat treatment was performed at 250 °C in a nitrogen atmosphere for one hour. An oven was used for the heat treatment.

Through the above process, Samples C1 and C2 were obtained.

Note that the insulating layer 105 of Sample C1 corresponds to the above-described Sample B1, and the insulating layer 105 of Sample C2 corresponds to the above-described Sample B2. Thus, the amount of hydrogen molecules desorbed from the insulating layer 105 of Sample C1 in a range higher than or equal to 50 °C and lower than or equal to 350 °C is estimated to be approximately 6.5×10¹³ molecules/cm², and the amount of hydrogen molecules desorbed from the insulating layer 105 of Sample C2 in the range higher than or equal to 50 °C and lower than or equal to 350 °C is estimated to be approximately 1.5×10¹³ molecules/cm² (see FIGS. 32A and 32B).

<I_{d}-V_{g} Characteristics>

Next, I_{d}-V_{g} characteristics of the transistors of Samples C1 and C2 were measured.

The I_{d}-V_{g} characteristics of the transistors were measured under the following conditions. A voltage applied to the gate electrode (hereinafter also referred to as a gate voltage (V_{g})) was changed from −10 V to +20 V in increments of 0.25 V. A voltage applied to the source electrode (hereinafter also referred to as a source voltage (Vₛ)) was 0 V (comm), and a voltage applied to the drain electrode (hereinafter also referred to as a drain voltage (V_{d})) was 0.1 V or 5.1 V.

The transistor measured here had a channel length of approximately 6 μm and a channel width of approximately 50 μm. The number of measurements was set to 19 in the substrate plane.

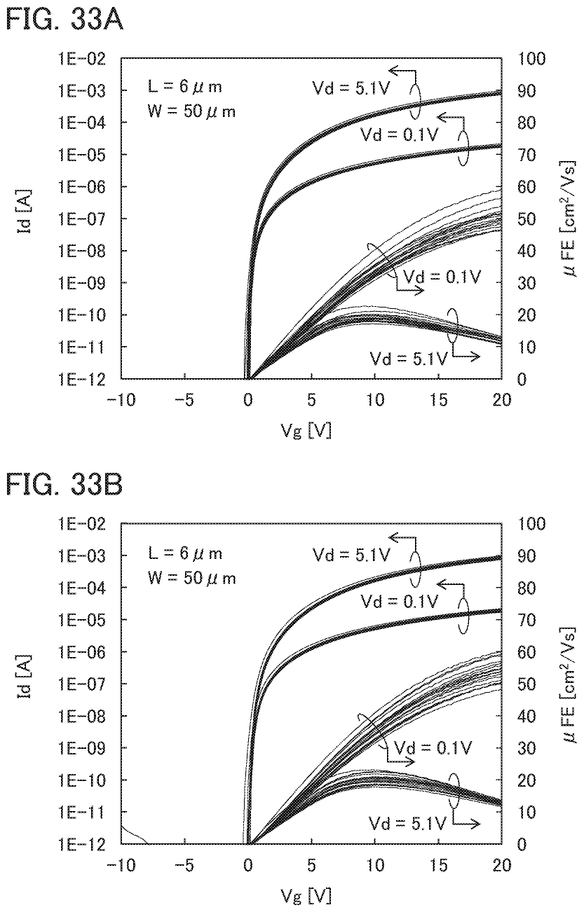

FIG. 33A shows the I_{d}-V_{g} characteristics of the transistors of Sample C1, and FIG. 33B shows the I_{d}-V_{g} characteristics of the transistors of Sample C2. In FIGS. 33A and 33B, the horizontal axis represents a gate voltage (V_{g}), the left vertical axis represents a drain current (I_{d}), and the right vertical axis represents field-effect mobility (μFE). FIGS. 33A and 33B show I_{d} and μFE at V_{d} of 0.1 V and I_{d} and μFE at Va of 5.1 V. FIGS. 33A and 33B each show superimposed I_{d}-V_{g} characteristics of the 19 transistors.

In Sample C1, the average value of μFE in the linear region (here, V_{d}=0.1 V) obtained from the I_{d}-V_{g} characteristics was 50.5 cm²/(V·s). The average value of I_{d} (Iₒₙ) in the saturation region (here, V_{d}=5.1 V) at V_{g} of 20 V was 800.1 μA, and the average value of Vₜₕ was 0.37 V.

In Sample C2, the average value of μFE in the linear region obtained from the I_{d}-V_{g} characteristics was 54.0 cm²/(V·s). The average value of Iₒₙ in the saturation region at V_{g} of 20 V was 835.1 μA, and the average value of Vₜₕ was 0.46 V.

The transistors in Samples C1 and C2 were confirmed to be normally off and exhibit high field-effect mobility.

### Example 4

In this example, samples each including an indium oxide film that can be used as the semiconductor layer 108 were fabricated, and the hydrogen concentrations in the indium oxide films were evaluated. In this example, five kinds of samples (Sample D1 to Sample D5) were fabricated.

### <Sample Fabrication>

As insulating films corresponding to the insulating layer 105, an approximately 17-nm-thick silicon nitride film and an approximately 90-nm-thick silicon oxynitride film were formed in this order over a glass substrate by a plasma CVD method. As film formation gases for the silicon nitride film, silane, nitrogen, and ammonia were used. As film formation gases for the silicon oxynitride film, silane and dinitrogen monoxide were used. The silicon nitride film corresponds to the insulating layer 105a, and the silicon oxynitride film corresponds to the insulating layer 105b (see FIGS. 2A and 2B).

Next, an approximately 20-nm-thick indium oxide film was formed as a metal oxide film corresponding to the semiconductor layer 108. The indium oxide film was formed by a sputtering method using an In₂O₃ sputtering target. Argon and oxygen were used as film formation gases for the indium oxide film, and hydrogen was not used.

Next, for Samples D2 to D5, heat treatment was performed at 350 °C in a dry air (CDA, dew point: lower than or equal to −70 °C) atmosphere for one hour with an oven. The heat treatment corresponds to the first heat treatment. Sample D1 was not subjected to heat treatment.

Then, for Samples D3 to D5, as an insulating film corresponding to the insulating layer 106, a silicon oxynitride film with a thickness of approximately 100 nm was formed by a plasma CVD method. As film formation gases for the silicon oxynitride film, silane and dinitrogen monoxide were used. For Samples D1 and D2, the silicon oxynitride film was not formed.

Next, for Samples D4 and D5, heat treatment was performed at 350 °C in a dry air atmosphere for one hour with an oven. The heat treatment corresponds to the second heat treatment. Sample D1 to D3 were not subjected to heat treatment.

Subsequently, an approximately 20-nm-thick IGZO film was formed for Sample D5. The IGZO film was formed by a sputtering method using an IGZO sputtering target with an atomic ratio of metal elements of In:Ga:Zn=1:1:1. The IGZO film corresponds to the film 139.

Next, for Sample D5, heat treatment was performed at 350 °C in a dry air atmosphere for one hour with an oven. The heat treatment corresponds to the third heat treatment. Sample D1 to D4 were not subjected to heat treatment.

Next, the IGZO film in Sample D5 was removed. For the removal of the IGZO film, a wet etching method was used. Samples D1 to D4 were not subjected to the removal treatment.

Through the above steps, Samples D1 to D5 were obtained.

### <SIMS>

Next, the hydrogen concentrations in Samples D1 to D5 were analyzed. SIMS measurement was performed in the direction from the indium oxide film toward the glass substrate, whereby depth profiles of the hydrogen concentrations were obtained. The SIMS analysis was performed with a quadrupole secondary ion mass spectrometer (PHI ADEPT-1010, manufactured by ULVAC-PHI, Inc.) using Cs⁺ as the primary ion species, with a primary acceleration voltage of 2.0 kV and a detection region of 135 μm×135 μm.

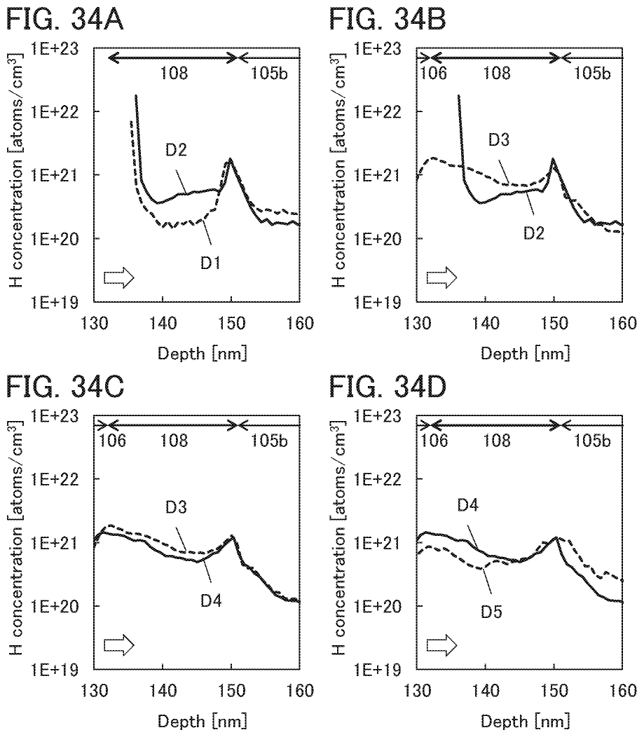

FIG. 34A shows the hydrogen concentrations of Sample D1 and Sample D2, FIG. 34B shows the hydrogen concentrations of Sample D2 and Sample D3, FIG. 34C shows the hydrogen concentrations of Sample D3 and Sample D4, and FIG. 34D shows the hydrogen concentrations of Sample D4 and Sample D5. In FIGS. 34A to 34D, the horizontal axis represents depth (Depth) from the sample surface, and the vertical axis represents hydrogen concentration (H concentration). Quantification was performed on the indium oxide film. Sample D1, Sample D3, and Sample D5 are denoted by dashed lines, and Sample D2 and Sample D4 are denoted by solid lines. The measurement direction is indicated by a block arrow. Note that Sample D1 and Sample D2 in each of which the insulating film corresponding to the insulating layer 106 was not provided differ in depth from the sample surface from Sample D3 to Sample D5 in each of which the insulating film was provided. For easy comparison of hydrogen concentrations in the indium oxide films between the samples, the depths of Sample D1 and Sample D2 in FIGS. 34A and 34B are displayed to be shifted by the thickness of the insulating film corresponding to the insulating layer 106.

The hydrogen concentration in the indium oxide film of Sample D1 was approximately 1.4×10²⁰ atoms/cm³. It can be considered that the formed indium oxide film includes hydrogen due to diffusion of hydrogen included in the insulating film corresponding to the insulating layer 105 into the indium oxide film even when hydrogen is not used as a film formation gas for the indium oxide film.

As shown in FIG. 34A, Sample D2 was found to have a higher hydrogen concentration in the indium oxide film than Sample D1. It can be considered that further diffusion of hydrogen included in the insulating film corresponding to the insulating layer 105 into the indium oxide film by the first heat treatment increased the hydrogen concentration in the indium oxide film.

As shown in FIG. 34B, Sample D3 was found to have a higher hydrogen concentration in the indium oxide film than Sample D2. It can be considered that diffusion of hydrogen included in the film formation gases for the insulating film corresponding to the insulating layer 106 into the indium oxide film increased the hydrogen concentration in the indium oxide film.

As shown in FIG. 34C, Sample D4 was found to have a lower hydrogen concentration in the indium oxide film than Sample D3. It can be considered that desorption of hydrogen included in the indium oxide film by the second heat treatment reduced the hydrogen concentration in the indium oxide film.

As shown in FIG. 34D, Sample D5 was found to have a lower hydrogen concentration in the indium oxide film than Sample D4. It can be considered that desorption of hydrogen included in the indium oxide film by the third heat treatment reduced the hydrogen concentration in the indium oxide film.

As described above, it was confirmed that hydrogen included in the film in contact with the indium oxide film diffuses into the indium oxide film and thus, the indium oxide film includes hydrogen even when hydrogen is not used as a film formation gas for the indium oxide film. It was also confirmed that the hydrogen concentration in the indium oxide film can be reduced by the second heat treatment or the third heat treatment.

### Example 5

In this example, samples each including a silicon oxynitride film that can be used as the insulating layer 105 were fabricated, and the hydrogen concentrations in the silicon oxynitride films were evaluated. In this example, two kinds of samples (Sample E1 and Sample E2) were fabricated.

### <Sample Fabrication>

As insulating films corresponding to the insulating layer 105, an approximately 17-nm-thick silicon nitride film and an approximately 90-nm-thick silicon oxynitride film were formed in this order over a glass substrate by a plasma CVD method. As film formation gases for the silicon nitride film, silane, nitrogen, and ammonia were used. As film formation gases for the silicon oxynitride film, silane and dinitrogen monoxide were used. The silicon nitride film corresponds to the insulating layer 105a, and the silicon oxynitride film corresponds to the insulating layer 105b (see FIGS. 2A and 2B).

Next, for Sample E2, heat treatment was performed at 650 °C in a dry air (CDA, dew point: lower than or equal to −70 °C) atmosphere for 6 minutes with a GRTA apparatus. The heat treatment corresponds to the fourth heat treatment. Sample E1 was not subjected to heat treatment.

Next, an approximately 20-nm-thick indium oxide film was formed as a metal oxide film corresponding to the semiconductor layer 108. The indium oxide film was formed by a sputtering method using an In₂O₃ sputtering target. Argon and oxygen were used as film formation gases for the indium oxide film, and hydrogen was not used.

Next, heat treatment was performed at 350 °C in a dry air (CDA, dew point: lower than or equal to −70 °C) atmosphere for one hour with an oven. The heat treatment corresponds to the first heat treatment.

Through the above steps, Samples E1 and E2 were obtained.

### <SIMS>

Next, the hydrogen concentrations in Samples E1 and E2 were analyzed. SIMS measurement was performed in the direction from the silicon oxynitride film toward the glass substrate, whereby depth profiles of the hydrogen concentrations were obtained. The SIMS analysis was performed with a quadrupole secondary ion mass spectrometer (PHI ADEPT-1010, manufactured by ULVAC-PHI, Inc.) using Cs⁺ as the primary ion species, with a primary acceleration voltage of 2.0 kV and a detection region of 135 μm×135 μm.

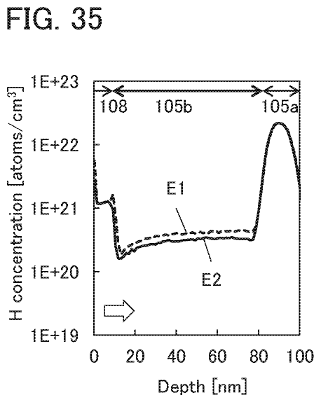

FIG. 35 shows the hydrogen concentrations of Samples E1 and E2. In FIG. 35, the horizontal axis represents depth (Depth) from the sample surface, and the vertical axis represents hydrogen concentration (H concentration). Quantification was performed on the silicon oxynitride film. Sample E1 is denoted by a dashed line, and Sample E2 is denoted by a solid line. The measurement direction is indicated by a block arrow.

As shown in FIG. 35, Sample E2 was found to have a lower hydrogen concentration in the silicon oxynitride film than Sample E1. It can be considered that desorption of hydrogen included in the silicon oxynitride film by the fourth heat treatment reduced the hydrogen concentration in the silicon oxynitride film.

As described above, it was confirmed that performing heat treatment after the formation of the silicon oxynitride film can reduce the hydrogen concentration in the silicon oxynitride film.

This application is based on Japanese Patent Application Serial No. 2025-079012 filed with Japan Patent Office on May 9, 2025, Japanese Patent Application Serial No. 2025-079007 filed with Japan Patent Office on May 9, 2025, Japanese Patent Application Serial No. 2025-095143 filed with Japan Patent Office on Jun. 6, 2025, and Japanese Patent Application Serial No. 2026-020063 filed with Japan Patent Office on Feb. 10, 2026, the entire contents of which are hereby incorporated by reference.

What is claimed is:

1. A semiconductor device comprising:
a semiconductor layer, a first insulating layer, a second insulating layer, and a conductive layer,
wherein the semiconductor layer is positioned over the first insulating layer,
wherein the second insulating layer is positioned over the semiconductor layer,
wherein the semiconductor layer comprises a region overlapping with the conductive layer with the second insulating layer therebetween,
wherein the semiconductor layer comprises a first metal oxide layer and a second metal oxide layer over the first metal oxide layer,
wherein the first metal oxide layer and the second metal oxide layer each comprise indium and oxygen,
wherein a film density of the first metal oxide layer is higher than a film density of the second metal oxide layer,
wherein the first insulating layer comprises silicon, oxygen, and hydrogen, and
wherein the second insulating layer comprises silicon and oxygen.

2. A semiconductor device comprising:
a semiconductor layer, a first insulating layer, a second insulating layer, and a conductive layer,
wherein the semiconductor layer is positioned over the first insulating layer,
wherein the second insulating layer is positioned over the semiconductor layer,
wherein the semiconductor layer comprises a region overlapping with the conductive layer with the second insulating layer therebetween,
wherein the semiconductor layer comprises a first metal oxide layer, a second metal oxide layer over the first metal oxide layer, and a third metal oxide layer over the second metal oxide layer,
wherein the first metal oxide layer, the second metal oxide layer, and the third metal oxide layer each comprise indium and oxygen,
wherein a film density of the first metal oxide layer is higher than a film density of the second metal oxide layer,
wherein a film density of the third metal oxide layer is higher than the film density of the second metal oxide layer,
wherein the first insulating layer comprises silicon, oxygen, and hydrogen, and
wherein the second insulating layer comprises silicon and oxygen.

3. The semiconductor device according to claim 1, further comprising:
a third insulating layer,
wherein the third insulating layer comprises a region overlapping with the semiconductor layer with the first insulating layer therebetween, and
wherein the third insulating layer comprises silicon and nitrogen.

4. The semiconductor device according to claim 3,
wherein the third insulating layer comprises hydrogen, and
wherein the third insulating layer comprises a region having a higher hydrogen concentration than the first insulating layer.

5. A semiconductor device comprising:
a semiconductor layer, a first insulating layer, a second insulating layer, a third insulating layer, a fourth insulating layer, and a conductive layer,
wherein the second insulating layer is positioned over the first insulating layer,
wherein the semiconductor layer is positioned over the second insulating layer,
wherein the third insulating layer is positioned over the semiconductor layer,
wherein the semiconductor layer comprises a region overlapping with the conductive layer with the third insulating layer therebetween,
wherein the fourth insulating layer is positioned over the semiconductor layer, the third insulating layer, and the conductive layer,
wherein the semiconductor layer comprises a first metal oxide layer, a second metal oxide layer over the first metal oxide layer, and a third metal oxide layer over the second metal oxide layer,
wherein the first metal oxide layer, the second metal oxide layer, and the third metal oxide layer each comprise indium and oxygen,
wherein a film density of the first metal oxide layer is higher than a film density of the second metal oxide layer,
wherein a film density of the third metal oxide layer is higher than the film density of the second metal oxide layer,
wherein the second insulating layer comprises silicon, oxygen, and hydrogen,
wherein the third insulating layer comprises silicon and oxygen, and
wherein the first insulating layer and the fourth insulating layer each comprise silicon and nitrogen.

6. The semiconductor device according to claim 5,
wherein the semiconductor layer comprises a first region and a pair of second regions, the first region overlapping with the conductive layer with the second insulating layer therebetween, the first region being sandwiched between the pair of second regions, and
wherein the fourth insulating layer comprises a region in contact with the second region.

7. The semiconductor device according to claim 5,
wherein the first insulating layer comprises hydrogen, and
wherein the first insulating layer comprises a region having a higher hydrogen concentration than the second insulating layer.
